(19) United States
(12) Patent Application Publication
(10) Pub. No.: US 2014/0076403 A1
(43) Pub. Date: Mar. 20, 2014

(54) DIPYRIN BASED MATERIALS FOR PHOTOVOLTAICS, COMPOUNDS CAPABLE OF UNDERGOING SYMMETRY BREAKING INTRAMOLECULAR CHARGE TRANSFER IN A POLARIZING MEDIUM AND ORGANIC PHOTOVOLTAIC DEVICES COMPRISING THE SAME

(71) Applicants: University of Southern California, Los Angeles, CA (US); The Regents of the University of Michigan, Ann Arbor, MI (US)

(72) Inventors: Stephen R. Forrest, Ann Arbor, MI (US); Mark E. Thompson, Anaheim, CA (US); John J. Chen, Arcadia, CA (US); Jonathan R. Sommer, Santa Monica, CA (US); Peter I. Djurovich, Long Beach, CA (US); Kathryn R. Allen, Los Angeles, CA (US)

(73) Assignees: University of Southern California, Los Angeles, CA (US); The Regents of the University of Michigan, Ann Arnor, MI (US)

(21) Appl. No.: 13/894,590

(22) Filed: May 15, 2013

Related U.S. Application Data
(63) Continuation-in-part of application No. 13/564,953, filed on Aug. 2, 2012.
(60) Provisional application No. 61/647,360, filed on May 15, 2012.

(51) Int. Cl. H01L 51/00

(52) U.S. Cl. CPC H01L 51/0067; H01L 51/0072
USPC 136/263; 548/405; 252/501.1; 438/57

(57) ABSTRACT

The present disclosure generally relates to organic photosensitive optoelectronic devices comprising at least one boron dipyrrin compound. In addition, the present disclosure relates to methods of making organic photosensitive optoelectronic devices comprising at least one boron dipyrrin compound. The present disclosure also generally relates to chromophoric compounds that combine strong absorption of light at visible wavelengths with the ability to undergo symmetry-breaking intramolecular charge transfer (ICT), and their use for the generation of free carriers in organic photovoltaic cells (OPVs) and electric-field-stabilized geminate polaron pairs. The present disclosure also relates to the synthesis of such compounds, methods of manufacture, and applications in photovoltaic systems and organic lasers.

### CROSS-REFERENCE TO RELATED APPLICATION

This application claims the benefit of priority to U.S. Provisional Patent Application No. 61/647,360 filed on May 15, 2012, and is a continuation-in-part of, and claims the benefit of priority to, U.S. patent application Ser. No. 13/564,953 filed on Aug. 2, 2012. The contents of both applications are incorporated herein by reference.

### STATEMENT REGARDING FEDERALLY SPONSORED RESEARCH

This invention was made with U.S. Government support under Contract No. DE-SC0001013 awarded by the Department of Energy. The government has certain rights to this invention.

### JOINT RESEARCH AGREEMENT

The subject matter of this application was made by, on behalf of, and/or in connection with one or more of the following parties to a joint university-corporation research agreement: University of Southern California, University of Michigan, and Global Photonic Energy Corporation. The agreement was in effect on and before the date the subject matter of this application was made, and such was made as a result of activities undertaken within the scope of the agreement.

The present disclosure generally relates to organic photosensitive optoelectronic devices comprising at least one boron dipyrrin compound. In addition, the present disclosure relates to methods of making organic photosensitive optoelectronic devices comprising at least one boron dipyrrin compound.

The present disclosure also generally relates to chromophoric compounds, including boron dipyrrin compounds, that combine strong absorption of light at visible to near infrared wavelengths with the ability to undergo symmetry-breaking intramolecular charge transfer (ICT), and their use for the generation of free carriers in organic photovoltaic cells (OPVs) and electric-field-stabilized geminate polaron pairs. The present disclosure also relates to the synthesis of such compounds, methods of manufacture, and applications in photovoltaic systems and organic lasers.

Optoelectronic devices rely on the optical and electronic properties of materials to either produce or detect electromagnetic radiation electronically, or to generate electricity from ambient electromagnetic radiation.

Photosensitive optoelectronic devices convert electromagnetic radiation into electricity. Solar cells, also called photovoltaic (PV) devices, are a type of photosensitive optoelectronic device that is specifically used to generate electrical power. PV devices, which may generate electrical energy from light sources other than sunlight, can be used to drive power consuming loads to provide, for example, lighting, heating, or to power electronic circuitry or devices such as calculators, radios, computers or remote monitoring or communications equipment. These power generation applications also often involve the charging of batteries or other energy storage devices so that operation may continue when direct illumination from the sun or other light sources is not available, or to balance the power output of the PV device with a specific application's requirements. As used herein the term “resistive load” refers to any power consuming or storing circuit, device, equipment or system.

Another type of photosensitive optoelectronic device is a photoconductor cell. In this function, signal detection circuitry monitors the resistance of the device to detect changes due to the absorption of light.

Another type of photosensitive optoelectronic device is a photodetector. In operation a photodetector is used in conjunction with a current detecting circuit which measures the current generated when the photodetector is exposed to electromagnetic radiation and may have an applied bias voltage. A detecting circuit as described herein is capable of providing a bias voltage to a photodetector and measuring the electronic response of the photodetector to electromagnetic radiation.

These three classes of photosensitive optoelectronic devices may be characterized according to whether a rectifying junction as defined below is present, and also according to whether the device is operated with an external applied voltage, also known as a bias or bias voltage. A photoconductor cell does not have a rectifying junction and is normally operated with a bias. A PV device has at least one rectifying junction and is operated with no bias. A photodetector has at least one rectifying junction and is usually but not always operated with a bias. As a general rule, a photovoltaic cell provides power to a circuit, device or equipment, but does not provide a signal or current to control detection circuitry, or the output of information from the detection circuitry. In contrast, a photodetector or photoconductor provides a signal or current to control detection circuitry, or the output of information from the detection circuitry but does not provide power to the circuitry, device or equipment.

Traditionally, photosensitive optoelectronic devices have been constructed of a number of inorganic semiconductors, e.g., crystalline, polycrystalline and amorphous silicon, gallium arsenide, cadmium telluride and others. Herein the term “semiconductor” denotes materials which can conduct electricity when charge carriers are induced by thermal or electromagnetic excitation. The term “photoconductive” generally relates to the process in which electromagnetic radiant energy is absorbed and thereby converted to excitation energy of electric charge carriers so that the carriers can conduct, i.e., transport, electric charge in a material. The terms “photoconductor” and “photoconductive material” are used herein to refer to semiconductor materials which are chosen for their property of absorbing electromagnetic radiation to generate electric charge carriers.

PV devices may be characterized by the efficiency with which they can convert incident solar power to useful electric power. Devices utilizing crystalline or amorphous silicon dominate commercial applications, and some have achieved efficiencies of 23% or greater. However, efficient crystalline-based devices, especially of large surface area, are difficult and expensive to produce due to the problems inherent in producing large crystals without significant efficiency-degrading defects. On the other hand, high efficiency amorphous silicon devices still suffer from problems with stability. Present commercially available amorphous silicon cells have stabilized efficiencies between 4 and 8%.

PV devices may be optimized for maximum electrical power generation under standard illumination conditions (i.e., Standard Test Conditions which are 1000 W/m², AM1.5 spectral illumination), for the maximum product of photocurrent times photovoltage. The power conversion efficiency of such a cell under standard illumination conditions depends on the following three parameters: (1) the current under zero bias, i.e., the short-circuit current I_{SC}, in Amperes; (2) the photovoltage under open circuit conditions, i.e., the open circuit voltage V_{OC}, in Volts; and (3) the fill factor, ff.

PV devices produce a photo-generated current when they are connected across a load and are irradiated by light. When irradiated under infinite load, a PV device generates its maximum possible voltage, V open-circuit, or V_{OC}. When irradiated with its electrical contacts shorted, a PV device generates its maximum possible current, I short-circuit, or I_{SC}. When actually used to generate power, a PV device is connected to a finite resistive load and the power output is given by the product of the current and voltage, I×V. The maximum total power generated by a PV device is inherently incapable of exceeding the product I_{SC}×V_{OC}. When the load value is optimized for maximum power extraction, the current and voltage have the values Iₘₐₓ and Vₘₐₓ, respectively.

A figure of merit for PV devices is the fill factor, ff, defined as:

ff={IₘₐₓVₘₐₓ}/{I_{SC} V_{OC}} (1)

where ff is always less than 1, as I_{SC} and V_{OC} are never obtained simultaneously in actual use. Nonetheless, as ff approaches 1, the device has less series or internal resistance and thus delivers a greater percentage of the product of I_{SC} and V_{OC} to the load under optimal conditions. Where P_{inc} is the power incident on a device, the power efficiency of the device, η_{P}, may be calculated by:

η_{P}=ff*(I_{SC}*V_{OC})/P_{inc}

To produce internally generated electric fields that occupy a substantial volume of the semiconductor, the usual method is to juxtapose two layers of material with appropriately selected conductive properties, especially with respect to their distribution of molecular quantum energy states. The interface of these two materials is called a photovoltaic junction. In traditional semiconductor theory, materials for forming PV junctions have been denoted as generally being of either n- or p-type. Here n-type denotes that the majority carrier type is the electron. This could be viewed as the material having many electrons in relatively free energy states. The p-type denotes that the majority carrier type is the hole. Such material has many holes in relatively free energy states. The type of the background, i.e., not photo-generated, majority carrier concentration depends primarily on unintentional doping by defects or impurities. The type and concentration of impurities determine the value of the Fermi energy, or level, within the gap between the conduction band minimum and valance band maximum energies. The Fermi energy characterizes the statistical occupation of molecular quantum energy states denoted by the value of energy for which the probability of occupation is equal to ½. A Fermi energy near the conduction band minimum energy indicates that electrons are the predominant carrier. A Fermi energy near the valence band maximum energy indicates that holes are the predominant carrier. Accordingly, the Fermi energy is a primary characterizing property of traditional semiconductors and the prototypical PV junction has traditionally been the p-n interface.

The term “rectifying” denotes, inter alia, that an interface has an asymmetric conduction characteristic, i.e., the interface supports electronic charge transport preferably in one direction. Rectification is associated normally with a built-in electric field which occurs at the junction between appropriately selected materials.

In the context of organic materials, the terms “donor” and “acceptor” refer to the relative positions of the HOMO and LUMO energy levels of two contacting but different organic materials. This is in contrast to the use of these terms in the inorganic context, where “donor” and “acceptor” may refer to types of dopants that may be used to create inorganic n- and p-types layers, respectively. In the organic context, if the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

A significant property in organic semiconductors is carrier mobility. Mobility measures the ease with which a charge carrier can move through a conducting material in response to an electric field. In the context of organic photosensitive devices, a layer including a material that conducts preferentially by electrons due to a high electron mobility may be referred to as an electron transport layer, or ETL. A layer including a material that conducts preferentially by holes due to a high hole mobility may be referred to as a hole transport layer, or HTL. In one embodiment, an acceptor material is an ETL and a donor material is a HTL.

Conventional inorganic semiconductor PV cells employ a p-n junction to establish an internal field. Early organic thin film cell, such as reported by Tang, Appl. Phys Lett. 48, 183 (1986), contain a heterojunction analogous to that employed in a conventional inorganic PV cell. However, it is now recognized that in addition to the establishment of a p-n type junction, the energy level offset of the heterojunction also plays an important role. The energy level offset at the organic D-A heterojunction is believed to be important to the operation of organic PV devices due to the fundamental nature of the photogeneration process in organic materials. Upon optical excitation of an organic material, localized Frenkel or charge-transfer excitons are generated. For electrical detection or current generation to occur, the bound excitons must be dissociated into their constituent electrons and holes. Such a process can be induced by the built-in electric field, but the efficiency at the electric fields typically found in organic devices (F˜10⁶ V/cm) is low. The most efficient exciton dissociation in organic materials occurs at a donor-acceptor (D-A) interface. At such an interface, the donor material with a low ionization potential forms a heterojunction with an acceptor material with a high electron affinity. Depending on the alignment of the energy levels of the donor and acceptor materials, the dissociation of the exciton can become energetically favorable at such an interface, leading to a free electron polaron in the acceptor material and a free hole polaron in the donor material.

Organic PV cells have many potential advantages when compared to traditional silicon-based devices. Organic PV cells are light weight, economical in materials use, and can be deposited on low cost substrates, such as flexible plastic foils. However, organic PV devices typically have relatively low external quantum efficiency (electromagnetic radiation to electricity conversion efficiency), being on the order of 1% or less. This is, in part, thought to be due to the second order nature of the intrinsic photoconductive process. That is, carrier generation requires exciton generation, diffusion and ionization or collection. There is an efficiency r associated with each of these processes. Subscripts may be used as follows: P for power efficiency, EXT for external quantum efficiency, A for photon absorption exciton generation, ED for diffusion, CC for collection, and INT for internal quantum efficiency. Using this notation:

η_{P}˜η_{EXT}=η_{A}*η_{ED}*η_{CC}

η_{EXT}=η_{A}*η_{INT}

The diffusion length (L_{D}) of an exciton is typically much less (L_{D}˜50Δ) than the optical absorption length (˜500Δ), requiring a tradeoff between using a thick, and therefore resistive, cell with multiple or highly folded interfaces, or a thin cell with a low optical absorption efficiency.

While favorable absorption and charge mobility characteristics make polymer organic PVs among the most highly efficient organic PV devices, polymer organic PVs may have several drawbacks. For example, polymers can be harder to synthesize, less predictable in terms of morphology, and not sublimable. Thus, there is a continuing need to develop new classes of compounds for photovoltaic applications.

Disclosed herein is a new class of 4,4-difluoro-4-bora-3a,4a-diaza-s-indacene (BODIPY) dyes for use in organic optoelectronic devices, particularly PVs. Thus, the present disclosure provides an organic photosensitive optoelectronic device comprising at least one compound of formula (I):

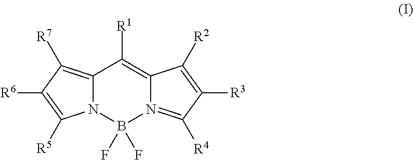

wherein: R¹ is chosen from an optionally substituted monocyclic group, an optionally substituted C₆₋₂₄ multicyclic group, and an optionally substituted meso-linked BODIPY, or R¹ and R² and R⁷ taken together with any intervening atoms comprise a substituted BODIPY, wherein R¹ is meso-linked and R² and R⁷ are beta-linked;

R² is chosen from hydrogen, an alkyl group, and a cyano group, or R² and R³ taken together with any intervening atoms comprise a group chosen from an optionally substituted monocyclic group and an optionally substituted C₆₋₂₄ multicyclic group, or R² and R¹ and R⁷ taken together with any intervening atoms comprise a substituted BODIPY, wherein R¹ is meso-linked and R² and R⁷ are beta-linked;

R³ is chosen from hydrogen, an alkyl group, and a cyano group, or R³ and R² taken together with any intervening atoms comprise a group chosen from an optionally substituted monocyclic group and an optionally substituted C₆₋₂₄ multicyclic group, or R³ and R⁴ taken together with any intervening atoms comprise a group chosen from an optionally substituted monocyclic group and an optionally substituted C₆₋₂₄ multicyclic group;

R⁴ is chosen from hydrogen, an alkyl group, and a cyano group, or R⁴ and R³ taken together with any intervening atoms comprise a group chosen from an optionally substituted monocyclic group and an optionally substituted C₆₋₂₄ multicyclic group;

R⁵ is chosen from hydrogen, an alkyl group, and a cyano group, or R⁵ and R⁶ taken together with any intervening atoms comprise a group chosen from an optionally substituted monocyclic group and an optionally substituted C₆₋₂₄ multicyclic group;

R⁶ is chosen from hydrogen, an alkyl group, and a cyano group, or R⁶ and R⁵ taken together with any intervening atoms comprise a group chosen from an optionally substituted monocyclic group and an optionally substituted C₆₋₂₄ multicyclic group, or R⁶ and R⁷ taken together with any intervening atoms comprise a group chosen from an optionally substituted monocyclic group and an optionally substituted C₆₋₂₄ multicyclic group; and

R⁷ is chosen from hydrogen, an alkyl group, and a cyano group, or R⁷ and R⁶ taken together with any intervening atoms comprise a group chosen from an optionally substituted monocyclic group and an optionally substituted C₆₋₂₄ multicyclic group, or R⁷ and R¹ and R² taken together with any intervening atoms comprise a substituted BODIPY, wherein R¹ is meso-linked and R² and R⁷ are beta-linked; and wherein the optionally substituted monocyclic and multicyclic groups are chosen from aryl and heteroaryl groups.

In some embodiments, R¹ is chosen from optionally substituted benzene and optionally substituted fused benzene.

In some embodiments, R² and R³ taken together with any intervening atoms, and R⁶ and R⁷ taken together with any intervening atoms, both comprise a group chosen from an optionally substituted monocyclic group and an optionally substituted C₆₋₂₄ multicyclic group, wherein the optionally substituted monocyclic and multicyclic groups are chosen from aryl and heteroaryl groups.

In some embodiments, R³ and R⁴ taken together with any intervening atoms, and R⁵ and R⁶ taken together with any intervening atoms, both comprise a group chosen from an optionally substituted monocyclic group and an optionally substituted C₆₋₂₄ multicyclic group, wherein the optionally substituted monocyclic and multicyclic groups are chosen from aryl and heteroaryl groups.

In some embodiments, R² and R⁷ are both chosen from hydrogen, an alkyl group, and a cyano group.

In some embodiments, R⁵ and R⁴ are both chosen from hydrogen, an alkyl group, and a cyano group.

In some embodiments, R³ and R⁶ are both chosen from hydrogen, an alkyl group, and a cyano group.

In some embodiments, R², R³, R⁴, R⁵, R⁶, and R⁷ are all chosen from hydrogen, an alkyl group, and a cyano group.

The present disclosure also provides methods for making the photosensitive optoelectronic devices of the present disclosure. In some embodiments, the method comprises depositing a photoactive region over a substrate, wherein the photoactive region comprises at least one compound of formula (I). In some embodiments, the photoactive region comprises a donor material and an acceptor material, wherein at least one of the donor and acceptor materials comprise at least one compound of formula (I).

In addition, photoinduced electron transfer reactions are important for energy storage processes in both biological and photovoltaic systems. Interfacial charge separation is a step in the generation of free carriers in OPVs. In the photosynthetic reaction center, electron transfer from the “special pair” is preceded by ultrafast formation of an intradimer charge-transfer state via symmetry breaking. In principle, the same sort of symmetry-breaking strategy could be used to facilitate the generation of free carriers in OPVs, but has not been utilized due to several important limitations. First, in order to form an intramolecular charge-transfer (ICT) state akin to the intradimer Charge Transfer (CT) state in Photosystem II, there must be a driving force for the formation of a CT state. Second, candidate molecules must combine strong absorption of light at visible wavelengths with an ability to undergo symmetry-breaking ICT. There are few dimeric molecules that meet these criteria. To date, the best studied system of this sort is 9,9′-bianthryl. However, 9,9′-bianthryl predominantly absorbs ultraviolet light.

As previously described in the literature, involvement of symmetry-breaking CT states can facilitate charge separation with minimal energy loss and slow recombination. This is likely the reason why the photosynthetic reaction center initiates its electron-transfer cascade with the fast (picosecond) formation of an intradimer CT state. Thus, a minimal-energy-loss mechanism could be useful for maximizing open-circuit voltage in OPVs. However, due to the low diffusivity of CT excitons in neat films, the use of standard donor/acceptor compounds in thin film photovoltaics has proven to be less desirable.

Therefore, there is also a present need to develop compounds having accessible symmetry-breaking ICT states, since such states generally only form in polarizing environments. The archetypical example of such a molecule is 9,9′-bianthryl, which forms a normal singlet excited state (S₁) in nonpolar solvents but undergoes ultrafast solvent-induced ICT in more polar environments.

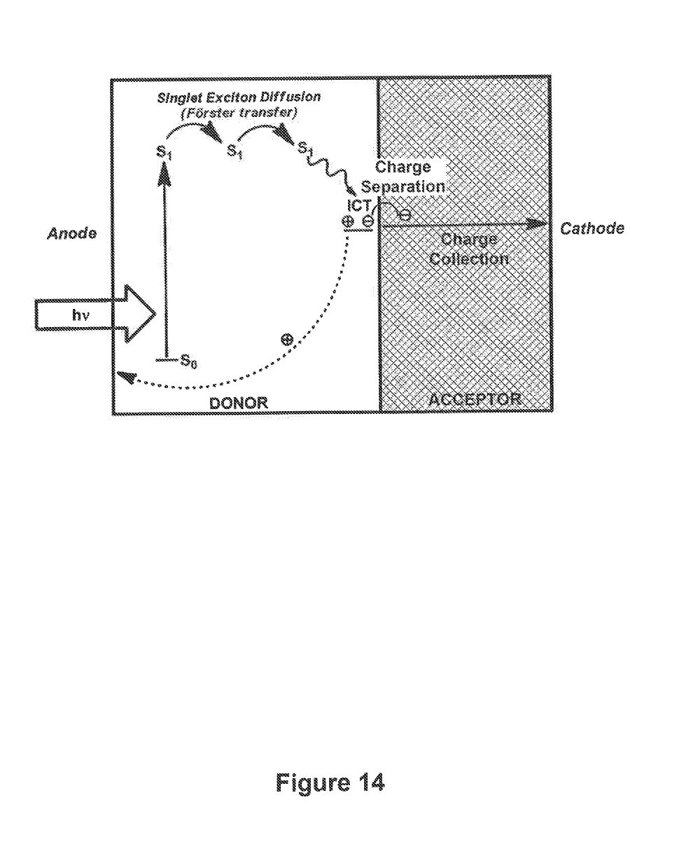

Without wishing to be bound by theory, it is believed that molecules that undergo symmetry-breaking ICT in polar environments will allow excitation energy to move quickly and over long distances through the bulk material in neat films by Forster energy transfer processes before internal conversion to an ICT state by symmetry breaking at the polarizing donor/acceptor interface (FIG. 14).

Therefore, there is also disclosed an organic photosensitive optoelectronic device comprising at least one higher order compound, such as dyads, triads and tetrads, that are capable of undergoing symmetry-breaking intramolecular charge transfer in a polarizing medium. In one embodiment, the intramolecular charge transfer occurs at a polarizing donor/acceptor interface.

The higher order compounds disclosed herein exhibit a high absorptivity of light in the visible and near infrared spectrum. In at least one embodiment, “high absorptivity of light” includes absorptivity of >10⁴ M⁻¹ cm⁻¹ at one or more visible to near infrared wavelengths ranging from 350 to 1500 nm.

In some embodiments, the higher order compound forms at least one donor and/or acceptor region in a donor-acceptor heterojunction. In some embodiments, the donor-acceptor heterojunction absorbs photons to form excitons.

In some embodiments, the device is an organic device, such as an organic photodetector, an organic solar cell, or an organic laser.

There are also disclosed methods of making an organic photosensitive optoelectronic device comprising a higher order compound. In one embodiment, the device may be an organic photodetector, in another an organic solar cell.

The foregoing and other features of the present disclosure will be more readily apparent from the following detailed description of exemplary embodiments, taken in conjunction with the attached drawings. It will be noted that, for convenience, all illustrations of devices show the height dimension exaggerated in relation to the width.

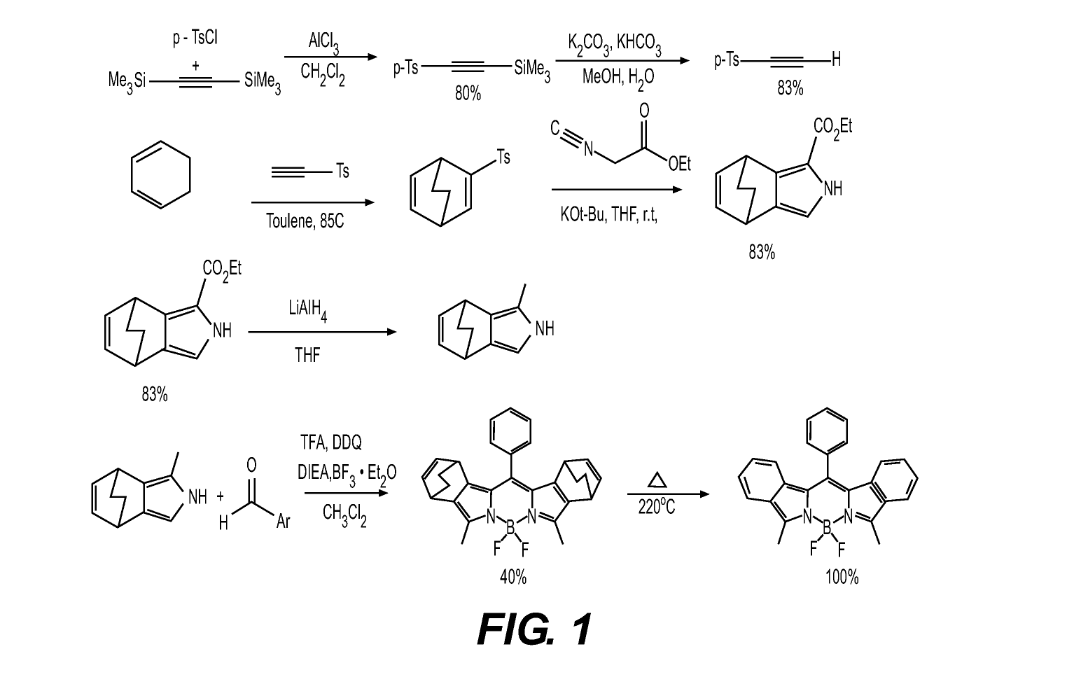

FIG. 1 depicts a scheme for synthesizing BenzoBODIPY.

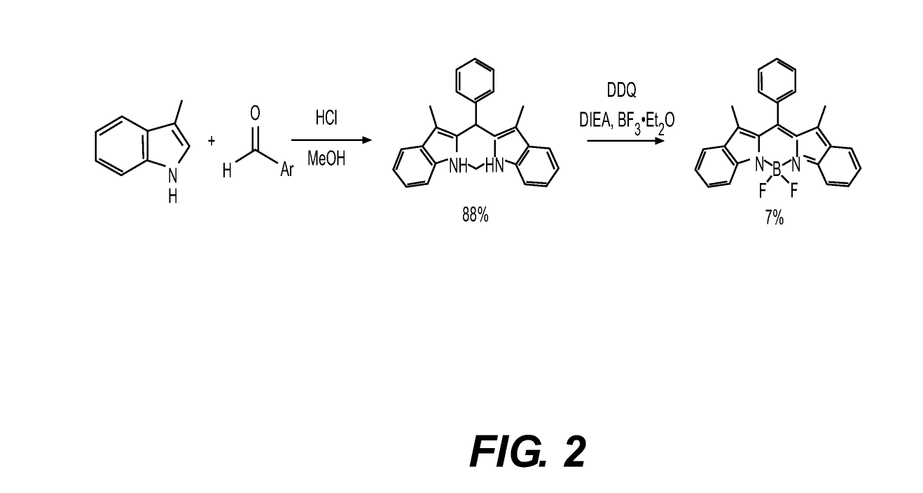

FIG. 2 depicts a scheme for synthesizing IndoBODIPY.

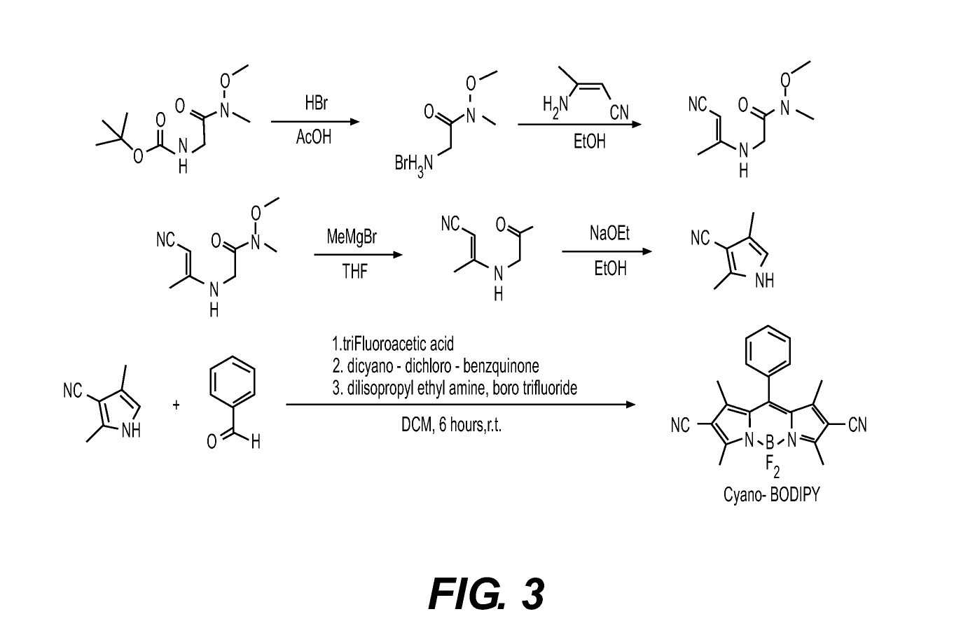

FIG. 3 depicts a scheme for synthesizing CyanoBODIPY.

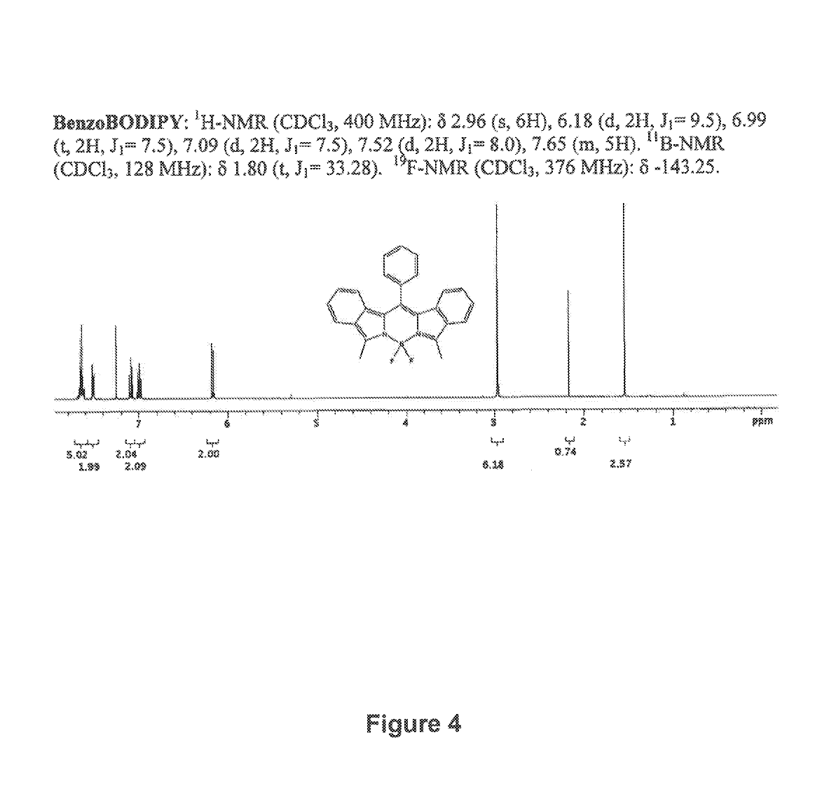

FIG. 4 provides Nuclear Magnetic Resonance (NMR) data for BenzoBODIPY.

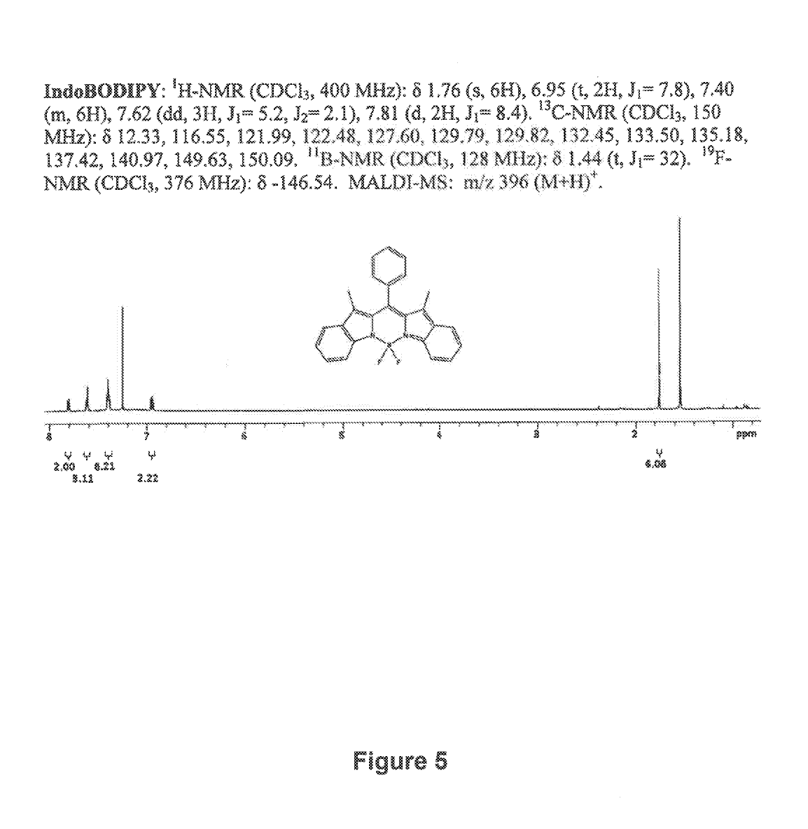

FIG. 5 provides NMR data for IndoBODIPY.

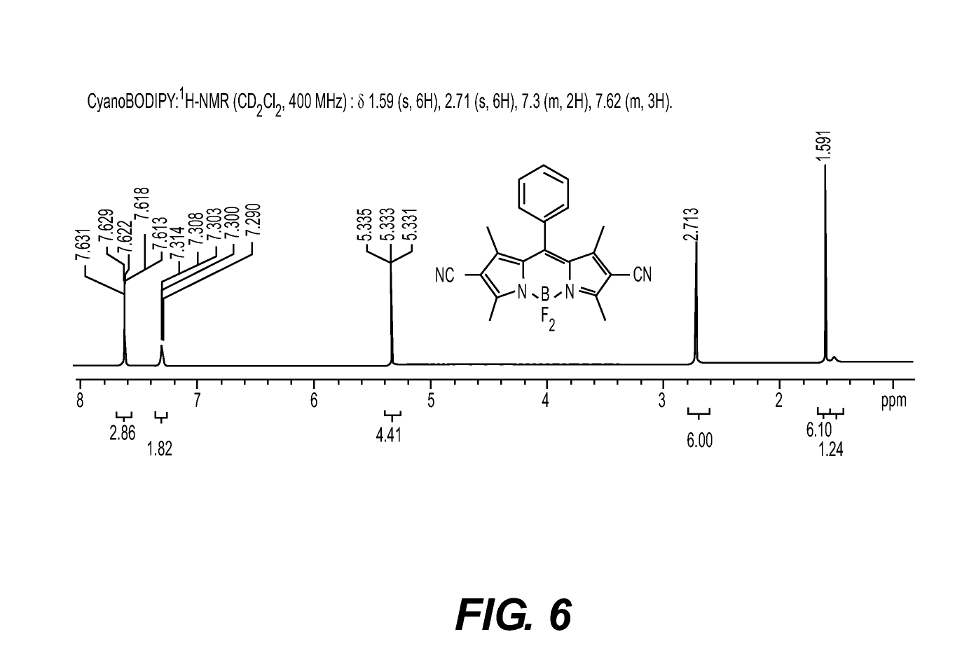

FIG. 6 provides NMR data for CyanoBODIPY.

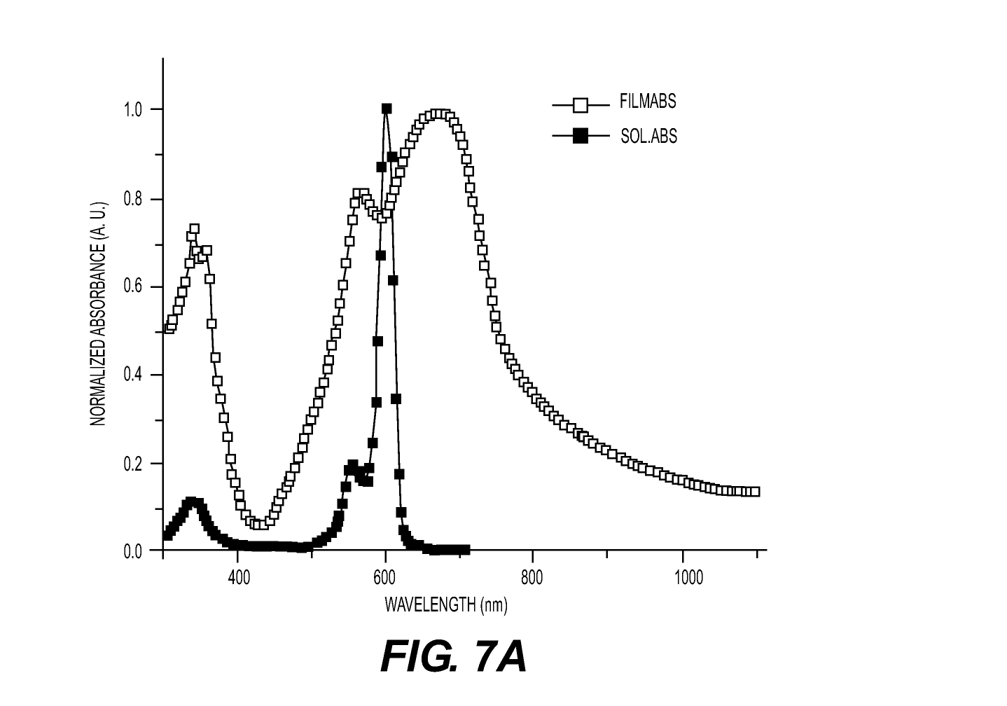

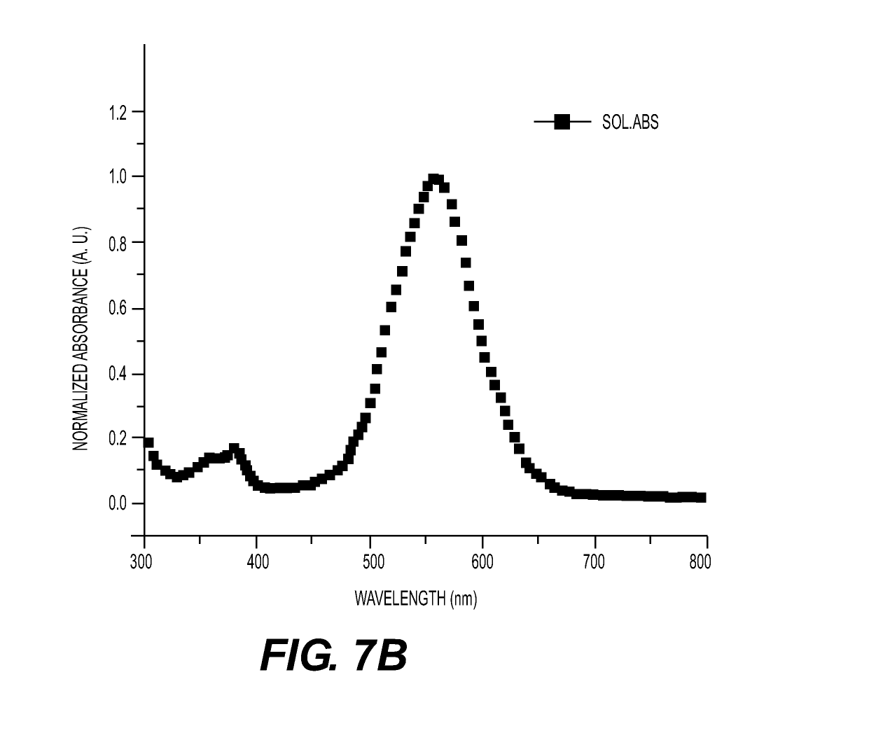

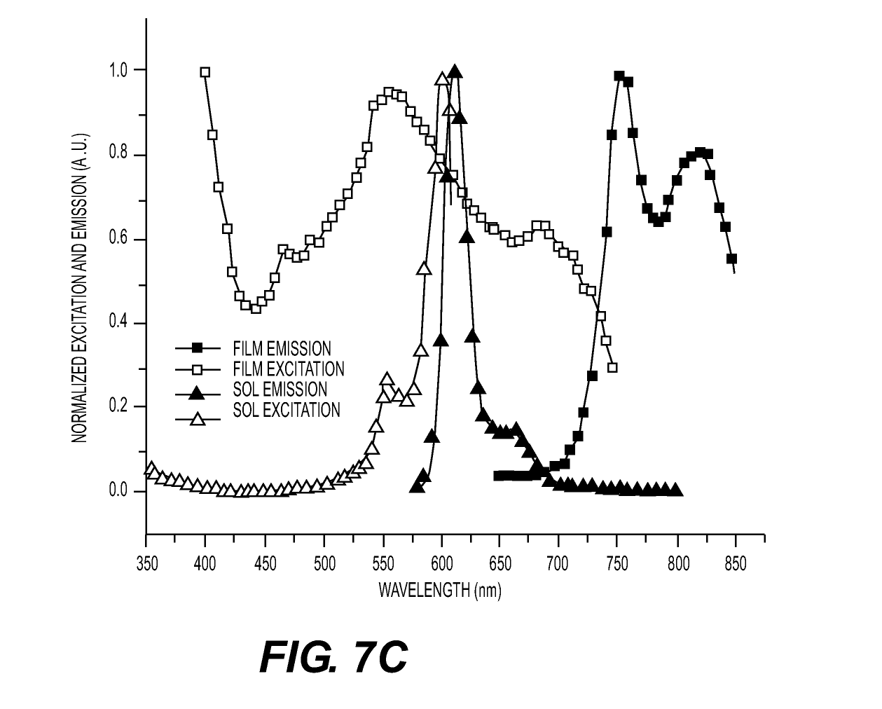

FIG. 7A shows absorption spectra for synthesized BenzoBODIPY in its solution and solid states.

FIG. 7B shows an absorption spectrum for synthesized IndoBODIPY in its solution state.

FIG. 7C shows excitation and emission spectra for BenzoBODIPY in its solution and solid states.

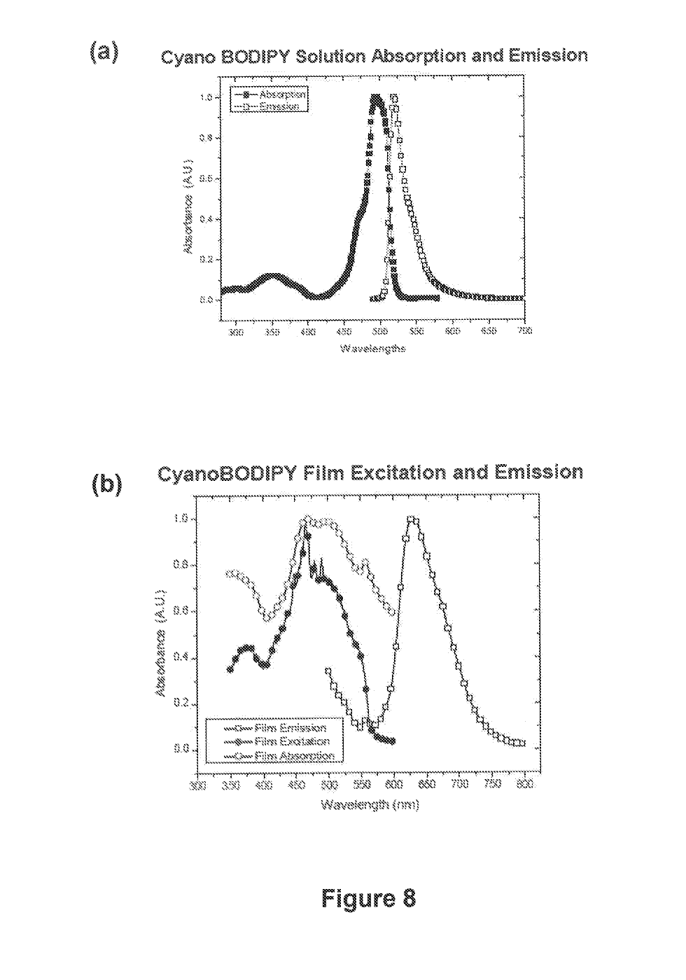

FIG. 8(a) shows solution absorption and emission spectra for CyanoBODIPY.

FIG. 8(b) shows film excitation, emission, and absorption spectra for CyanoBODIPY.

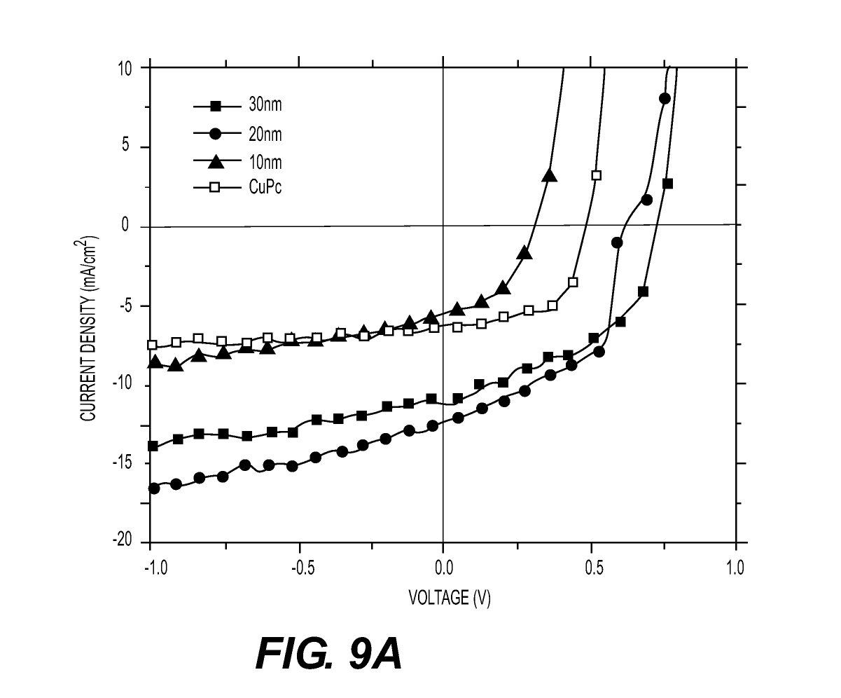

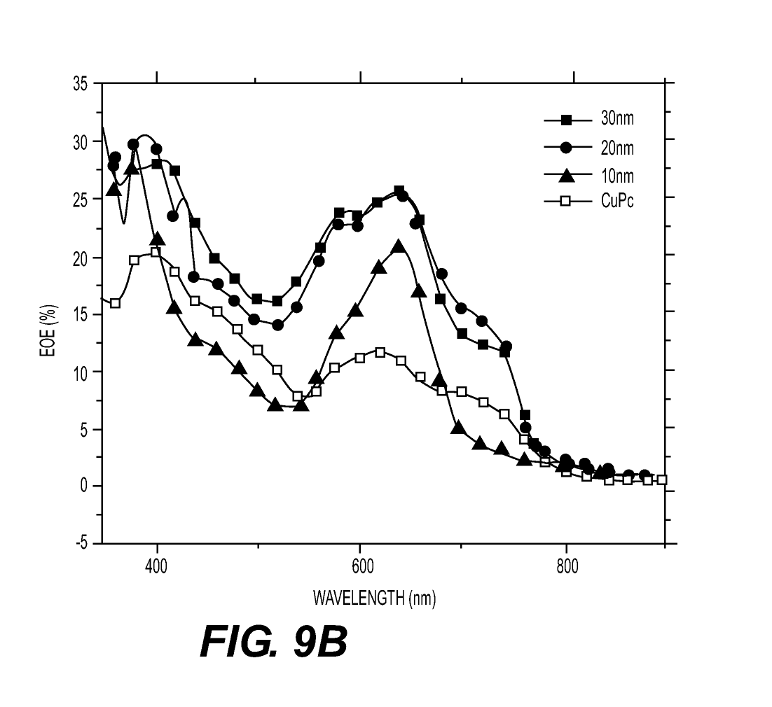

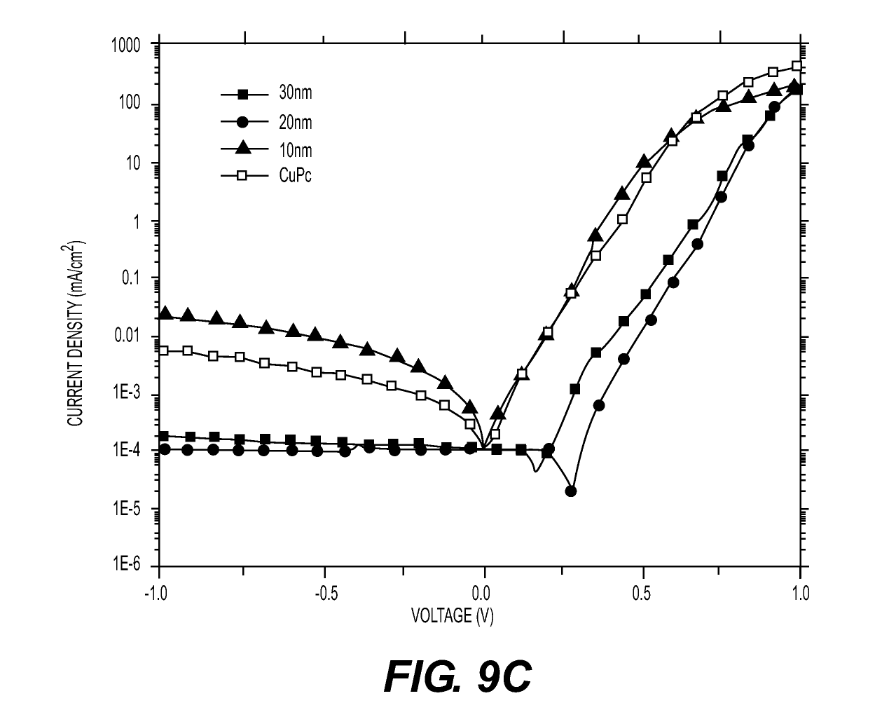

FIGS. 9A, 9B, and 9C show PV performance data of an organic PV using CuPc as the donor material and of organic PVs using BenzoBODIPY as the donor material at various thicknesses. In particular, FIG. 9A shows current-voltage curves, FIG. 9B shows external quantum efficiencies (EQEs), and FIG. 9C shows dark current curves.

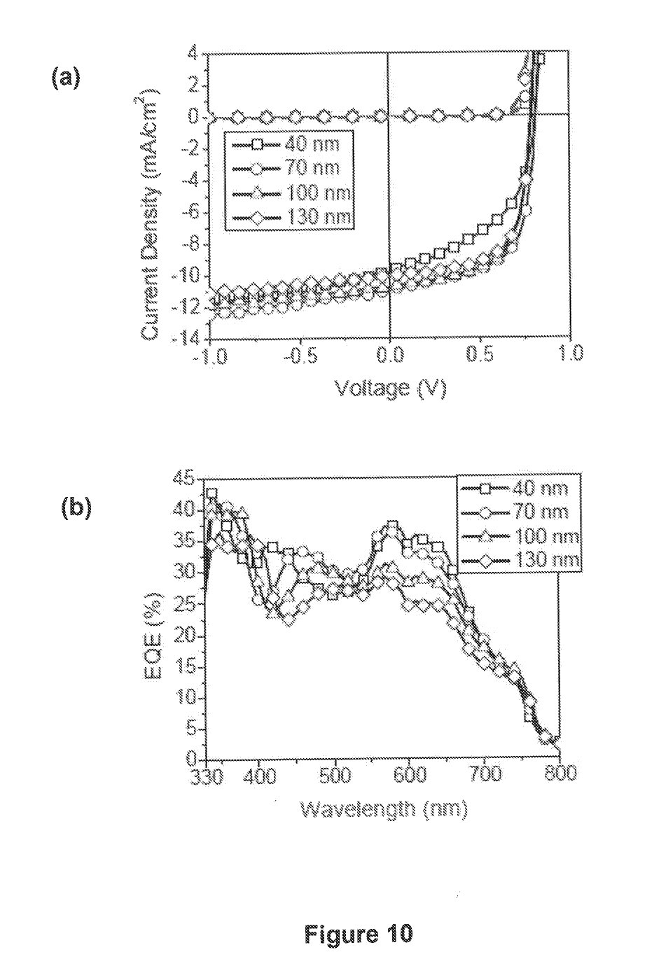

FIGS. 10(a) and 10(b) show additional PV performance data of organic PVs using BenzoBODIPY as the donor material at various thicknesses. In particular, FIG. 10(a) shows current-voltage curves, and FIG. 10(b) shows EQEs.

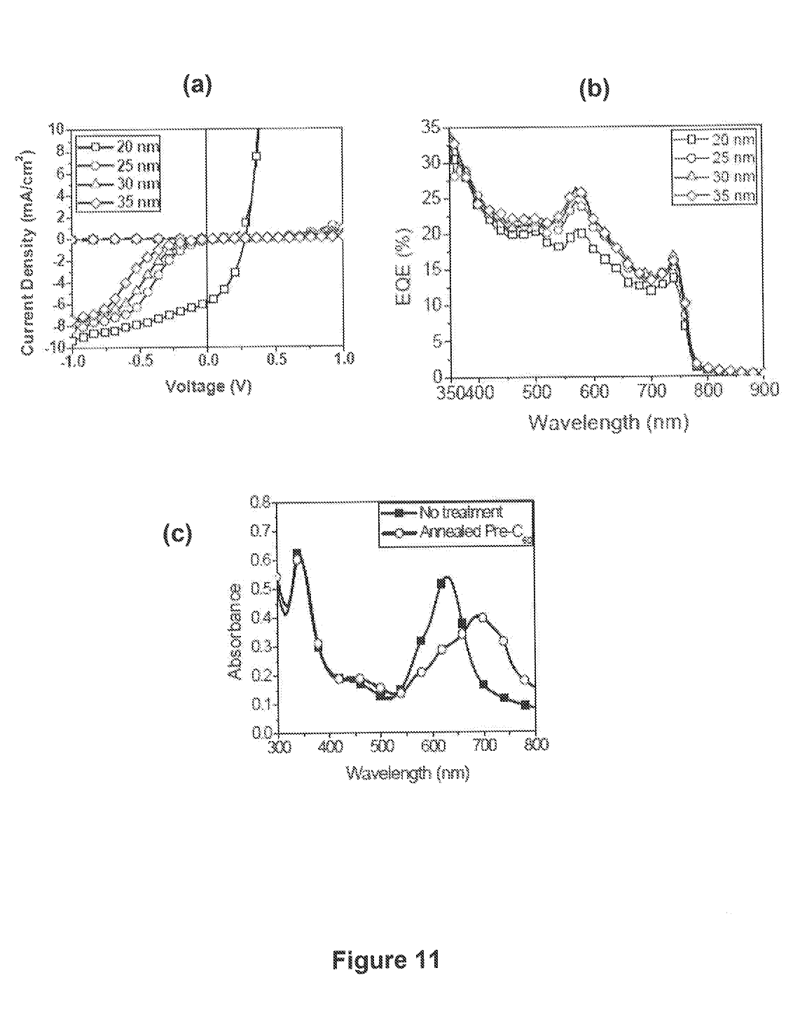

FIGS. 11(a) and 11(b) show PV performance data of organic PVs that were thermally annealed after deposition of the donor layer but prior to deposition of the acceptor material and that used BenzoBODIPY as the donor material at various thicknesses. In particular, FIG. 11(a) shows current-voltage curves, and FIG. 11(b) shows EQEs.

FIG. 11(c) shows absorption spectra for non-treated and thermally treated organic PVs.

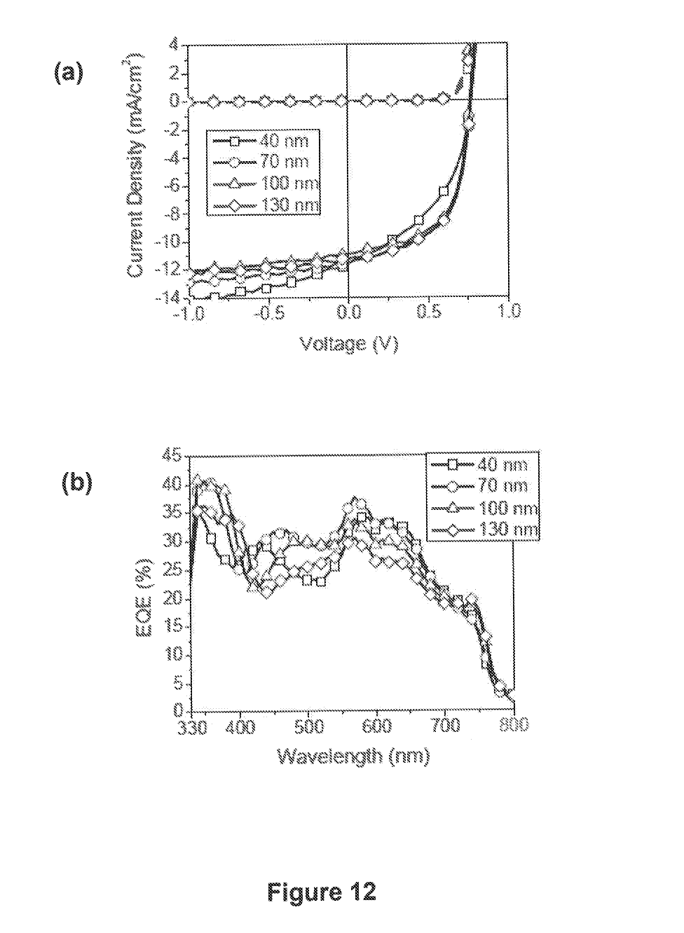

FIGS. 12(a) and 12(b) show PV performance data of organic PVs that were thermally annealed after deposition of the donor and acceptor layers and that used BenzoBODIPY as the donor material at various thicknesses. In particular, FIG. 12(a) shows current-voltage curves, and FIG. 12(b) shows EQEs.

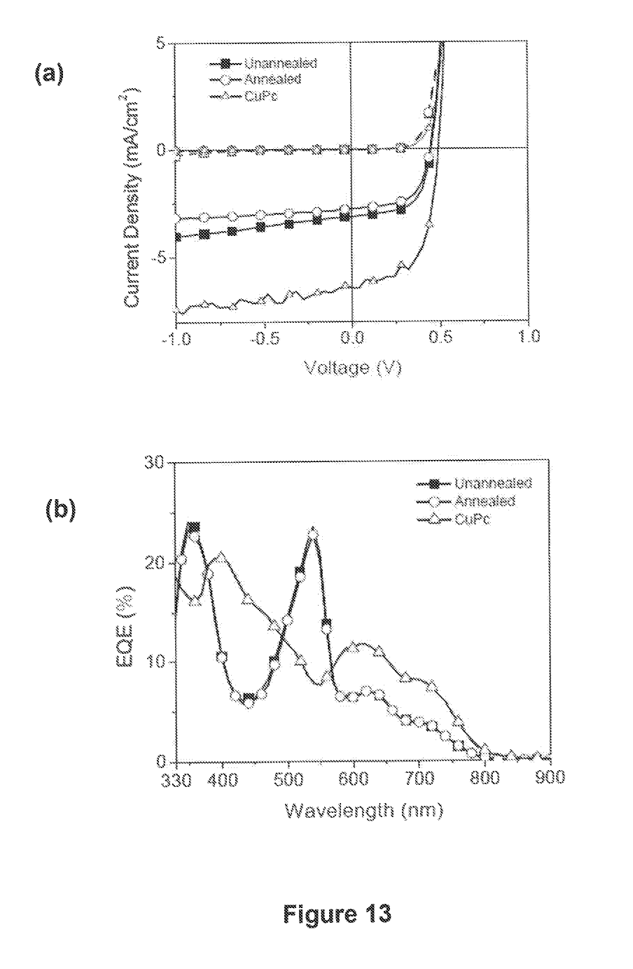

FIGS. 13(a) and 13(b) show PV performance data of an organic PV device using CuPc and C₆₀ as donor and acceptor materials, respectively, and of an organic PV device using CuPc as the donor material and a 1:1 ratio of CyanoBODIPY and C60 as acceptor materials. One CyanoBODIPY device was thermally annealed after deposition of the acceptor layer. FIG. 13(a) shows current-voltage curves and FIG. 13(b) shows EQEs.

FIG. 14 is a schematic representation of symmetry-breaking ICT to facilitate charge separation at a polarizing donor/acceptor interface.

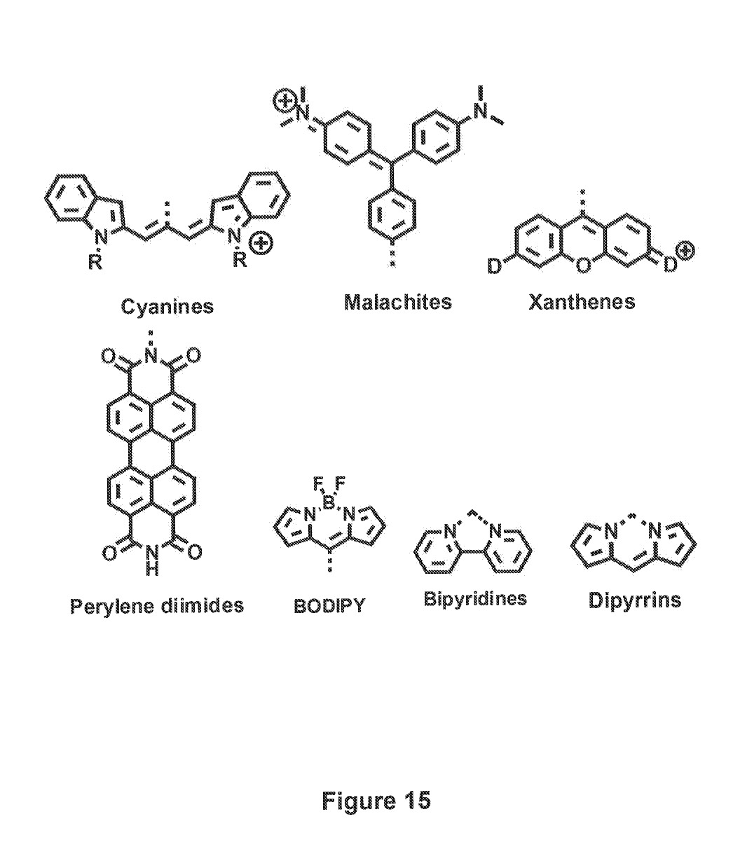

FIG. 15 shows examples of dyes that can be coupled into dimers, trimers, etc. for symmetry breaking ICT.

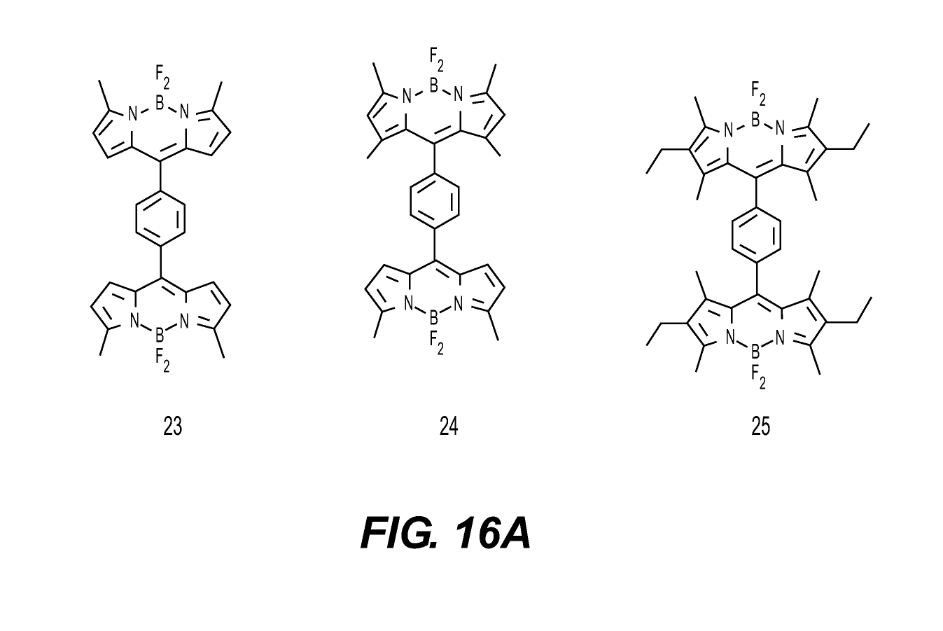

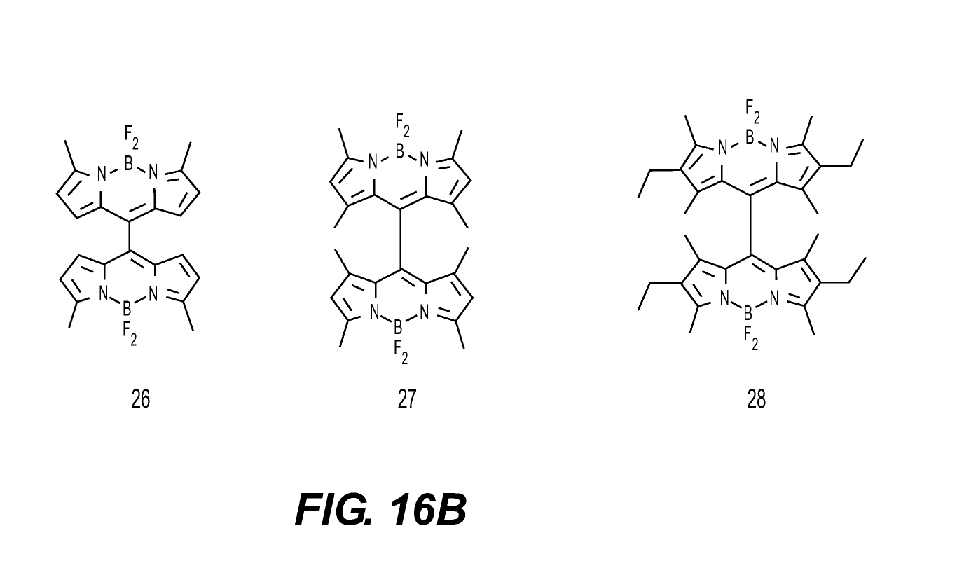

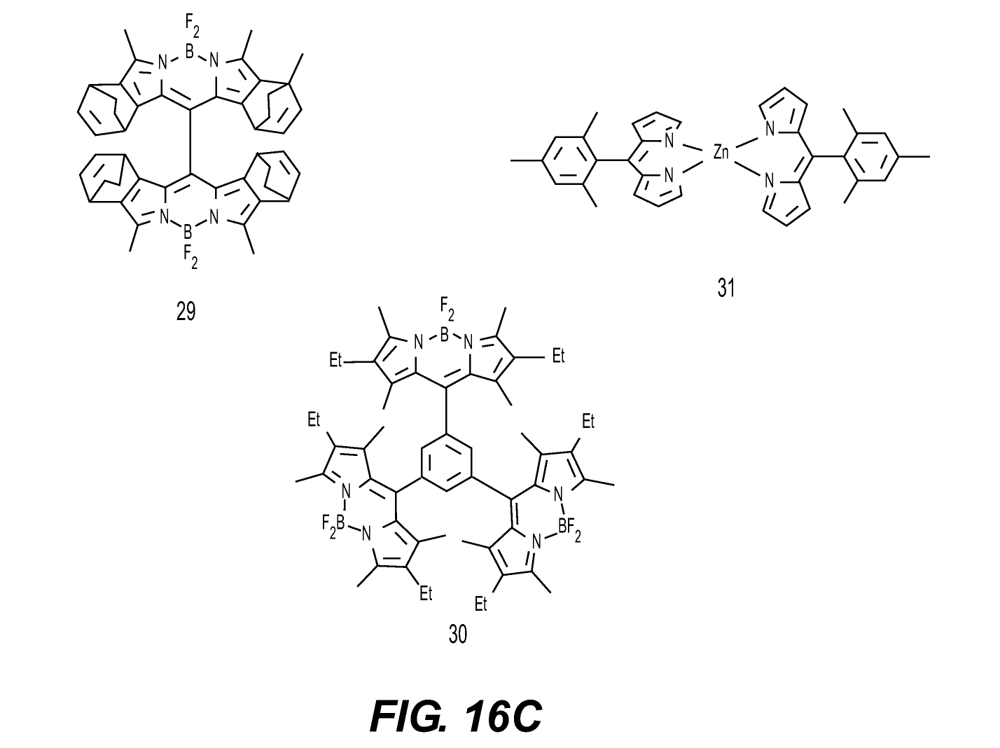

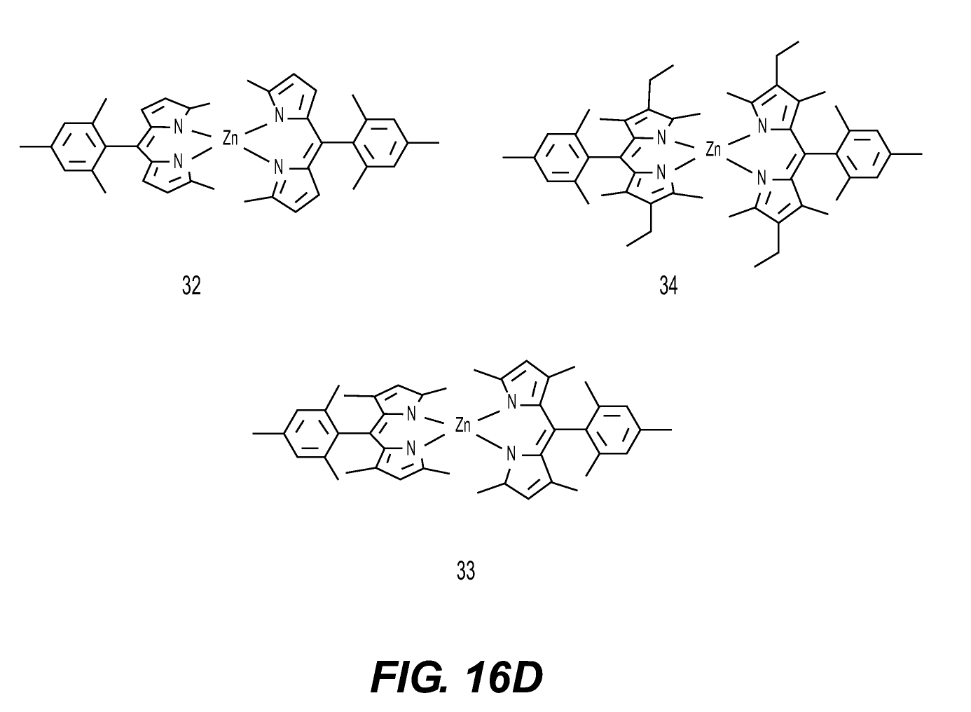

FIGS. 16A, 16B, 16C, and 16D show examples of dipyrrin chromophores synthesized for symmetry breaking ICT.

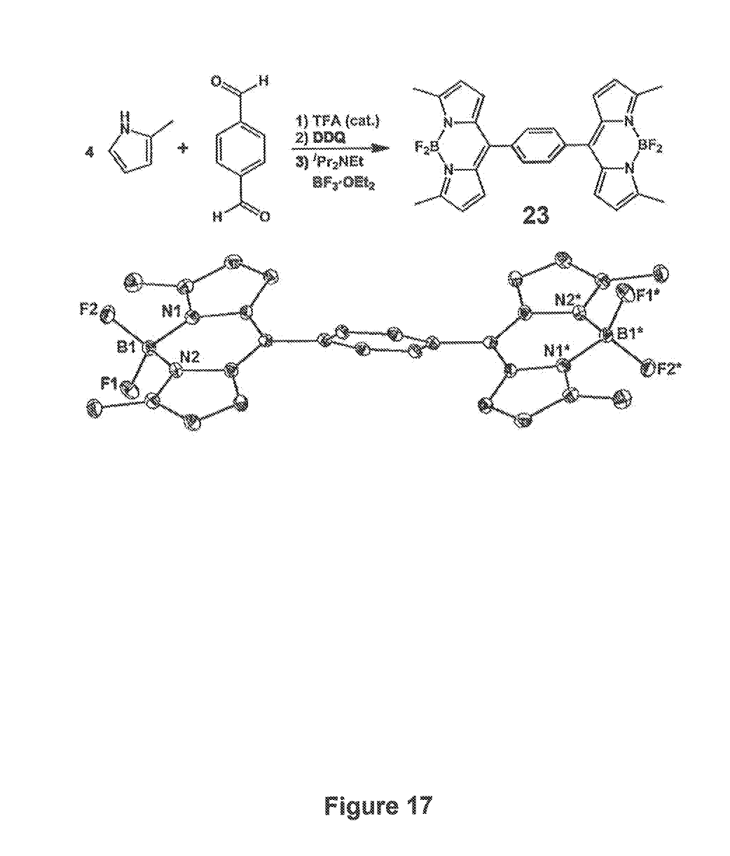

FIG. 17 shows the synthetic scheme and displacement ellipsoid of BODIPY dyad 23 of FIG. 16.

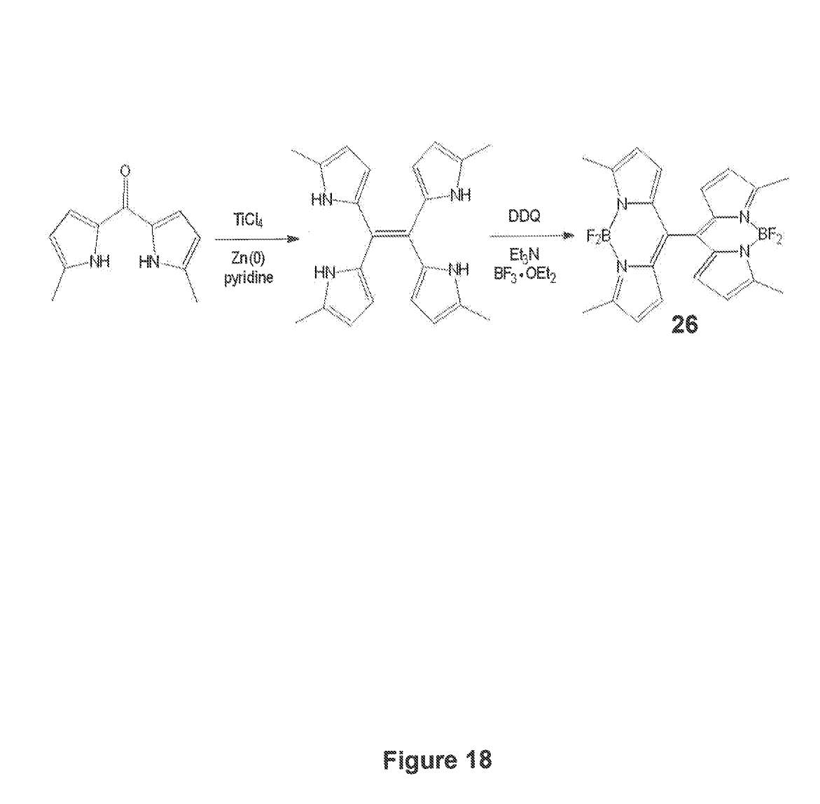

FIG. 18 shows a synthetic scheme for BODIPY dyad 26.

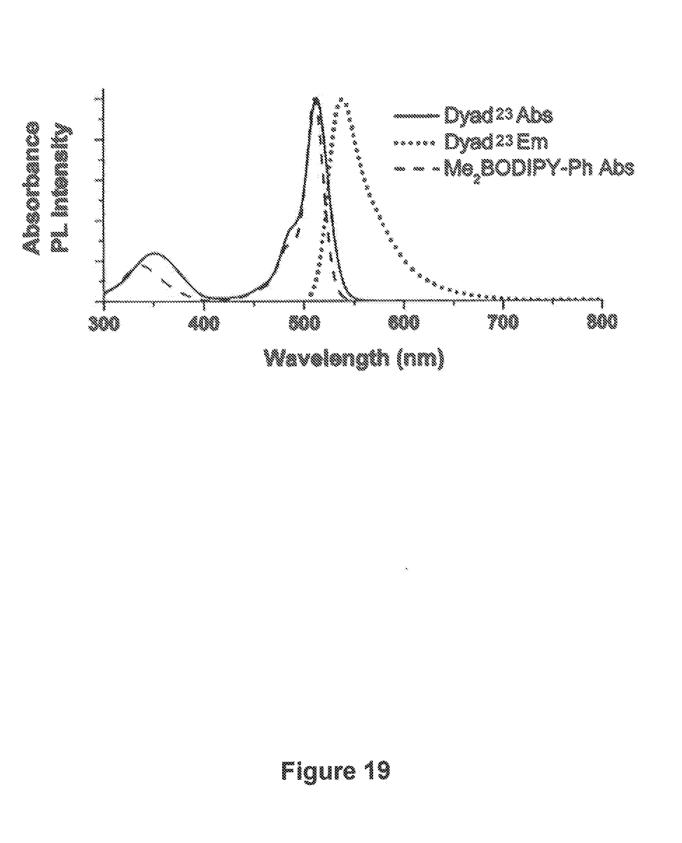

FIG. 19 represents the normalized absorption and emission spectra of dyad 23 and the absorption spectra of 3,5-Me₂BODIPY-Ph in CH₂Cl₂.

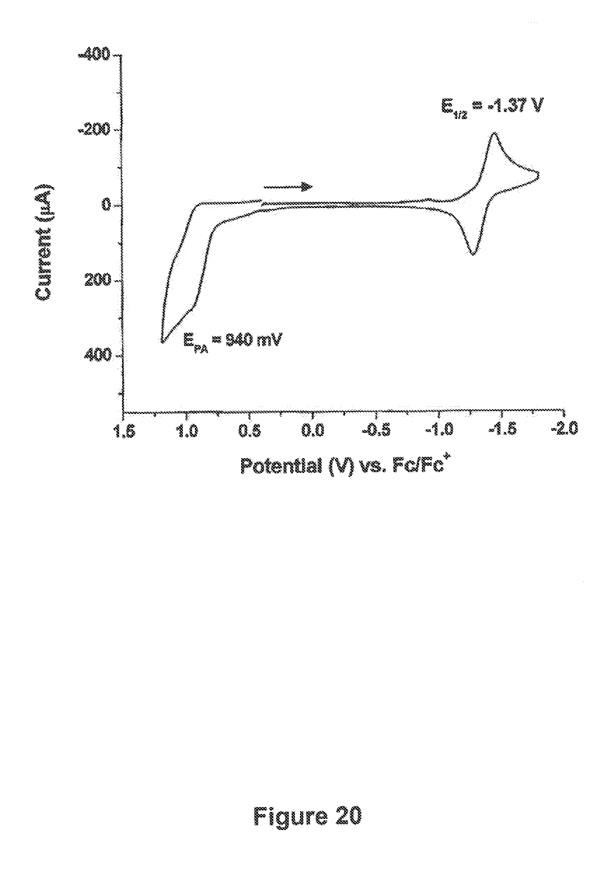

FIG. 20 shows the cyclic voltammetry of dyad 23 in CH₂Cl₂.

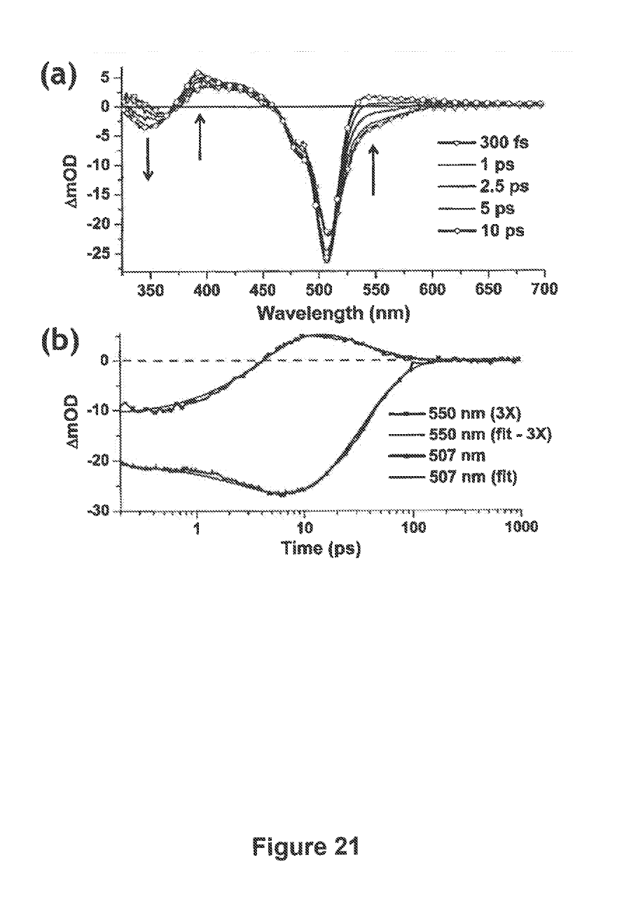

FIGS. 21(a) and 21(b) represent the ultrafast transient absorption spectra of dyad 23 after excitation at 508 nm, and time domain slices of transient absorptions at 507 and 550 nm with predicted traces based on kinetic parameters.

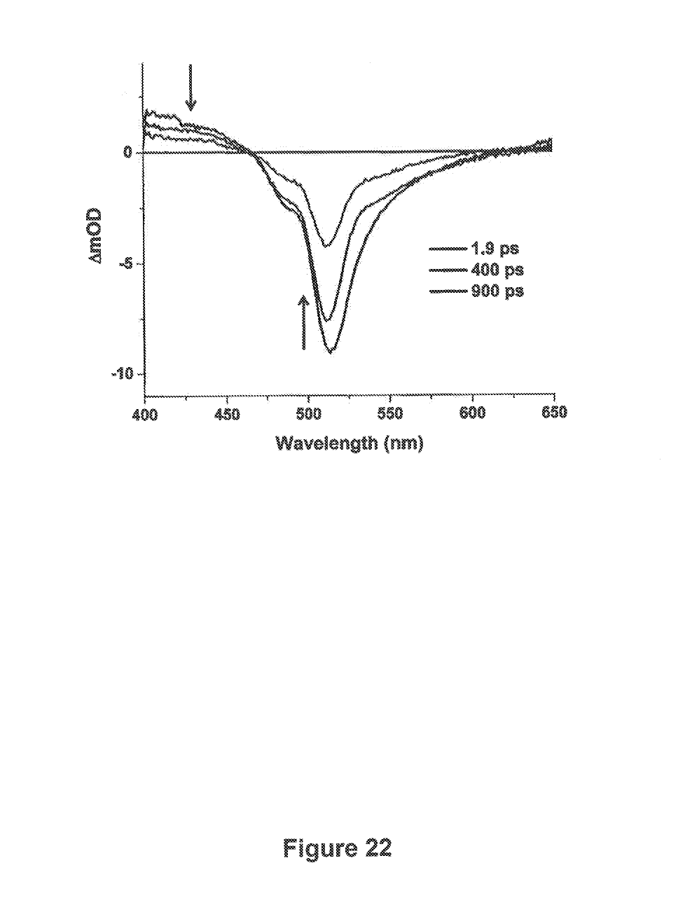

FIG. 22 shows the transient absorption of dyad 23 in toluene.

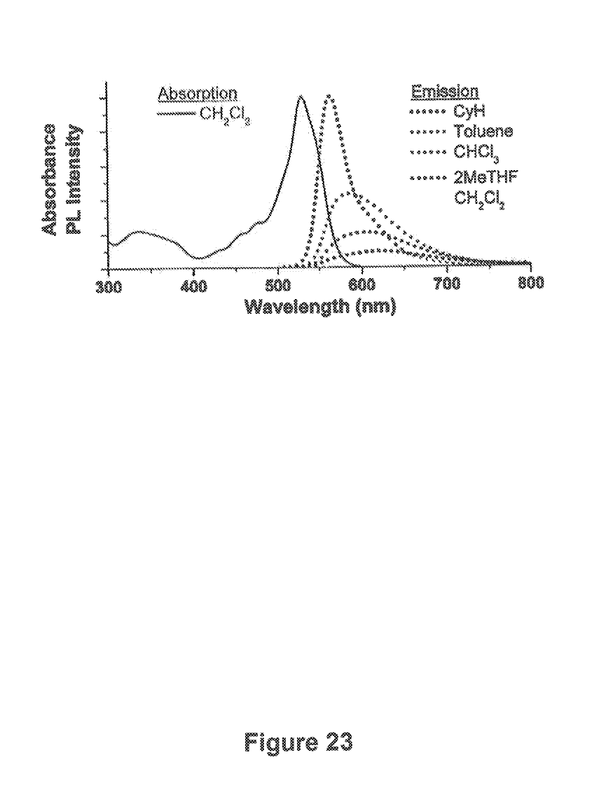

FIG. 23 shows the absorption spectra of dyad 26 in CH₂Cl₂ and emission spectra of 26 in solvents of varying polarity.

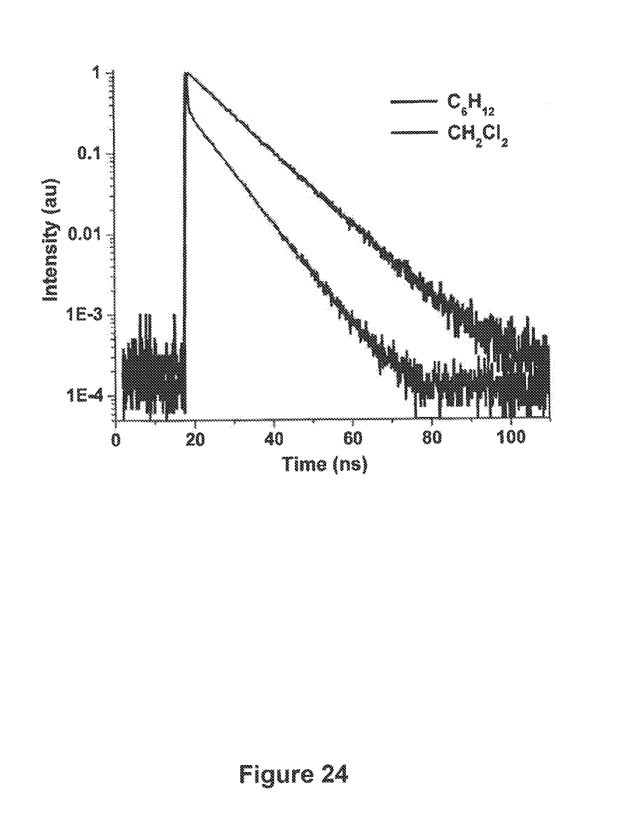

FIG. 24 shows the normalized emission decays of dyad 26 in cyclohexane (564 nm) and CH₂Cl₂ (651 nm) following excitation at 405 nm.

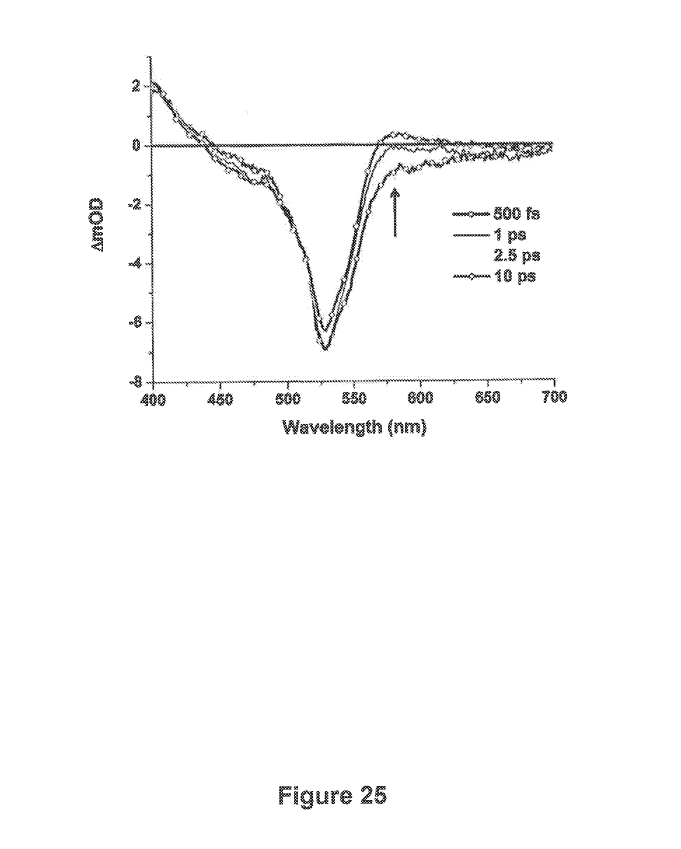

FIG. 25 represents the transient absorption of dyad 26 in CH₂Cl₂.

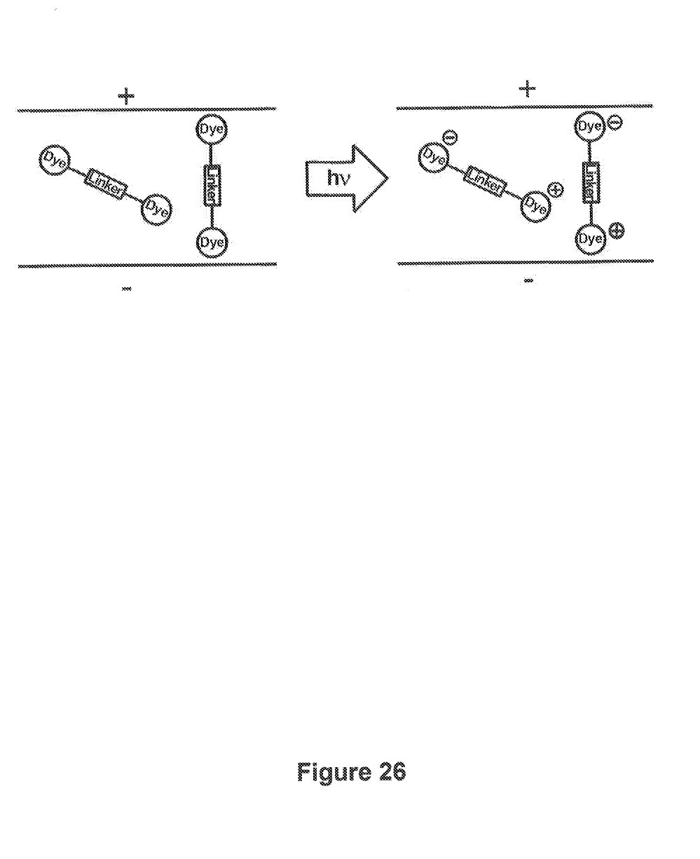

FIG. 26 represents the generation of stabilized intramolecular polaron pairs in the presence of an electric field.

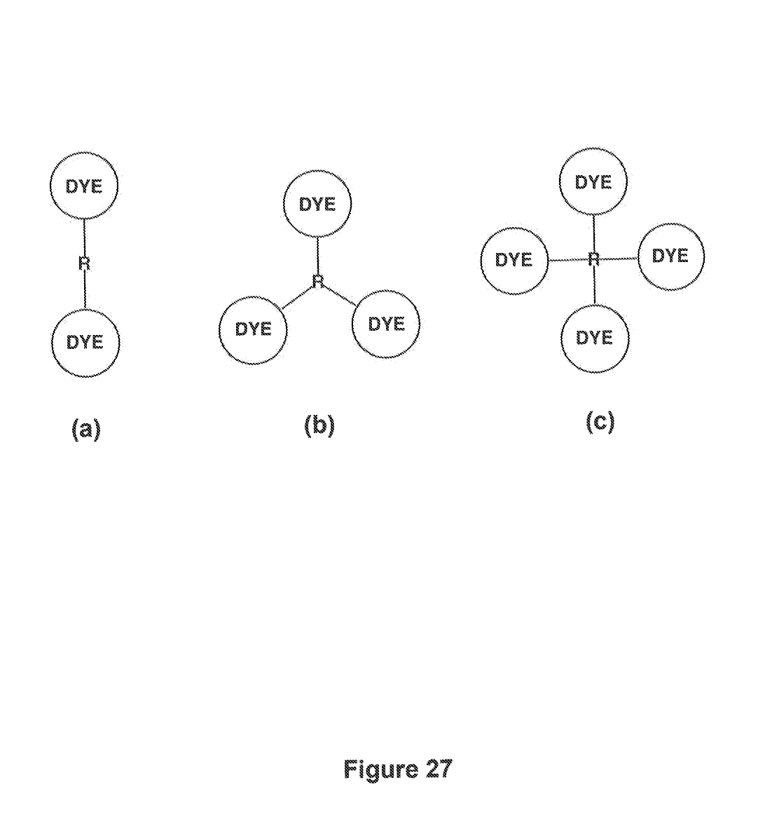

FIG. 27(a), 27(b), and 27(c) represent methods for structuring symmetry-breaking ICT dyads, triads, and tetrads ((a), (b) and (c) respectively) where R represents the linking molecule between the dyes.

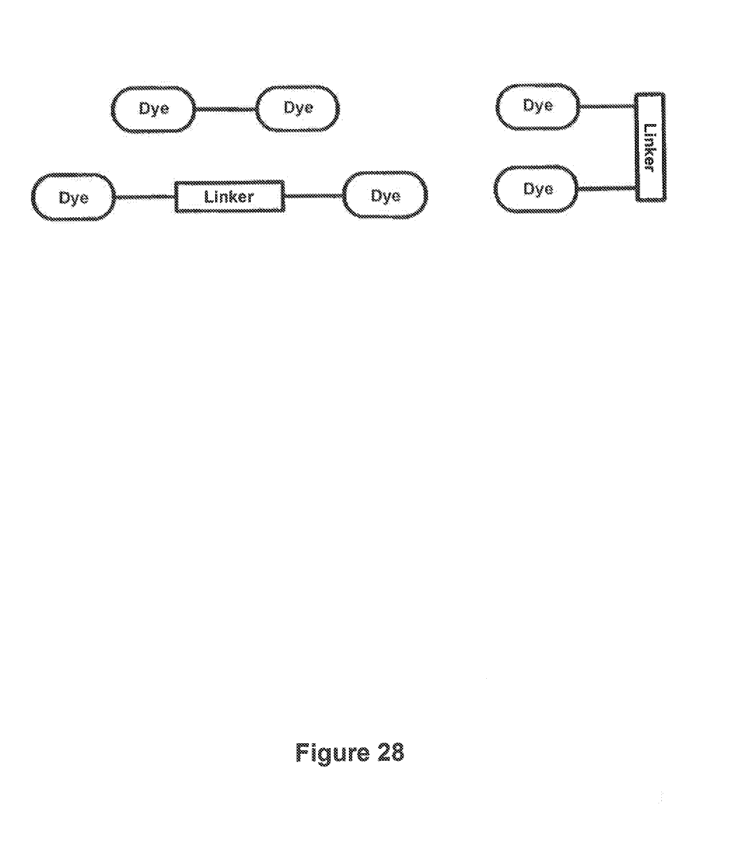

FIG. 28 represents methods for connecting two dyes to facilitate symmetry-breaking ICT.

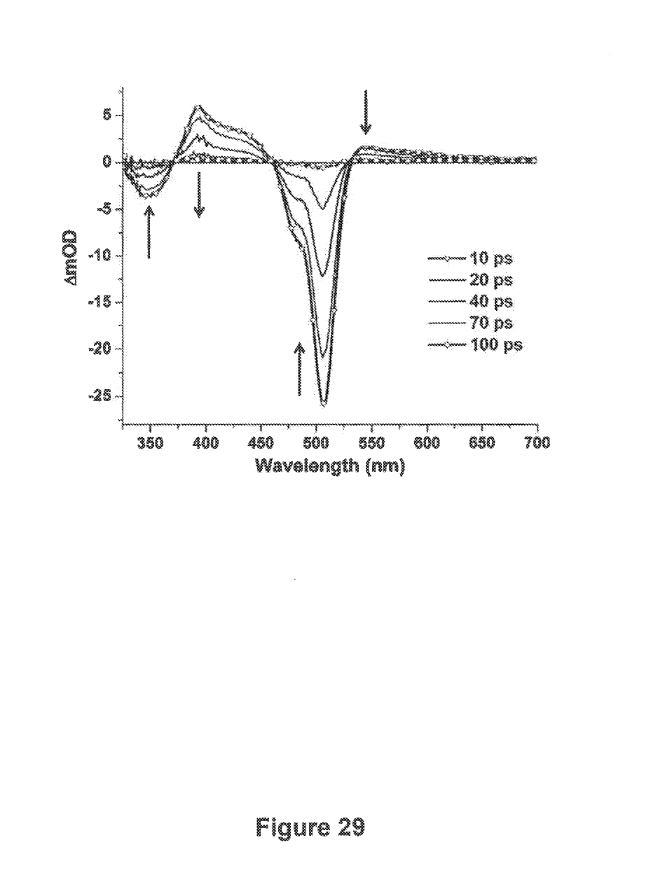

FIG. 29 shows the transient absorption of dyad 23 in acetonitrile with all transient spectral features completely relaxed within ca. 150 ps.

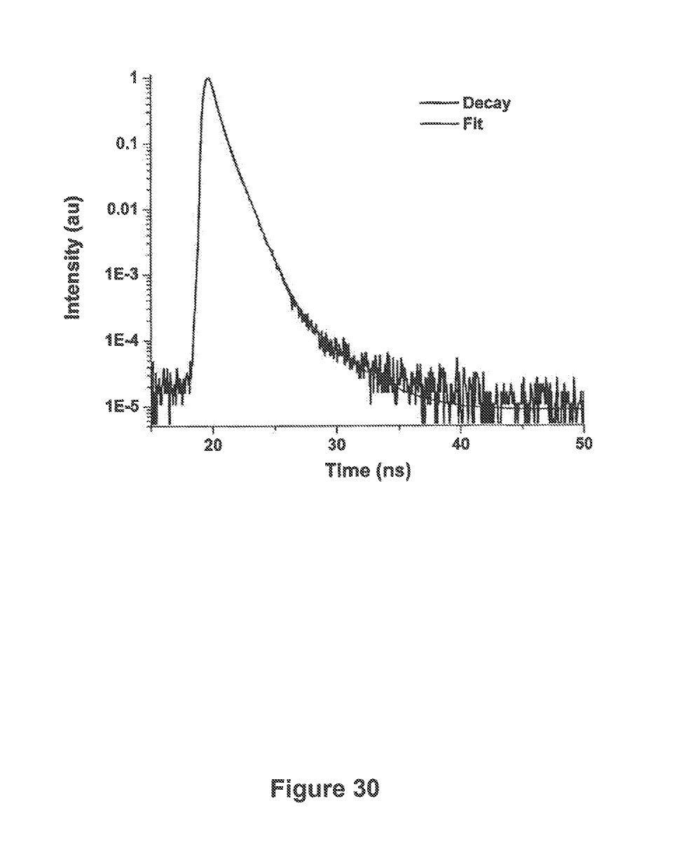

FIG. 30 represents time domain slices of transient absorption of dyad 23 in toluene.

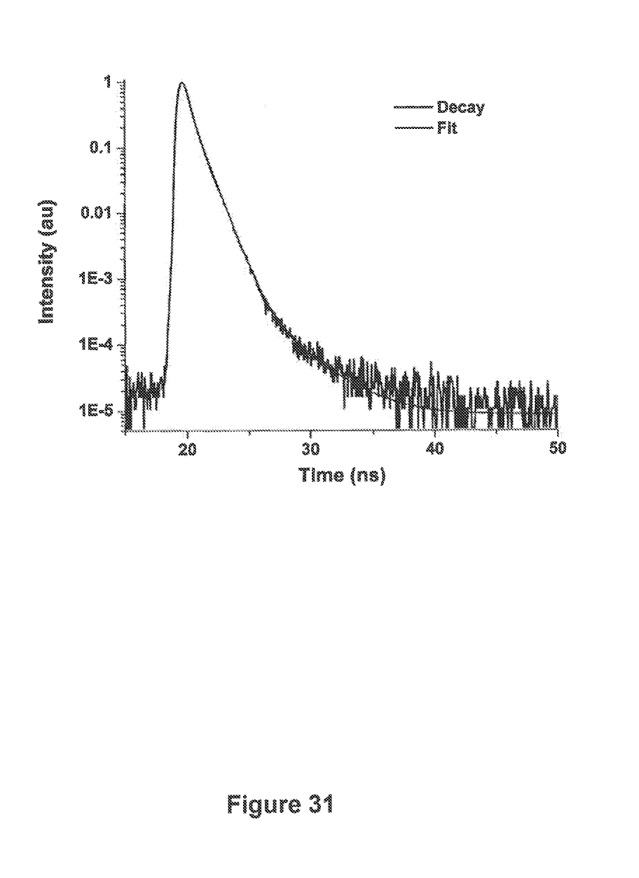

FIG. 31 shows the normalized emission decay of dyad 23 in toluene (535 nm) following excitation at 435 nm.

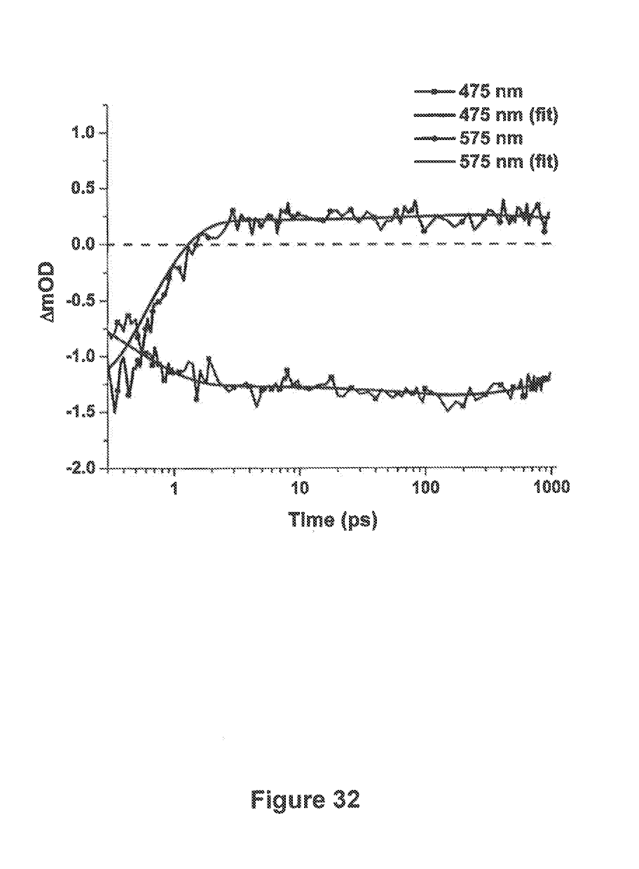

FIG. 32 represent time domain slices of transient absorptions at 475 and 575 nm with predicted traces based on kinetic parameters.

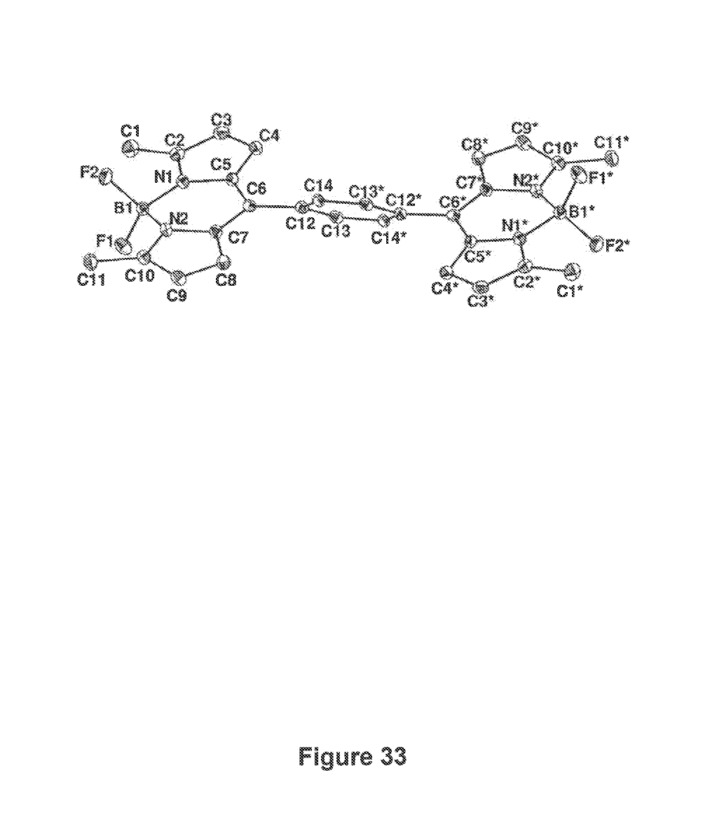

FIG. 33 shows the X-ray structure of dyad 23.

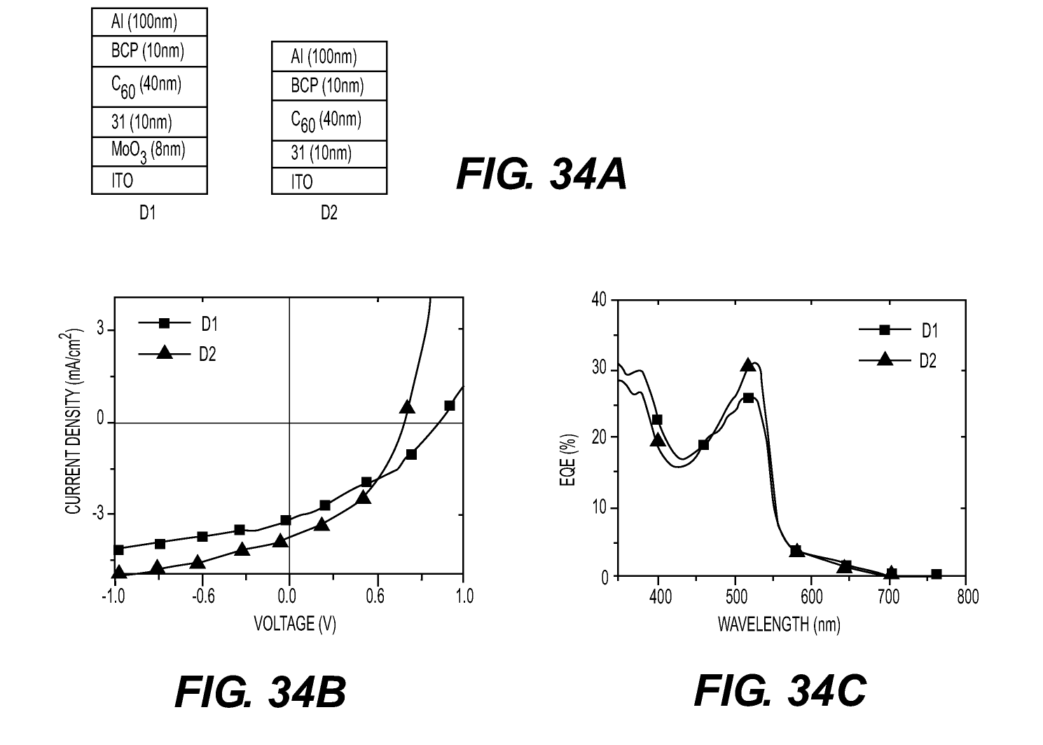

FIG. 34A shows device structures of organic PVs using compound 31 of FIG. 16; FIG. 34B shows current-voltage characteristics of the organic PVs under AM1.5G illumination; and FIG. 34C shows EQEs.

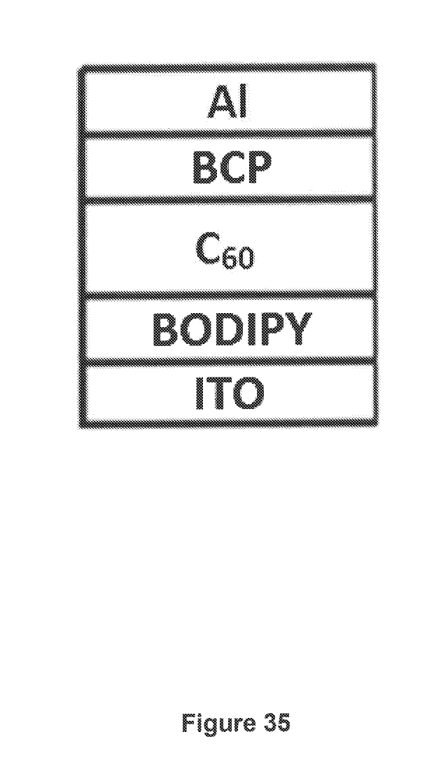

FIG. 35 shows a non-limiting example of a lamellar device structure of an organic PV using at least one compound of formula (I) as a donor material.

The compounds described herein have application in organic photosensitive optoelectronic devices. In some embodiments, the organic photosensitive optoelectronic device is a solar cell. In other embodiments, the organic photosensitive optoelectronic device is a photodetector. In some embodiments, the organic photosensitive optoelectronic device is a photosensor. In other embodiments, the organic photosensitive optoelectronic device is a photoconductor.

In some embodiments, the at least one compound of formula (I) exhibits an absorptivity of light greater than 10⁴ M⁻¹ cm⁻¹ at one or more wavelengths ranging from 450 to 900 nm. In some embodiments, the at least one compound of formula (I) exhibits an absorptivity of light greater than 10⁵ M⁻¹ cm⁻¹ at one or more wavelengths ranging from 450 to 900 nm.

As used herein, the term “monocyclic” refers to a carbocyclic or heterocyclic group comprising only a single ring.

As used herein, the term “multicyclic” refers to a carbocyclic or heterocyclic group comprising at least two rings. Some or all of the rings in the “multicyclic” group can be peri-fused, ortho-fused and/or bridged.

As used herein, the term “alkyl” refers to a straight-chain or branched saturated hydrocarbyl group.

As used herein, the term “aryl” refers to an aromatic hydrocarbyl group. The “aryl” group is monocyclic or multicyclic.

As used herein, the term “heteroaryl” refers to an aryl group having at least one N, O, or S ring atom, with C atom(s) as the remaining ring atom(s).

As used herein, the term “substituted” means that the chemical group has at least one hydrogen atom replaced by a substituent.

In some embodiments, the at least one compound of formula (I) is chosen from

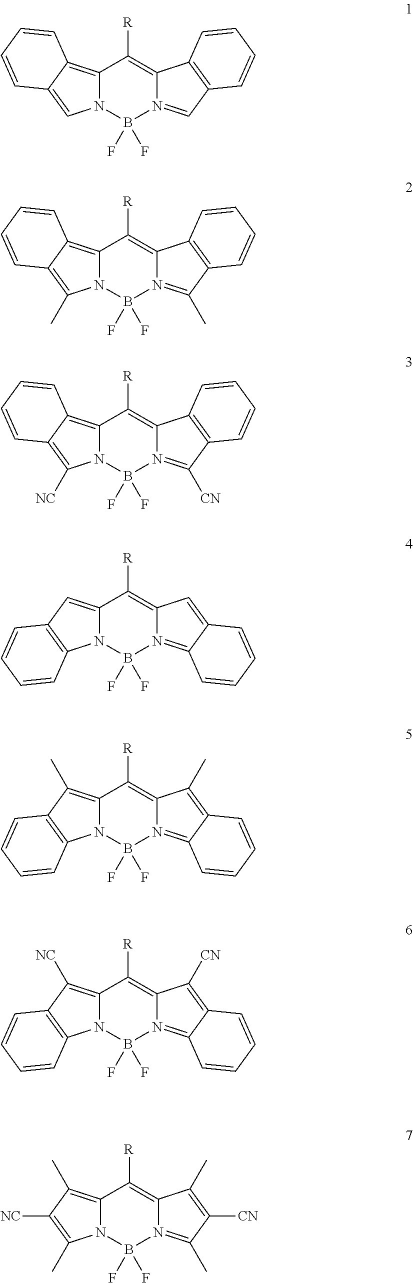

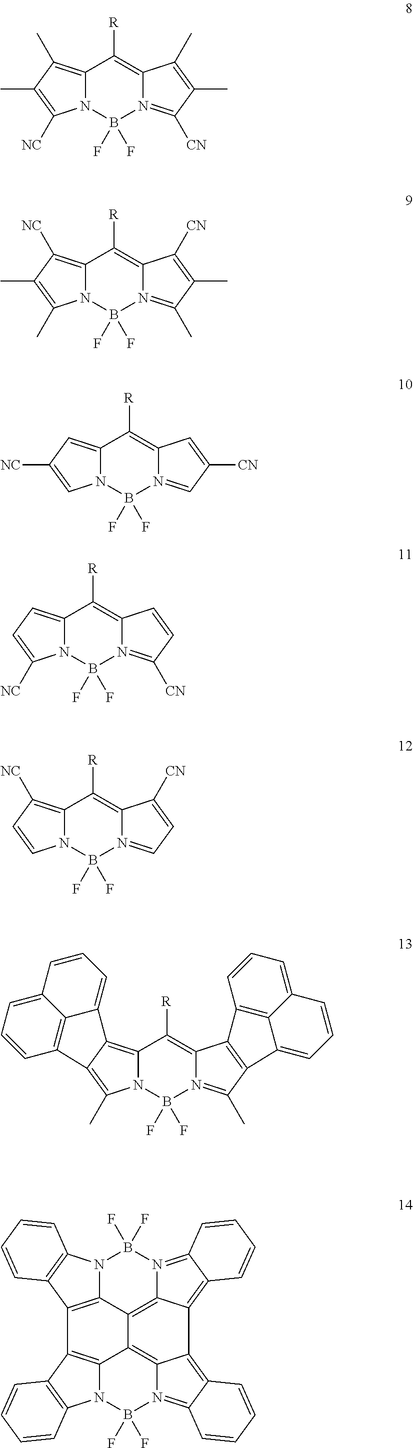

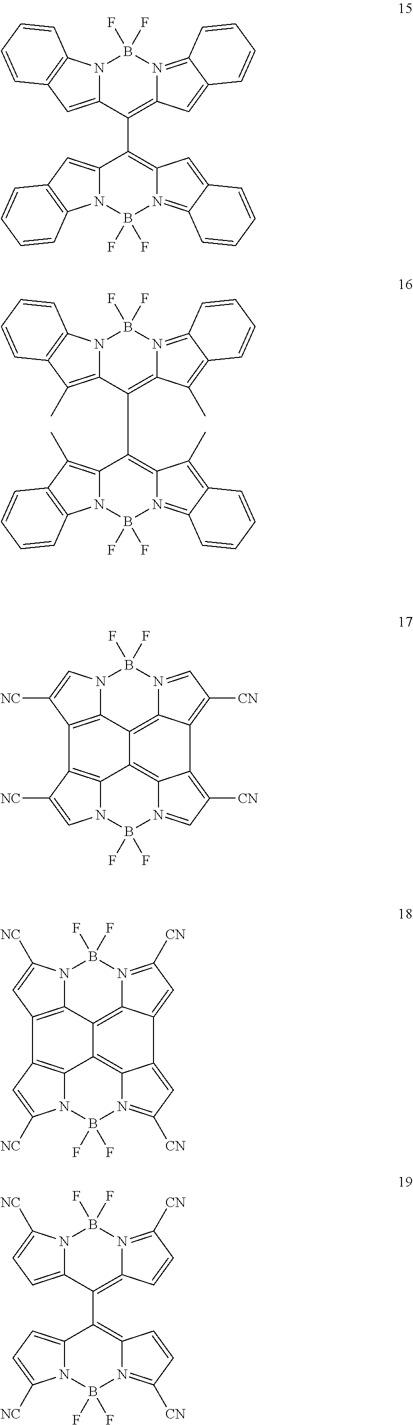

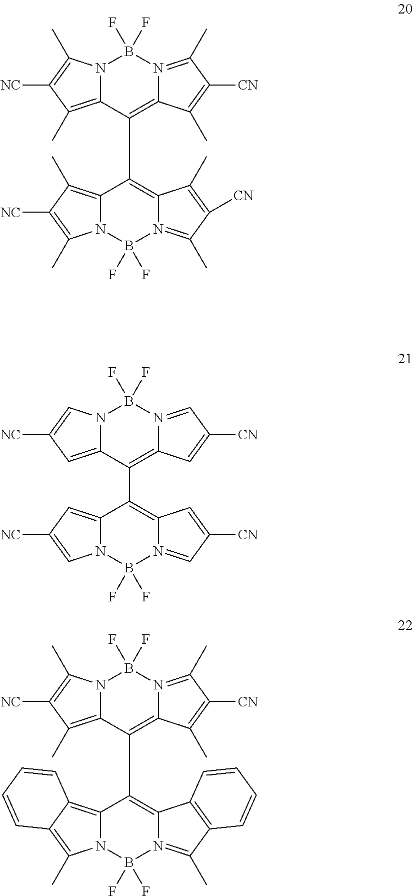

wherein R is chosen from an optionally substituted monocyclic group and an optionally substituted C₆₋₂₄ multicyclic group. In some embodiments, the optionally substituted monocyclic or multicyclic group of R is an aryl or a heteroaryl group. In some embodiments, R is chosen from

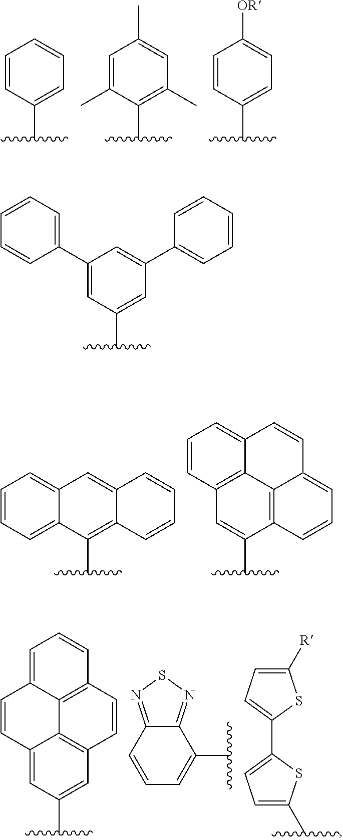

wherein R′ is chosen from H, alkyl, and aryl or heteroaryl groups.

In certain embodiments, the at least one compound of formula (I) does not include

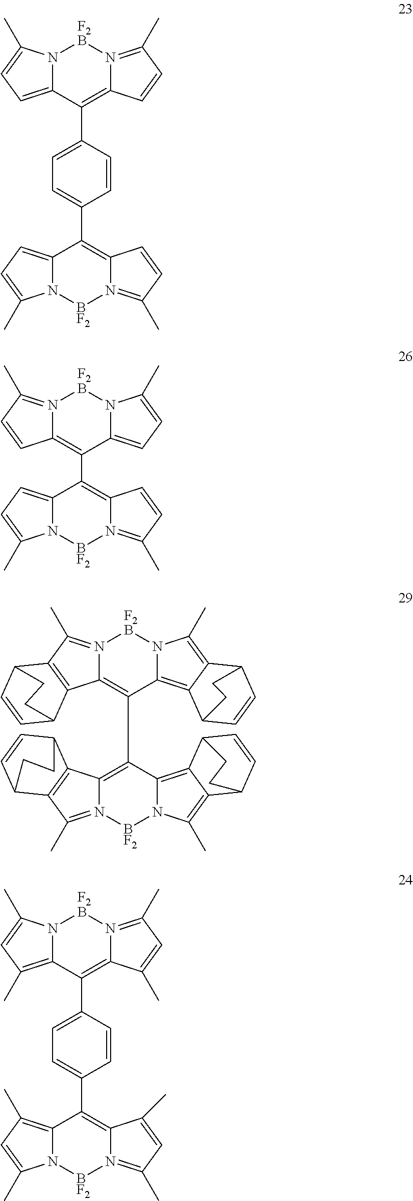

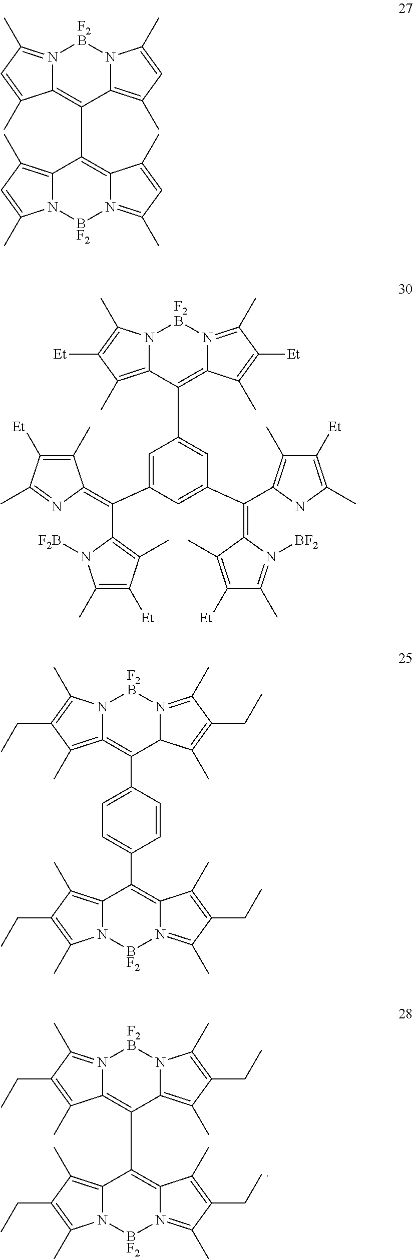

In some embodiments of the photosensitive optoelectronic device of the present disclosure, the device comprises at least one donor material and at least one acceptor material, wherein at least one of the donor and acceptor materials comprises at least one compound of formula (I). In some embodiments, the at least one donor material comprises at least one compound of formula (I). In some embodiments, the at least one acceptor material comprises at least one compound of formula (I). In some embodiments, both the donor and acceptor materials comprise at least one compound of formula (I), wherein the at least one compound of formula (I) that comprises the donor material is different from the at least one compound of formula (I) that comprises the acceptor material. As one of ordinary skill in the art would appreciate, the use of the BODIPY compounds disclosed herein as a donor and/or acceptor material depends upon the relationship of the HOMO and LUMO levels between two BODIPY compounds or between the BODIPY compound and a second organic semiconducting material used to complete a donor-acceptor pair.

In some embodiments, the at least one donor material comprises at least one compound of formula (I), and the at least one acceptor material comprises a fullerene or a derivative thereof. In certain embodiments, the at least one acceptor material comprises at least one of C₆₀, C₇₀ and phenyl-C₇₁-butyric-acid-methyl ester (PCBM).

In some embodiments, the at least one acceptor material comprises at least one compound of formula (I), and the at least one donor material comprises copper phthalocyanine (CuPc).

In some embodiments, the at least one acceptor material comprises at least one compound of formula (I) and a second organic semiconducting material. In certain embodiments, the second organic semiconducting material comprises C₆₀.

In some embodiments, the at least one donor material and the at least one acceptor material form a donor-acceptor heterojunction. The donor-acceptor heterojunction may be planar or non-planar. For example, the donor and acceptor materials may form at least one of a mixed heterojunction, planar heterojunction, bulk heterojunction, and hybrid planar-mixed heterojunction.

In some embodiments, the at least one donor material and the at least one acceptor material form a lamellar structure, wherein the at least one donor material comprises at least one compound of formula (I) and has a thickness ranging from about 1-150 nm, or about 10-150 nm, or about 10-100 nm, or about 20-80 nm. A non-limiting example of a device comprising at least one donor material and at least one acceptor material forming a lamellar structure, wherein the at least one donor material comprises at least one compound of formula (I), is shown in FIG. 35.

The organic photosensitive optoelectronic device of the present disclosure may further comprise two electrodes comprising an anode and a cathode. A photoactive region can be located between the anode and the cathode, wherein the photoactive region comprises at least one compound of formula (I). In some embodiments, the photoactive region comprises at least one donor material and at least one acceptor material, wherein at least one of the donor and acceptor materials comprises the at least one compound of formula (I). The donor and acceptor materials may form a donor-acceptor heterojunction as described herein.

Stacked organic photosensitive optoelectronic devices are further contemplated herein. The stacked device according to the present disclosure may comprise a plurality of photosensitive optoelectronic subcells, wherein at least one subcell comprises two electrodes comprising an anode and a cathode in superposed relation, and a photoactive region between the two electrodes, wherein the photoactive region comprises at least one compound of formula (I). In some embodiments, the photoactive region comprises at least one donor material and at least one acceptor material, wherein at least one of the donor and acceptor materials comprises at least one compound of formula (I). The donor and acceptor materials may form a donor-acceptor heterojunction as described herein. The donor and acceptor materials may form a lamellar structure as described herein.

When a subcell is used individually as a photosensitive optoelectronic device, it typically includes a complete set of electrodes, i.e., positive and negative. In some stacked configurations, it is possible for adjacent subcells to utilize common, i.e., shared, electrode, charge transfer region or charge recombination zone. In other cases, adjacent subcells do not share common electrodes or charge transfer regions. The term “subcell” is disclosed herein to encompass the subunit construction regardless of whether each subunit has its own distinct electrodes or shares electrodes or charge transfer regions with adjacent subunits. The subcells may be electrically connected either in parallel or in series.

The organic photosensitive optoelectronic devices of the present disclosure may also comprise one or more blocking layers, such as exciton blocking layers (EBLs), between the two electrodes. In some embodiments, one or more blocking layers are located between the photoactive region and the anode, between the photoactive region and the cathode, or both. Examples of blocking layers are described in U.S. Patent Publication Nos. 2012/0235125 and 2011/0012091 and in U.S. Pat. Nos. 7,230,269 and 6,451,415, which are incorporated herein by reference for their disclosure of blocking layers.

The organic photosensitive devices of the present disclosure may be structured in various configurations with varying material combinations. Examples of device configurations and materials are described in U.S. Patent Application No. 13/666,664, U.S. Patent Publication Nos. 2012/0235125 and 2010/0102304, and U.S. Pat. Nos. 6,657,378; 6,580,027, and 6,352,777, which are incorporated herein by reference for their disclosure of organic photosensitive optoelectronic device structures, particularly photovoltaic structures, and materials.

Methods for making the photosensitive optoelectronic devices of the present disclosure are also disclosed herein. In some embodiments, the method comprises depositing a photoactive region over a substrate, wherein the photoactive region comprises at least one compound of formula (I). In some embodiments, the photoactive region comprises at least one donor material and at least one acceptor material, wherein at least one of the donor and acceptor materials comprises at least one compound of formula (I). In some embodiments, the at least one donor material comprises the at least one compound of formula (I). In some embodiments, the at least one acceptor material comprises the at least one compound of formula (I). In some embodiments, both the donor and acceptor materials comprise at least one compound of formula (I), wherein the at least one compound of formula (I) that comprises the donor material is different from the at least one compound of formula (I) that comprises the acceptor material.

In some embodiments, the deposition of the photoactive region comprises depositing at least one compound of formula (I) over the substrate. In some embodiments, the deposition of the photoactive region comprises codepositing an organic semiconducting material and at least one compound of formula (I) over the substrate. The deposition of the photoactive region may form at least one of a donor-acceptor mixed heterojunction, planar heterojunction, bulk heterojunction, and hybrid planar-mixed heterojunction. In some embodiments, the deposition of the photoactive region forms a lamellar device structure.

In some embodiments, the deposition of the photoactive region comprises depositing at least one donor material over a substrate, thermally annealing the substrate and the at least one donor material, and depositing at least one acceptor material over the at least one donor material. In some embodiments, the at least one donor material comprises at least one compound of formula (I). In some embodiments, the at least one donor material comprises at least one compound of formula (I), and the at least one acceptor material comprises C₆₀. In other embodiments, the at least one acceptor material comprises at least one compound of formula (I).

In some embodiments, the deposition of the photoactive region comprises depositing at least one donor material over a substrate, depositing at least one acceptor material over the at least one donor material, and thermally annealing the substrate, the at least one donor material, and the at least one acceptor material. In some embodiments, the at least one donor material comprises at least one compound of formula (I). In some embodiments, the at least one donor material comprises at least one compound of formula (I), and the at least one acceptor material comprises C₆₀. In other embodiments, the at least one acceptor material comprises at least one compound of formula (I). In some embodiments, the at least one acceptor material comprises at least one compound of formula (I), and the at least one donor material comprises CuPc.

In some embodiments, annealing is performed between 90° C. and 150° C. from 0 to 30 minutes. Suitable times and temperatures for annealing may be chosen based on the particular materials used.

Organic layers may be deposited using methods known in the art. One advantage of the BODIPY dyes disclosed herein is that they are solution-processable and sublimable. Thus, in some embodiments, the at least one compound of formula (I) is deposited over a substrate using a technique chosen from spin casting and vapor deposition.

Another aspect of the present disclosure relates to compounds that exhibit the light absorption and symmetry breaking properties required for applications in OPVs. By extension, these compounds of the present disclosure mimic features seen in the photosynthetic reaction center.

Compounds that exhibit the light absorption and symmetry breaking properties required for applications in OPVs include, for example, higher order compounds, such as symmetrical dyads, triads, tetrads, etc. These compounds may populate intramolecular charge-transfer states in a polarizing medium by symmetry breaking, but cannot do so in the absence of a polarizing medium because of their symmetry. The higher order compounds may have at least C₂ symmetry and should have a luminescent lifetime of at least 1 ps to allow charge transfer to take place prior to other radiative or non-radiative decay processes.

In one embodiment, the higher order compounds may comprise, for example, dye compounds chosen from perylenes, malachites, xanthenes, cyanines, bipyridines, dipyrrins, coumarins, acridines, phthalocyanines, subphthalocyanines, porphyrins, and acenes. These dyes may be substituted with alkyl, H, electron donating or electron withdrawing groups at any position other than the linking site to control the physical and electronic properties of the dye. The relevant physical properties include solubility as well as sublimation and melting temperatures. The relevant electronic properties include the absorption and emission energies, as well as the oxidation and reduction potentials.

In another embodiment, the higher order compounds are chosen from the following dipyrrin chromophores:

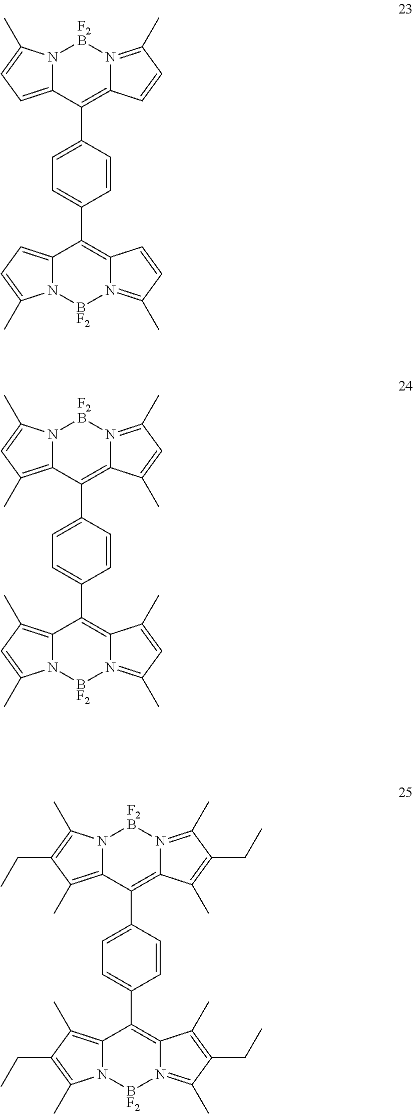

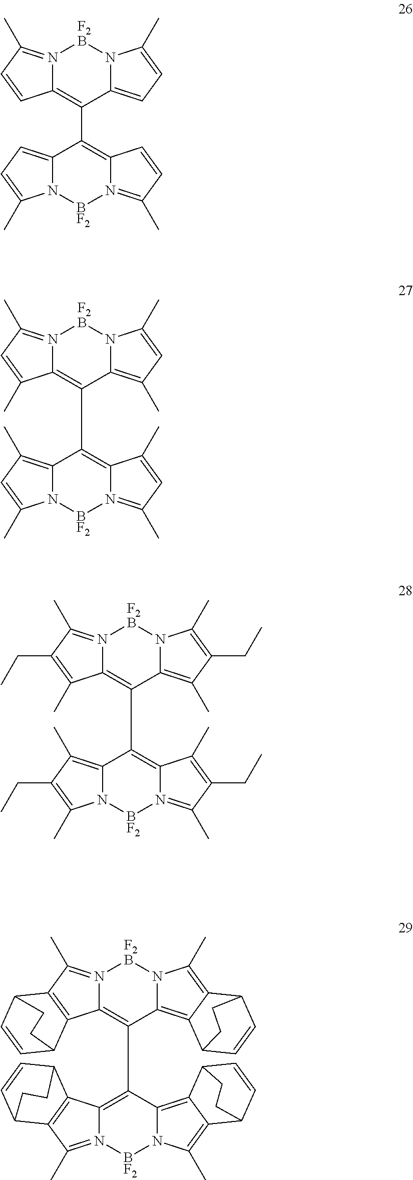

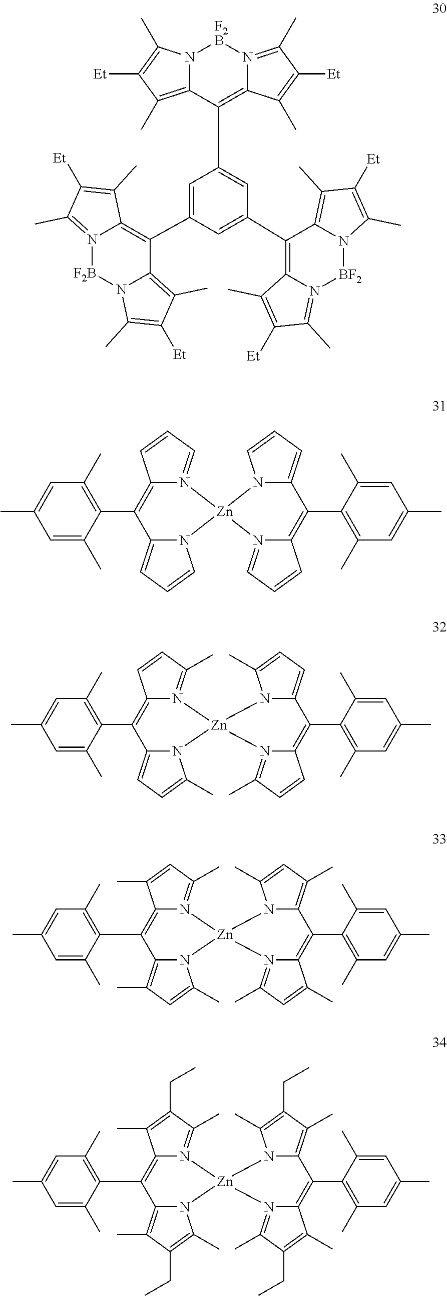

Another embodiment of the present disclosure provides for symmetry-breaking ICT compounds and their use as chromophores for the generation of electric-field-stabilized geminate polaron pairs. These polaron pairs collapse in the absence of an electric field, generating a high concentration of excitons and may be useful for the construction of organic lasers. In this process a large electric field is applied to drive the charge separation of excitons formed on light absorption and stabilize the geminate polaron pairs toward recombination. This was accomplished with a lightly doped matrix, where the dopant absorbs light and acts as one of the polarons (cation or anion), with the other polaron on the matrix material. The BODIPY dyads and related compounds described herein have donor and acceptor present in the same molecule (though in the absence of an electric field there is no driving force for excited-state charge separation), such that charge separation to form the geminate pairs can be efficiently achieved within the chromophore itself. This allows the chromophore to be doped into nonconductive host materials, preventing carrier leakage. The inherent C2 symmetry of the substituted porphryins ensure that nearly every molecule is present in an orientation that will promote charge separation (FIG. 26). An orientation that cannot be efficiently coupled with the electric field is one in which the plane of the dyad is perpendicular to the applied electric field. By using a randomly doped film, only a low percentage of the dopant is present in the nonproductive orientation.

In order to prove useful in solar cell applications, the constituent higher order dye compounds must exhibit high absorptivity (ε>10⁻⁴ M⁻¹ cm⁻¹) of light at some visible to near infrared wavelengths (350-1500 nm), for example, dyads of xanthenes dyes (e.g., fluorescein, eosins, and rhoadmines), coumarins, acridines, phthalocyanines, subphthalocyanines, porphyrins, acenes such as tetracene or pentacene, perylenes, malachites, cyanines, bipyridines, and dipyrrins, among others. In some solar cell applications, for example, single cell solar cells, the higher order dye compounds may exhibit high absorptivity of light at some visible to near infrared wavelengths between 350 to 950 nm. In other solar cell applications, for example, tandem solar cells, the higher order dye compounds may exhibit high absorptivity of light at some visible to near infrared wavelengths between 350 nm to at least 1200 nm. In an organic photodetector, the higher order dye compounds may exhibit high absorptivity of light at some visible to near infrared wavelengths between 350 nm to at least 1500 nm.

The dyad (or triad, tetrad, etc.) must also possess an intramolecular charge-transfer (ICT) state that is energetically accessible from the photogenerated S₁ state in a polarizing medium. It is known that the energy of an ICT state can be approximated as:

E(ICT)=IP(D)−EA(A)+C+ΔEₛₒₗᵥ (1)

where IP(D) is the ionization potential of the donor, EA(A) is the electron affinity of the acceptor, C is the Coulombic stabilization of a neighboring cation and anion in the system, and ΔEₛₒₗᵥ is the stabilization of the ion pair by a surrounding polar environment (due to solvent or otherwise).

For the molecules proposed, the donor and acceptor are the same moiety, so a crude approximation of the energy of a symmetry-breaking ICT state can come from the energy required to pass one electron through the potential difference between the one-electron oxidation and reduction events, as determined by cyclic voltammetry or other electrochemical method. Since C and ΔEₛₒₗᵥ only serve to stabilize the ICT state, this method will always lead to an overestimate of the energy. Thus, for example, if the difference in oxidation and reduction events for a dye is 2.50 V, then the energy of an ICT state for a dyad constructed from that dye will be less than 2.50 eV. To a first approximation, dimers (and higher order structures) of dyes with a first singlet excited state (S₁) energy greater than E_{ICT}-0.260 eV (i.e., E_{ICT} as determined by this method minus 10 kT) may be able to undergo symmetry-breaking intramolecular charge transfer at a polarizing donor/acceptor interface to facilitate charge separation in photovoltaics. The oxidation and reduction potentials and E₀₀ energies for some of the compounds in FIGS. 16A to 16D are listed in Table 1.

TABLE 1
Oxidation and reduction potentials of molecules
from FIGS. 16A to 16D in CH₂Cl₂.

| | | | | | E_{CT} (V) | |
|---|---|---|---|---|---|---|
| | 2^{nd} E_{-1/2} | 1^{st} E_{-1/2} | 1^{st} E_{+1/2} | Eₚₐ | 1^{st} (E_{red} − Eₒₓ) | E₀₀ (eV) |
| 23 | | −1.37 | 0.94 | | 2.31 | 2.38 |
| 24 | | −1.62 | | 0.83 | 2.43 | 2.41 |
| 25 | | −1.69 | 0.66 | | 2.34 | 2.32 |
| 26 | | −1.19 | | 0.97 | 2.16 | 2.25 |
| 28 | | −1.50 | 0.72 | | 2.22 | 2.20 |
| 31 | −2.33 | −1.93 | | 0.80 | 2.73 | 2.54 |
| 32 | −2.42 | −2.11 | | 0.60 | 2.71 | 2.48 |
| 33 | −2.79 | −2.35 | | 0.38 | 2.73 | 2.49 |
| 34 | −2.82 | −2.44 | | 0.24 | 2.68 | 2.40 |

The absorption profiles of the chromophores in FIGS. 16A to 16D are generally similar to the monomer units of their respective dyes, indicating minimal excitonic coupling between the two (or three or more) dye units on the chromophore molecule. They are also generally invariant across different solvent polarities, since

TABLE 2
Absorption and emission maxima for BODIPY dyes numbered in FIGS. 16A to 16D.

| | E_{T} (30) | | | | | | | | | | | | |
|---|---|---|---|---|---|---|---|---|---|---|---|---|---|
| Solvent | (kcal mol⁻¹)^{a} | 23 | 24 | 25 | 26 | 27 | 28 | 29 | 30 | 31 | 32 | 33 | 34 |
| Cyclohexane | 30.9 | 513 | NM | 525 | 523 | NM | 540 | NM | 537 | 484 | 493 | 489 | 506 |
| Toluene | 33.9 | 515 | 501 | 526 | 526 | 516 | 542 | 550 | 537 | 486 | 495 | 491 | 508 |
| Dichloromethane | 40.7 | 513 | 500 | 525 | 530 | 515 | 541 | 550 | 538 | 485 | 493 | 488 | 506 |
| Acetonitrile | 45.6 | 508 | 495 | 520 | 526 | 516 | 538 | 545 | 531 | 481 | 490 | NM | NM |
| Cyclohexane | 30.9 | 538 | NM | 544 | 564 | NM | 592 | NM | 564 | 501 | 506 | 507 | 533 |
| Toluene | 33.9 | 540 | 524 | 545 | 574 | 587 | 601 | 584 | 564 | 503 | 509 | 509 | 533 |
| Dichloromethane | 40.7 | 538 | 522 | 543 | 651 | 624 | 635 | 601 | 566 | 495 | 511 | 509 | 528 |
| Acetonitrile | 45.6 | 531 | 522 | 538 | — | 678 | 680 | 671 | 553 | 490 | 508 | NM | NM |

^{a}Solvent polarity index,
^{b}No emission was observed in these solvents.
NM—No measurement taken in this solvent.

accessing any ICT state should first excite directly to the S₁ state. The absorption of the chromophores from FIGS. 16A to 16D are listed in Table 2 for different solvents.

The fluorescence for each chromophore (Table 3) can be altered based on the solvent environment, as the increasing solvent polarity should stabilize access to the CT state and decrease the energy of that CT state. Thus, a red shift of any emissive CT state should be seen in the fluorescence spectra and is noted for directly linked dyads 26, 27, 28 and 29. Chromophores 31-34 illustrate separate CT bands that grow in as solvent polarity increases at longer wavelength. However, the rest of the chromophores seem to possess non-emissive CT states. Evidence for these CT states is seen when measuring the photoluminescent quantum yield (Table 3), which decreases for all candidates as solvent polarity increases. The decrease in quantum yield indicates there is some state that is increasingly non-emissive as solvent polarity increases.

TABLE 3
PL quantum yield
Photoluminescence quantum yields in varying solvents of compounds from FIGS. 16A to 16D.

| | E_{T} (30) | | | | | | | | | | | |
|---|---|---|---|---|---|---|---|---|---|---|---|---|
| Solvent | (kcal mol⁻¹) | 23 | 24 | 25 | 26 | 27 | 29 | 30 | 31 | 32 | 33 | 34 |
| Cyclohexane | 30.9 | 0.052 | NM | NM | 0.780 | NM | NM | 0.281 | 0.414 | 0.700 | 0.180 | 0.172 |
| Toluene | 33.9 | 0.095 | 0.510 | 0.420 | 0.620 | 0.155 | 0.701 | 0.130 | 0.333 | 0.190 | 0.138 | 0.134 |
| Dichloromethane | 40.7 | 0.069 | 0.290 | 0.370 | 0.087 | 0.094 | 0.291 | 0.124 | 0.028 | 0.038 | 0.005 | 0.002 |
| Acetonitrile | 45.6 | <0.001 | 0.005 | 0.036 | — | 0.004 | 0.027 | — | <0.001 | <0.001 | <0.001 | <0.001 |

^{a}Solvent polarity index,
^{b}No emission was observed in these solvents
NM—no measurement taken.

Support for the formation of an ICT state in polar solvents was provided by femtosecond transient absorption measurements (Table 4). Excitation at a BODIPY wavelength (˜500 nm) in acetonitrile populates the S₁ state, as reflected by the appearance of a stimulated emission band from 525-600 nm for the BODIPY chromophores. Over the course of 10 ps, this band disappears concomitant with the rise of a weak induced absorption band peaked at ˜545 nm that matches absorption spectra reported for the BODIPY radical anion. A global fit to the data yields a rate formation of this ICT state (k_{CT}⁻¹). Subsequently, all transient spectral features decay with a rate constant given as k_{rec}⁻¹. The evidence of the CT state decreases as solvent polarity decreases from acetonitrile to dichloromethane to toluene and the recombination increases (becomes faster) correspondingly. We also note that as sterics increase (i.e. from 1 to 4), k_{CT}⁻¹ increases (becomes faster) and k_{rec}⁻¹ decreases (becomes slower).

TABLE 4
Rates of charge transfer (k_{CT}⁻¹) and charge recombination (k_{rec}⁻¹) for the compounds in FIGS.
16A to 16D in various solvents as calculated using femtosecond transient absorption spectroscopy.

| TOLUENE | | | DICHLOROMETHANE | | | | ACETONITRILE | | | | |
|---|---|---|---|---|---|---|---|---|---|---|---|
| Molecule | k_{CT}⁻¹ | k_{rec}⁻¹ | Molecule | k_{CT}⁻¹ | | k_{rec}⁻¹ | Molecule | k_{CT}⁻¹ | | k_{rec}⁻¹ | |
| 23 | NA | NA | 1 | 18 | ps | 1.6 ns | 23 | 4.8 | ps | 34 | ps |
| 24 | NA | NA | 2 | 136 | ps | 3.2 ns | 24 | 53.0 | ps | 196 | ps |
| 25 | NA | NA | 3 | 165 | ps | 2.5 ns | 25 | 74.0 | ps | 288 | ps |
| 26 | 4.5 ps | NA | 4 | 0.49 | ps | 6.7 ns | 26 | 0.17 | ps | 650 | ps |
| 27 | 2.35 ps | 14.5 ps | 5 | 1.34 | ps | 10.3 ns | 27 | 0.32 | ps | 1.93 | ns |
| 28 | 1.7 ps | 6.1 ns | 6 | 0.78 | ps | 16.8 ns | 28 | 0.21 | ps | 1.8 | ns |

| | | | | | | | | | | |
|---|---|---|---|---|---|---|---|---|---|---|
| 31 | 9.0 ps | NA | 10 | 5.7 | ps | NA | 31 | 3.5 | ps | NA |

| | | | | | | | | | |
|---|---|---|---|---|---|---|---|---|---|
| 32 | 5.7 ps | NA | 11 | NA | NA | 32 | 1.1 | ps | NA |
| 33 | 2.6 ps | NA | 12 | NA | NA | 33 | 1 | ps | NA |

NA—No measurement was taken because of instrument limitation or lack of CT formation.

In order to undergo such symmetry-breaking charge transfer, the dyes must be able to communicate electronically (though there need not be any ground-state interaction). Thus, the manner in which they are connected is important. There are a number of possible ways to link the dyes together to allow for symmetry breaking ICT to take place. Three examples are illustrated in FIG. 27 for bringing two, three, or four dyes together. For dyad-type structures, the two constituent dyes may be connected directly or through a linker that places them in linear or cofacial arrangements (FIG. 28). The linker must have higher energy optical transitions than the dyes to prevent direct energy transfer from the dye to the linker. Numerous linkers can be utilized, including saturated and unsaturated hydrocarbon linkers, with the most important requirement being that the linker must have ground state oxidation and reduction potentials, such that the linker is neither reduced nor oxidized by the photoexcited dye.

FIG. 27(a) contemplates a wide range of effectively divalent linkers. The linker could be a single atom, as illustrated for the Zinc based materials in compounds 31-34 of FIGS. 16C and 16D. This divalent group can also be a disubstituted arene, as illustrated in compounds 23-25 or a single bond as illustrated in compounds 26-29. One of skill in the art can envision a range of similar divalent linkers using other divalent atoms or effective divalent linkers constructed from aryl, fused aryl, such as naphthyl, anthryl, etc., alkyl, alkynyl, alkenyl, a single bond (R is a single bond), a heterocycle, a diazo or organosilane moiety. A tetravalent atom may also be used to link dyads, if the linker makes two covalent bonds to each dye. Such a connection with a carbon or silicon atom is termed a spiro connection and leads to a rigorous orthogonal of the two molecules bridged by the spiro C or Si.

FIG. 27(b) illustrates three dyes disposed around a linker. This effectively trivalent linkage is demonstrated for 1,3,5-benzene in compound 30 of FIG. 16C. This linkage could also be a trivalent metal atom such as Al or Ga, or a transition metal. These complexes are analogous to compounds 31-34 of FIGS. 16C and 16D, except the central metal atom would be surrounded by three bidentate ligands. One of skill in the art can envision a range of similar trivalent linkers using trivalent atoms or effective trivalent linkers constructed from aryl, fused aryl, such as naphthyl, anthryl, etc., alkyl, alkenyl, a heterocycle, or organosilane moiety.

FIG. 27(c) illustrates four dyes bound to a central linker. This linkage could be a tetravalent metal atom such as Ti, Zr or Hf. These complexes are analogous to compounds 31-34 of FIGS. 16C and 16D, except the central metal atom would be surrounded by four bidentate ligands. One of skill in the art can envision a range of similar tetravalent linkers using trivalent atoms or effective tetravalent linkers constructed from aryl, fused aryl, such as naphthyl, anthryl, etc., alkyl, alkenyl, a heterocycle, or organosilane moiety. A number of other geometries can be envisioned for higher-order structures, with the requirement that they be symmetric or pseudosymmetric in the ground state so that there is no driving force for ICT in the absence of a polarizing medium. Moreover, any interaction of the two molecules in the ground or excited state should not lead to the formation of an excited state lower in energy than the ICT, such as a triplet or excimeric excited state. These alternate excited states can exist, but they must be higher in energy than the ICT.

In one embodiment, the symmetry-breaking charge transfer compounds has at least C₂ symmetry, and this symmetry is maintained upon linkage in the dyad, triad, tetrad, etc. The symmetry can be maintained by having the atom linking the dye to the linker lying on the C₂ axis, as in cynines, malachites, xanthenes and perylenes. Alternatively, the dye can be bound in such a way that the C₂ symmetry is retained in the bound structure-no atom bonded to the linkage center is on the C₂ axis.

To continue studies on charge and energy transfer reactions in BODIPY-porphyrin hybrids, one aspect of the disclosure provides for the synthesis and unusual symmetry-breaking ICT properties of symmetrical BODIPY dyads, wherein the units are connected through the meso position either indirectly by an intervening phenylene or directly through a C—C bond. Further investigation found the directly linked dyad to have excited-state properties that mimic behavior found in 9,9′-bianthryl.

Phenylene-bridged BODIPY dyad 23 of FIG. 16A was initially targeted due to its structural semblance to BODIPY-porphyrin hybrids.

Dyad 23 was prepared by acid-catalyzed condensation of terephthalaldehyde and 2-methylpyrrole, followed by oxidation with DDQ and difluoroborylation in the presence of N,N-diisopropylethylamine and boron trifluoride diethyl etherate. Analysis of dyad 23 by single-crystal x-ray diffraction reveals two coplanar BODIPY units rendered identical by a crystallographic center of symmetry (FIG. 33). The phenylene bridge is canted at an angle of 47° relative to the BODIPY planes, suggesting minimal steric encumbrance to partial rotation of the BODIPY units with respect to the linker. Thus, electronic superexchange, which requires interaction of the BODIPY and phenylene n-orbitals, should be possible across the phenylene bridge.

Absorption spectra of dyad 23 in solvents of varying polarity are nearly identical to the model compound 3,5Me₂BODIPY-Ph, indicating minimal ground-state interaction or excitonic coupling between the chromophores of dyad 23 (FIG. 19). Emission spectra of dyad 23 display small Stokes shifts that are nearly invariant in all 60 solvents. However, the photoluminescence quantum efficiencies (QE) are less than 0.1 and drop precipitously in the most polar solvents (Table 5). In contrast, the QE of 3,5Me₂BODIPY-Ph is 0.29 in cyclohexane, and declines to 0.17 in acetonitrile. The sharp decrease in the QE of dyad 23 indicates the possible formation of a non-emissive charge-transfer state that entails some degree of symmetry breaking since the BODIPY units are identical to the linker.

TABLE 5

| | E_{T}(30)^{a} | λ_{max, ab}λ_{max,} | λ_{max, ab}λ_{max,} | |
|---|---|---|---|---|
| Solvent | (kcal mol⁻¹) | ₑₘ s(nm) | ₑₘ s(nm) | Φ |
| Cyclohexane | 30.9 | 513 | 538 | 0.052 |
| Toluene | 33.9 | 515 | 540 | 0.095 |
| 2-Methyltet- | 36.5 | 511 | 540 | 0.046 |
| rahydrofuran | | | | |
| Chloroform | 39.1 | 515 | 538 | 0.097 |
| Dichloromethane | 40.7 | 513 | 538 | 0.069 |
| Acetone | 42.2 | 509 | 534 | <0.001 |
| N,N-Dimethyl- | 43.2 | 512 | 536 | <0.001 |
| formaide | | | | |
| Acetonitrile | 45.6 | 508 | 531 | <0.001 |

^{a}Solvent polarity index

The potential for dyad 23 to undergo symmetry-breaking ICT was examined by electrochemistry. Cyclic voltammetry of dyad 23 revealed a reversible reduction (E_{1/2}=−1.37 V) and an irreversible oxidation (EPA=940 mV, both versus Fc/Fc⁺). The difference between oxidation and reduction values (2.31 V) indicates that the S₁ state of dyad 23 (E₀₀=2.38 eV in cyclohexane) should be energetic enough to undergo ICT, as previously discussed by Zander and Rettig.

Support for the formation of an ICT state in polar solvents was provided by femtosecond transient absorption measurements (FIG. 21). Excitation of dyad 23 at 508 nm in acetonitrile populates the S₁ state, as reflected by the appearance of a stimulated emission band from 525-600 nm that matches the S₁ emission line shape. Over the course of 10 ps, this band disappears concomitant with the rise of a weak induced absorption band peaked at 545 nm that matches absorption spectra reported for the BODIPY radical anion. A global fit to the data (FIG. 21(b)) yields a rate of 4.8 ps for the formation of this ICT state. Subsequently, all transient spectral features decay with a rate constant of 34 ps, indicating a fast non-radiative return to the S₀ state, consistent with asymmetric dyads incorporating a BODIPY acceptor. On other hand, excitation of dyad 23 in toluene leads to formation of an S₁ state that decays at a rate consistent with the lifetime determined from emission studies (τ=850 ps).

The importance of twisting and other structural changes of ICT excited states in donor/acceptor molecules has been extensively explored. Additionally, rotation of meso-aryl substituents relative to BODIPY chromophores has previously been invoked as a major pathway for non-radiative deactivation. In the present case, facile rotation of the phenylene bridge in dyad 23 is also what likely allows the ICT state to undergo ultrafast direct surface crossing to the ground state. Thus, these studies were extended using dyad 26 of FIG. 16B, with the two BODIPY units linked directly at the meso position by a C—C bond, for which rotational freedom should be significantly restricted. Dyad 26 was prepared in low yield (<3%) from 1,1,2,2-tetrakis(5-methyl-1H-pyrrol-2yl)ethene, which in turn was synthesized by a McMurry reaction, using standard oxidation and difluoroborylation conditions (Eq I). Although X-ray quality single crystals of dyad 26 have not been obtained, structure minimization using DFT (B3LYP/63 lg*) methods indicated that the planar BODIPY units of dyad 26 have local geometries similar to those of dyad 23, and are canted at a dihedral angle of 71° with respect to each other.

Absorption spectra of dyad 26 are nearly invariant across several solvents and are similar to that of dyad 23 and other BODIPY chromophores. Slight splitting of the primary (S₀→S_{I}) absorption band at 530 nm indicates a modest degree of exciton coupling between the BODIPY units. Fluorescence spectra, on the other hand, were dramatically affected by solvent. A small Stokes shift and high quantum efficiency were observed in cyclohexane. A progressive red-shift in the emission wavelength was observed with increasing solvent polarity, with concomitant broadening and decrease in QE (FIG. 23 and Table 6). The spectra indicated that dyad 26 has a nonpolar ground state and a significantly higher dipole moment in the excited state, even though the two constituent chromophores are identical. Similar behavior was observed for the 9,9′-bianthryl molecule.

TABLE 6

| | E_{T}(30)^{a} | λ_{max, ab}λ_{max,} | λ_{max, ab}λ_{max,} | |
|---|---|---|---|---|
| Solvent | (kcal mol⁻¹) | ₑₘ s(nm) | ₑₘ s(nm) | Φ |
| Cyclohexane | 30.9 | 523 | 564 | 0.78 |
| Toluene | 33.9 | 526 | 574 | 0.62 |
| 2-Methyltet- | 36.5 | 524 | 620 | 0.18 |
| rahydrofuran | | | | |
| Chloroform | 39.1 | 526 | 585 | 0.35 |
| Dichloromethane | 40.7 | 530 | 651 | 0.087 |
| Acetone | 42.2 | 528 | —^{b} | —^{b} |
| N,N-Dimethyl- | 43.2 | 530 | —^{b} | —^{b} |
| formaide | | | | |
| Acetonitrile | 45.6 | 526 | —^{b} | —^{b} |

^{a}Solvent polarity index;
^{b}No emission observed

Dyad 26 exhibited a simple first-order luminescence decay in cyclohexane (τ=9.3 ns), whereas biexponential decay was observed in dichloromethane, comprised of a fast component (<200 ps) accompanied by a longer-lived (ca 7 ns) decay. (FIG. 24) The non-radiative decay rate of dyad 26 (kₙᵣ=1.4×10⁸ S⁻¹) in CH₂Cl₂ is more than two orders of magnitude slower than that of dyad 23 in acetonitrile. These results indicate that a local S₁ state formed upon photoexcitation of dyad 26 undergoes ultrafast transformation to an emissive ICT state by solvent-induced symmetry breaking in polar solvents.

Femtosecond transient absorption spectroscopy in CH₂Cl₂ was used to further illuminate the charge-transfer behavior of dyad 26 in polar media. The S₁ state observed upon excitation at 508 nm quickly evolves (k_{IC}⁻¹=570±80 fs) to produce an excited state that absorbs at 580 nm, consistent with the formation of a BODIPY radical anion (FIG. 25). In contrast to the ICT state observed in dyad 23 however, the spectral features associated with the ICT state in dyad 26 show only minimal change in amplitude over the course of 1 ns, indicating that this state has a lifetime comparable to that of the emissive state.

Although several biacenes display similar luminescent properties, to the best of our knowledge dyad 26 represents the first example of a dyad that combines symmetry-breaking formation of an emissive ICT state with intense absorption in the visible region of the spectrum. While porphyrins are in many respects related to dipyrrins, the meso-linked porphyrin analogues of dyad 26 do not undergo symmetry-breaking ICT because formation of such an excited state is endothermic with respect to the S₁ state. BODIPY dyads directly linked at the α- or β positions also do not exhibit this sort of emissive behavior. However, Benniston et al. have reported a hybrid of dyad 26 and 9,9′-bianthryl, a meso-linked 9-anthracenyl-BODIPY compound, that readily forms an emissive ICT state in polar solvents, akin to an exciplex.

These directly linked dyads serve as a visible-light-absorbing analogue of 9,9′-bianthryl.

BODIPY dyads 23 and 26 lead to formation of ICT states in polar media by solvent-induced symmetry breaking. The further presence of strong absorption at visible wavelengths enables these molecules to mimic features seen in the photosynthetic reaction center. Model systems that possess both these characteristics are rare. Differing degrees of rotational freedom in the dyads significantly alter the behavior of the ICT state. Whereas dyad 23 undergoes rapid non-radiative decay to the ground state, the more hindered dyad 26 has a long-lived ICT state with moderate-to-high fluorescence quantum efficiency.

Femtosecond transient absorption measurements were performed using a Ti:sapphire regenerative amplifier (Coherent Legend, 3.5 mJ, 35 fs, 1 kHz repetition rate). Approximately 10% of the amplifier output was used to pump a type II OPA (Spectra Physics OPA-80OC) resulting in the generation of excitation pulses centered at 508 nm with 11.5 nm of bandwidth. At the sample position, the pump was lightly focused to a spot size of 0.29 mm (FWHM) using a 50 cm CaF₂ lens. Probe pulses were generated by focusing a small amount of the amplifier output into a rotating CaF₂ plate, yielding a supercontinuum spanning the range of 320-950 nm. A pair of off-axis aluminum parabolic mirrors collimated the supercontinuum probe and focused it into the sample.

Samples consisting of either dyad 23 or 26 dissolved in the appropriate solvent were held in a 1 cm path length quartz cuvette and had a peak optical density between 0.13 and 0.18. Data were collected for perpendicularly oriented pump and probe. This allowed for the suppression of scatter originating from the pump beam by passing the probe through an analyzing polarizer after the sample. A spectrograph (Oriel MS1271) was used to disperse the supercontinuum probe onto a 256 pixel silicon diode array (Hamamatsu) that enabled multiplex detection of the transmitted probe as a function of wavelength. An optical chopper was used to block every other pump pulse, allowing for differential detection of the pump-induced changes in the probe. The data in the main text represent the average probe transmission change measured for 1500 on/off pump pulse pairs.

At early time delays, a strong non-resonant signal from the sample cell and solvent is observed, but relaxes within 300 fs. Careful measurement of this non-resonant signal enabled its partial subtraction from the transient data. The non-resonant solvent response also provided a measure of the temporal dispersion of the supercontinuum probe resulting from propagation through the CaF₂ plate and sample. The presented data have been corrected to account for this dispersion.

Transient experiments were carried out using a pump fluence of 265 uJ/cm². Based on the cross sections of dyads 23 and 26, at this fluence we expect less than one excitation per dyad molecule. Transient experiments carried out at a fluence of 135 uJ/cm² scaled linearly with those measured at higher fluence and yielded similar fit time constants, suggesting that annihilation processes do not contribute to the signal.

The measured transient spectra indicate that in dyad 23, the initially excited population evolves over time to form an ICT state that non-radiatively returns to the ground state while in dyad 26 the ICT state persists for nanosecond or longer time scales. To obtain rates for the formation of the ICT state in either dyad as well as for the non-radiative repopulation of the ground state in dyad 23, it is assumed that the transient spectra can be described using a three-state model governed by a series of sequential first order rate processes:

$${S}_{1} {\to }^{{K}_{ICT}} ICT {\to }^{{K}_{nr}} {S}_{o} \qquad ( S 1 )$$

where k_{ICT} and kₙᵣ denote the rates for the formation of the ICT state and non-radiative return to the ground state, respectively. On the basis of Eq S1 we can linearly decompose the transient spectra of either dyad, S(λ,t), as:

S(λ,t)=c_{S1}(t)σ_{S1}(λ)+c_{ICT}(t)σ_{ICT}(λ). (S2)

Here, c_{S1}(t) and c_{ICT}(t) denote their time-dependent populations of the S₁ and ICT states of a given dyad, while σ_{S1}(λ) and σ_{ICT}(λ) represent the time-independent characteristic transient absorption spectrum that results from the population of either state. These basis spectra contain both positive features due to excited state absorption and negative going peaks due to a combination of stimulated emission and ground state depopulation (bleaching).

The time dependent behavior of c_{S1}(t) and C_{ICT}(t) is given by the solution to the set of coupled differential equations implied by Eq. S1:

$$\frac{d {c}_{S 1} ( t )}{d t} = {I}_{o} - {k}_{ICT} {c}_{S 1} ( t ) \\ \frac{d {c}_{ICT} ( t )}{d t} = {k}_{ICT} {C}_{S 1} ( t ) - {k}_{nr} {c}_{ICT} ( t ) \qquad ( S 3 )$$

where I₀ is the initial population placed in the SI state by the excitation pulse. To model the behavior of dyad 23 in acetonitrile, both k_{ICT} and kₙᵣ were determined through a least squares minimization routine. Since transient spectra of 26 in dichloromethane showed minimal signatures of non-radiative relaxation to the ground state over the course of the experimental time window (1 ns), kₙᵣ was constrained to match the non-radiative decay rate of 26 determined by luminescence measurements (1.4×10⁸ S⁻¹).

The fits that result from the global analysis model appear alongside the experimental transients plotted in FIG. 21(b) and FIG. 32. Overall, the agreement between the experimental data and our model is quite good. Regarding dyad 23, FIG. 21(b) shows that the disclosed model reproduces the growth of the induced absorption at 550 nm resulting from formation of the ICT state (1/k_{ICT}=4.8 ps). This feature subsequently decays at a rate that matches the recovery of the ground state bleach at 507 om (1/kₙᵣ=34 ps), indicating that decay of the ICT state results in refilling of the ground state. In contrast, the ICT state of dyad 26 develops nearly an order of magnitude faster than that of dyad 23 (1/k_{ICT}=570 fs) as evidenced by the rapid formation of an induced absorption band at 575 nm (FIG. 32), but shows no indication of ground state reformation over the experimental time window (1 ns).

Crystal Data and Structure Refinement for Dyad 23

| | |
|---|---|
| Empirical formula | C₂₈H₂₄B₂F₄N₄ |
| Formula weight | 514.13 |
| Temperature | 123(2) K |
| Wavelength | 0.71073 \acute{Å} |
| Crystal System | Orthorhombic |
| Space group | Pbca |
| Unite cell dimensions | a = 12.808(3) \acute{Å} α = 90°. |
| Volume | b = 12.205(2) \acute{Å} β = 90°. |
| | c = 15.019(3) \acute{Å} γ = 90°. |
| | 2347.8(8) \acute{Å}³ |
| Z | 4 |
| Density (calculated) | 1.455 Mg/m³ |
| Absorption coefficient | 0.108 mm⁻¹ |
| F(000) | 1064 |
| Crystal Size | 0.10 × 0.09 × 0.07 mm³ |
| Theta range for data collection | 2.67 to 27.55°. |
| Index ranges | −16 <= h <= 16, −10 <= k <= |
| | 15, −19 <= l <= 18 |
| Reflections collected | 13598 |
| Independent reflections | 2688 [R(int) = 0.1065] |
| Completeness to theta = 25.00° | 100.0% |
| Absorption correction | Semi-empirical from equivalents |
| Max. and min. transmission | 0.7456 and 0.5788 |
| Refinement method | Full-matrix least-squares on F² |
| Data/restraints/parameters | 2688/0/174 |
| Goodness-of-fit on F² | 1.119 |
| Final R indices [I > 2sigma(I)] | R1 = 0.0571, wR2 = 0.0838 |
| R indices (all data) | R1 = 0.1215, wR2 = 0.0926 |
| Largest diff. peak and hole | 0.285 and −0.209 e.\acute{Å}³ |

The combination of strong visible-light absorption and excited-state ICT make dyads 23 and 26, as well as their analogues, promising candidates for applications such as those described above, where organic materials with accessible ICT states efficiently move singlet excitation energy to a D/A interface before undergoing intramolecular charge transfer to maximize the rate of forward electron transfer while minimizing the reverse interfacial recombination process.

The present disclosure provides for an organic photosensitive optoelectronic device comprising: at least one compound chosen from a higher order structure, wherein said compound's absorptivity of light at some visible wavelength is about >10⁴ M⁻¹ cm⁻¹, and wherein said compound is capable of undergoing symmetry-breaking intramolecular charge transfer in the excited state. The organic photosensitive devices disclosed herein can be, for example, an organic photodetector, or an organic solar cell.

In some embodiments, the at least one compound is chosen from dyads of xanthenes dyes, coumarins, acridines, phthalocyanines, subphthalocyanines, porphyrins, acenes, perylenes, malachites, cyanines, bipyridines, and dipyrrins. In other embodiments, the compound is chosen from even higher order structures such as triads and tetrads.

In some embodiments, the intramolecular charge transfer occurs in a polarizing medium.

In some embodiments, the intramolecular charge transfer in the excited state is energetically accessible from a photogenerated S₁ state in a polarizing medium.

In some embodiments, the dyads may be connected either directly or through a linker (such as saturated or unsaturated linear or branched hydrocarbons, or aromatic rings, e.g., phenylene, or constructed from aryl, fused aryl, such as naphthyl, anthryl, etc., alkyl, alkynyl, alkenyl, a heterocycle, a diazo or organosilane moiety), such that the dyads are arranged in linear or cofacial fashion.

In some embodiments, the higher order compound is 1,4-Bis(4,4-difluoro-3,5-dimethyl-4-bora-3a,4a-diaza-s-indacene-8-yl)benzene or a salt or hydrate thereof. In other embodiments, the higher order compound is Bis(4,4-difluoro-3,5-dimethyl-4-bora-3a,4a-diaza-s-indacene-8-yl), or a salt or hydrate thereof.

A further embodiment is directed to a process for preparing 1,4-Bis(4,4-difluoro-3,5-dimethyl-4-bora-3a,4a-diaza-s-indacene-8-yl)benzene, or a salt or hydrate thereof, comprising treating a mixture comprising terephthalaldehyde and 2-methylpyrrole with a halogenated carboxylic acid, an oxidizing agent, and Lewis acid to form 1,4-Bis(4,4-difluoro-3,5-dimethyl-4-bora-3a,4a-diaza-s-indacene-8-yl)benzene. In further embodiments, the halogenated carboxylic acid can be trifluoroacetic acid, the oxidant can be DDQ and the Lewis acid can be boron trifluoride diethyl etherate.

An additional embodiment is directed to a process for preparing Bis(4,4-difluoro-3,5-dimethyl-4-bora-3a,4a-diaza-s-indacene-8-yl), or a salt or hydrate thereof, comprising treating a mixture comprising a first Lewis acid and a transition metal with a mixture comprising bis(5-methyl-1H-pyrrol-2-yl)methanone to form 1,1,2,2-tetrakis(5-methyl-1H-pyrrol-2-yl)ethene; and treating a mixture comprising 1,1,2,2-tetrakis(5-methyl-1H-pyrrol-2-yl)ethene and a base with an oxidant and second Lewis acid to form Bis(4,4-difluoro-3,5-dimethyl-4-bora-3a,4a-diaza-s-indacene-8-yl). In further embodiments, the first Lewis acid can be TiCl4, the transition metal can be zinc, the base can be triethylamine, the oxidant can be DDQ, and the second Lewis acid can be boron trifluoride diethyl etherate.

The present disclosure also provides for methods of making an organic photosensitive device comprising an organic photosensitive optoelectronic device, wherein said organic photosensitive optoelectronic device comprises: at least one compound chosen from a dyad or higher order structure, wherein said compounds absorptivity of light at some visible wavelength is about >10⁴ M⁻¹ cm⁻¹, and wherein said compound is capable of undergoing symmetry-breaking intramolecular charge transfer in the excited state.

### EXAMPLES

### Example 1

### Synthesis of BenzoBODIPY, IndoBODIPY, and CyanoBODIPY

As shown in FIG. 1, BenzoBODIPY was prepared in two steps from the corresponding pyrrole and aldehyde followed by retro-Diels-Alder deprotection. The required pyrrole was prepared via Barton-Zard synthesis from the necessary precursors with yields generally >80%. The pyrrole carboxylate ester was converted to the methyl pyrrole moiety using lithium aluminum hydride and used without further purification due to its sensitivity to air. Under known conditions for BODIPY synthesis using Hünig's base and BF₃.Et₂O, a yield of about 40% was obtained for the masked BenzoBODIPY. Upon heating, the masked BenzoBODIPY was quantitatively converted to BenzoBODIPY. The materials were then recrystallized into copper-colored crystals and sublimed.

As shown in FIG. 2, IndoBODIPY was prepared by first isolating its corresponding diindolyl-methane precursor. The precursor was isolated using known literature techniques. The boron complex was prepared using conditions identical to those of BenzoBODIPY, though only a yield of 7% was achieved. The materials were recrystallized to give a purple solid.

CyanoBODIPY was prepared using the synthetic scheme shown in FIG. 3.

### Example 2

### Optical Properties of BenzoBODIPY, IndoBODIPY, and CyanoBODIPY

The absorption maxima of the BODIPY dyes disclosed herein, for example BenzoBODIPY and IndoBODIPY, were red-shifted when compared to an unsubstituted BODIPY core. A typical BODIPY core has a solution absorption maximum of −510 nm, but, as shown in FIGS. 7A and 7B, the solution absorption maxima of BenzoBODIPY and IndoBODIPY were at 604 nm and 559 nm, respectively. Furthermore, FIG. 7B shows that the solution absorption of IndoBODIPY broadened significantly, deviating from the narrow bandwidth that is usually observed for this class of materials as exhibited by BenzoBODIPY in FIG. 7A. FIG. 7 also shows that the film excitation of BenzoBODIPY was much wider and more red shifted than the solution absorption due to strong intermolecular interactions. A larger Stokes shift was also observed when comparing solution and solid-state.

The CyanoBODIPY exhibited a sharp maximum around ˜500 nm, as shown in FIG. 8(a). Due to the CyanoBODIPY's smaller π-system than the BenzoBODIPY, a smaller degree of peak broadening and red-shift were observed for thin-film properties, as shown in FIG. 8(b).

Molar absorptivity was measured in a glass cuvette in dichloromethane. A value of 3.03×10⁵M⁻¹ cm⁻¹ was measured for BenzoBODIPY, and a value of 1.46×10⁵ M⁻¹ cm⁻¹ was measured for CyanoBODIPY.

### Example 3

### Photovoltaic Devices Using BenzoBODIPY

Photovoltaic devices using BenzoBODIPY as a donor material and a device using CuPc as a donor material were fabricated on ITO-glass substrates cleaned with Tergitol, alcohols, acetone, followed by UV-ozone treatment. C₆₀ (MTR Limited), 2,9-dimethyl-4,7-diphenyl-1,10-phenanthroline (BCP) (Aldrich), and BenzoBODIPY were purified by sublimation prior to use. Aluminum (Alfa Aesar) was used for metal cathode deposition. All devices were fabricated as lamellar devices in a vacuum deposition chamber with a fixed deposition rate for each layer. Three BenzoBODIPY devices were fabricated each with a different donor layer thickness—10 nm, 20 nm, and 30 nm. Device performance (Current-Voltage curve and external quantum efficiency (EQE)) was measured under simulated AM1.5G solar illumination (Oriel Instruments) using a Keithley 2420 3A Source Meter. The device structures and performance of each device are summarized below and in FIGS. 9A to 9C.

CuPc Device: Glass/ITO/CuPc (40 nm)/C₆₀ (40 nm)/BCP (10 nm)/Al
BenzoBODIPY Device: Glass/ITO/BDPY (30-10 nm)/C₆₀ (40 nm)/BCP (10 nm)/Al.

The Current-Voltage curves are shown in FIG. 9A. The external quantum efficiencies (EQEs) are plotted in FIG. 9B. The dark current curves are shown in FIG. 9C. The performance data is recorded in Table 7. As shown in Table 7, device performance was dependent on the thickness of the donor layer. These experiments led to an optimal thickness around 20 nm, at which the device demonstrated the highest short-circuit current of 12.4 mA/cm². Although increasing the thickness generally increases the open-circuit voltage, the V_{OC} averaged out at around 730 mV for the two thicker devices. The 10 nm device may have had aggregates of donor materials, forming islands on the surface and leaving direct C₆₀ and ITO contact. Lack of complete coverage on the surface may have led to a drop in potential and charge generation. With a fill factor of 0.53, the highest performing device achieved a power conversion efficiency (PCE) of 4.17%.

TABLE 7
Photovoltaic Data for BenzoBODIPY Devices

| | J_{SC} | | | | | | |
|---|---|---|---|---|---|---|---|
| | (mA/ | V_{OC} | | η | | Jₛ | Rₛ |
| | cm²) | (V) | FF | (%) | n | (μA/cm²) | (kΩ/cm²) |
| 30 nm | 9.51 | 0.73 | 0.45 | 3.09 | 2.53 | 0.14 | 0.25 |
| 20 nm | 12.4 | 0.629 | 0.53 | 4.17 | 1.8 | ~0 | ~0 |
| 10 nm | 5.49 | 0.283 | 0.44 | 0.67 | 3.1 | 13.1 | 28.8 |
| CuPc | 6.53 | 0.494 | 0.60 | 1.92 | 1.88 | 0.34 | 0.88 |

An additional study was performed using device structures identical to the previous example, except that the thickness of the BenzoBODIPY donor layer was further varied (40, 70, 100, and 130 nm). Current-voltage curves are shown in FIG. 10(a). The EQEs are shown in FIG. 10(b). The performance of each device is summarized in Table 8 below. The highest performing device achieved a PCE of 5.68%. Increasing the donor layer initially improved device performance, but performance dropped between 70 nm and 100 nm BenzoBODIPY thickness. The decrease in performance for thicker devices was mainly due to the overall drop in

TABLE 8
Photovoltaic Data for BenzoBODIPY Devices

| | J_{SC} | | | | | | |
|---|---|---|---|---|---|---|---|
| | (mA/ | V_{OC} | | η | | J_{S} | R_{S} |
| | cm²) | (V) | FF | (%) | n | (μA/cm²) | (kΩ*cm²) |
| 40 nm | 9.84 | 0.812 | 0.50 | 3.96 | 1.66 | 1.84 × 10 [symbol] | 0.7 |
| 70 nm | 11.0 | 0.814 | 0.63 | 5.68 | 1.59 | 2.02 × 10 [symbol] | 2.59 |
| 100 nm | 10.8 | 0.786 | 0.65 | 5.48 | 1.72 | 1.30 × 10⁻⁴ | 0.57 |
| 130 nm | 10.1 | 0.793 | 0.66 | 5.29 | 3.27 | 0.15 | 0.09 |

[symbol]

indicates data missing or illegible when filed

Further data was generated at certain BenzoBODIPY thicknesses (20, 25, 30, 35 nm) using the device structures above, except that the devices were thermally annealed prior to deposition of the C₆₀ layer. The glass substrate, ITO and BenzoBODIPY layers were heated. The thermal treatment was performed under nitrogen at 100° C. for 15 minutes. Current-voltage curves are shown in FIG. 11(a). The EQEs are shown in FIG. 11(b). The performance of each device is summarized in Table 9 below. Device performances for all thicknesses were significantly worse than standard devices. The J-V curves were S-shaped, suggesting energetic barriers that may have resulted from trap-states generated from increased crystalline boundaries of the donor material. Compared to unannealed films, the film annealed prior to C₆₀ deposition exhibited a red shift in absorption, as shown in FIG. 11(c), suggesting an increase in crystallinity from a higher degree of π-π interaction between crystalline domains. No beneficial effect was observed for thermally annealing the devices before the deposition of C₆₀. Even though the EQE showed similar photoresponse from different thicknesses, all parameters suffered from the pre-C₆₀ thermal treatment with lower currents, voltages, and fill factors. The decrease in power conversion efficiency may have been due to the crystallinity of the donor layer after thermal annealing.

TABLE 9
Photovoltaic Data for BenzoBODIPY Devices Thermally
Treated Before Deposition of Acceptor Layer

| | J_{SC} | | | | | | |
|---|---|---|---|---|---|---|---|
| | (mA/ | V_{OC} | | η | | J_{S} | R_{S} |
| | cm²) | (V) | FF | (%) | n | (μA/cm²) | (kΩ*cm²) |
| 20 nm | 5.85 | 0.280 | 0.40 | 0.65 | 1.83 | 2.77 | 0.62 |
| 25 nm | 0.187 | 0.332 | 0.10 | 0.006 | 5.51 | 3 | 60.1 |
| 30 nm | 0.120 | 0.362 | 0.09 | 0.00 | 5.56 | 1.54 | 161.4 |
| 35 nm | 0.0649 | 0.391 | 0.09 | 0.00 | 5.81 | 0.75 | 493.1 |

Additional data was generated at certain BenzoBODIPY thicknesses (40, 70, 100, 130 nm) using the device structures above, except that the devices were thermally annealed post deposition of the C₆₀ layer. Current-voltage curves are shown in FIG. 12(a). The EQEs are shown in FIG. 12(b). The performance of each device is summarized in Table 10 below. Thermal treatment post deposition of C₆₀ showed improvements in J_{SC}, with a slight drop in V_{OC} and fill factor. Performance similar to unannealed devices was obtained.

TABLE 10
Photovoltaic Data for BenzoBODIPY Devices Thermally
Treated After Deposition of Acceptor Layer

| | J_{SC} | | | | | | |
|---|---|---|---|---|---|---|---|
| | (mA/ | V_{OC} | | η | | J_{S} | R_{S} |
| | cm²) | (V) | FF | (%) | n | (μA/cm²) | (kΩ*cm²) |
| 40 nm | 11.6 | 0.771 | 0.45 | 4.00 | 2.46 | 0.02 | 0.12 |
| 70 nm | 11.5 | 0.774 | 0.57 | 5.07 | 1.76 | 1.87 × 10⁻4 | 1.63 |
| 100 nm | 10.9 | 0.766 | 0.60 | 5.02 | 1.62 | 8.05 × 10⁻5 | 3.79 |
| 130 nm | 11.2 | 0.774 | 0.59 | 5.15 | 1.61 | 5.67 × 10⁻⁵ | 4.98 |

### Example 4

### Photovoltaic Devices Using CyanoBODIPY

CyanoBODIPY purified by sublimation was used in preparing the devices. The devices were prepared and tested under the conditions described above in Example 3. Unannealed and annealed CyanoBODIPY devices employed copper phthalocyanine (CuPc) as an electron donor material and a 1:1 ratio codeposited layer of CyanoBODIPY and C₆₀ as an electron acceptor. A control device using CuPc and C₆₀ as donor and acceptor layers, respectively, was also fabricated. For the annealed device, the device was heated at 110° C. under nitrogen for 10 minutes after deposition of the acceptor layer. The device structures are summarized as follows:

### CyanoBODIPY Device:

Glass/ITO/CuPc (40 nm)/CyanoBDPY:C₆₀ 1:1 (40 nm)/BCP (10 nm)/Al

### CuPc Device:

Glass/ITO/CuPc (40 nm)/C₆₀ (40 nm)/BCP (10 nm)/Al.

Current-voltage curves for the devices are shown in FIG. 13(a). The EQEs are shown in FIG. 13(b). The performance of each device is summarized in Table 11 below. The devices performed at about 50% PCE of analogous CuPc/C₆₀ devices. The fill factor is similar, presumably due to similar donor-acceptor interfaces as with CuPc/C₆₀ devices. All other parameters were lower with respect to the control device. The open-circuit voltage was a few hundred millivolt lower and the short-circuit current was about half of the control device. The drop in PCE is predominantly due to the loss in photoresponse from CuPc. The loss in C₆₀ absorption around 420 nm was roughly compensated by the CyanoBODIPY absorption at 520 nm. However, there was about a 50% loss in the region where CuPc absorbs, which was similarly reflected in the PCE. Thermal treatment for the CyanoBODIPY devices showed no beneficial effects on the performance.

TABLE 11
Photovoltaic Data for CyanoBODIPY Devices

| | J_{SC} | | | | | | |
|---|---|---|---|---|---|---|---|
| | (mA/ | V_{OC} | | η | | Jₛ | Rₛ |
| | cm²) | (V) | FF | (%) | n | (μA/cm²) | (kΩ*cm²) |
| Unannealed | 3.11 | 0.451 | 0.61 | 0.85 | 1.89 | 0.21 | 1.39 |
| Annealed | 2.77 | 0.446 | 0.60 | 0.74 | 1.68 | 0.1 | 2.33 |
| CuPc | 6.44 | 0.491 | 0.58 | 1.85 | 1.91 | 0.42 | 0.71 |

### Examples 5-9

### General Considerations

2-Methylpyrrole was obtained by a Wolff-Kishner reduction of pyrrole-2-carboxaldehyde as previously described. 1-Methyl-4,7-dihydro-2H-4,7-ethanoisoindole was prepared by lithium aluminum hydride reduction of the corresponding ester according to literature procedure. All other reagents were purchased from commercial vendors and used without further purification. All air-sensitive manipulations were performed using standard Schlenk techniques as needed, following the procedures indicated below for each preparation. NMR spectra were recorded at ambient temperature on Varian Mercury 400 MHz and 600 MHz spectrometers. ¹H chemical shifts were referenced to residual solvent. UV-vis spectra were recorded on a Hewlett-Packard 4853 diode array spectrophotometer. Steady-state emission experiments were performed using a Photon Technology International QuantaMaster Model C-60SE spectrofluorimeter. Fluorescence lifetime measurements were performed by a time-correlated single-photon counting method using an IBH Fluorocube lifetime instrument by equipped with a 405 nm or 435 nm LED excitation source. Quantum efficiency measurements were carried out using a Hamamatsu C9920 system equipped with a xenon lamp, calibrated integrating sphere and model C10027 photonic multichannel analyzer.

### Example 5

### General Reaction Scheme for Phenylene Bridged Dyads 23, 24 and 25 of FIG. 16A

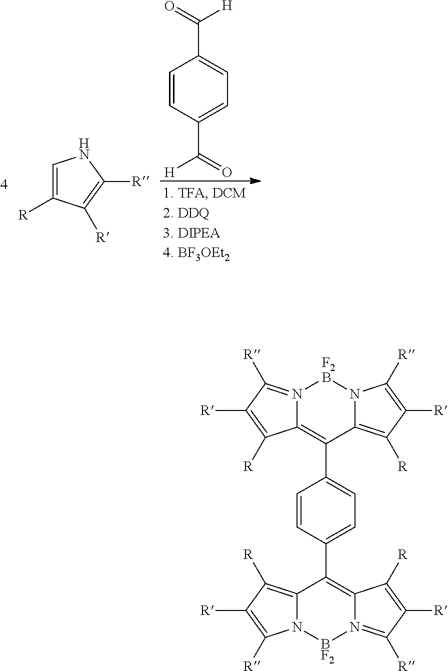

Phenylene Bridged Dyad 23.

Terephthalaldehyde (762 mg, 5.68 mmol) and 2-methylpyrrole (2.03 g, 23.3 mmol) were dissolved in dry, degassed CH₂Cl₂ (40 mL) under N₂. The resulting solution was further degassed for 10 min, and trifluoroacetic acid (64 μL, 0.84 mmol) was added in two portions, causing the solution to darken immediately, and the reaction was allowed to proceed with stirring for 2 h. DDQ (2.58 g, 11.4 mmol) was added in one portion, causing an immediate color change to dark red-orange, and the resulting mixture was stirred for 13 h. N,N-Diisopropylethylamine (8.0 mL, 46 mmol) was added at once, causing a color change to dark brown, and stirring was continued for 15 min. Boron trifluoride diethyl etherate (8.0 mL, 64 mmol) was added slowly over the course of 1 min, causing the mixture to warm slightly. After 45 min, the mixture was quenched with NaHCO₃ (5% aq, 200 mL) and stirred vigorously for 2 h. Organics were removed and washed with Na₂SO₃ (10% aq, 2×100 mL), HCl (5% aq, 1×100 mL), and brine (2×100 mL). The organics were removed and dried with MgSO₄, filtered, and concentrated to a dark solid, which was purified by column chromatography (SiO₂ gel, CHCl₃ eluent, R_{f}=0.5) to afford dyad 23 as a pure red-orange solid (200 mg, 7%). UV-vis (CH₂Cl₂) λₘₐₓ: 350, 513. ¹H NMR (CDCl₃): δ 7.62 (s, 4H, phenylene Ar—H), 6.76 (d, ³J_{HH}=4.4 Hz, 4H, BODIPY Ar—H), 6.31 (d, ³J_{HH}=4.4 Hz, 4H, BODIPY Ar—H), 2.68 (s, 12H, —CH₃). ¹³C NMR (CDCl₃): δ 158.38, 141.14, 135.94, 134.47, 130.41, 130.32, 119.91, 15.13. MALDI, m/z for C₂₈H₂₄B₂F₄N₄ calcd 514.21 (100%), 513.22 (51%), 515.22 (33%). found 512.83 (100%), 511.83 (51%), 513.82 (45%).

Phenylene Bridged Dyad 24.

Terephthalaldehyde (1 g, 7.55 mmol) and 2,4-dimethylpyrrole (2.98 g, 31.3 mmol) were dissolved in dry, degassed CH₂Cl₂ (30 mL) under N₂. The resulting solution was further degassed for 10 min, and trifluoroacetic acid (1 drop) was added and the reaction was allowed to proceed with stirring for 5 h. DDQ (3.38 g, 14.9 mmol) was added in one portion, and the resulting mixture was stirred overnight. N,N-Diisopropylethylamine (10.4 mL, 59.6 mmol) was added at once, and stirring was continued for 15 min. Boron trifluoride diethyl etherate (7.5 mL, 59.6 mmol) was added. After 45 min, the mixture was quenched with NaHCO₃ (5% aq, 200 mL) and stirred vigorously for 2 h. Organics were removed and washed with Na₂SO₃ (10% aq, 2×100 mL), HCl (5% aq, 1×100 mL), and brine (2×100 mL). The organics were removed and dried with MgSO₄, filtered, and concentrated to a dark solid, which was purified by column chromatography (SiO₂ gel, CH₂Cl₂ eluent) to afford dyad 24 as a pure red-orange solid (427 mg, 10%). ¹H NMR (CDCl₃): δ 7.52 (s, 4H, phenylene Ar—H), 6.01 (s, 4H, BODIPY Ar—H), 2.57 (s, 12H, —CH₃), 1.53 (s, 12H, —CH₃).

Phenylene Bridged Dyad 25.

Terephthalaldehyde (1 g, 7.46 mmol) and 2,4-dimethyl-3-ethylpyrrole (3.67 g, 29.8 mmol) were dissolved in dry, degassed CH₂Cl₂ (40 mL) under N₂. The resulting solution was further degassed for 10 min, and trifluoroacetic acid (1 drop) was added and the reaction was allowed to proceed with stirring for 2 h. DDQ (3.39 g, 14.9 mmol) was added in one portion, causing an immediate color change to dark red-orange, and the resulting mixture was stirred for 13 h. N,N-Diisopropylethylamine (10.4 mL, 59.7 mmol) was added at once, causing a color change to dark brown, and stirring was continued for 15 min. Boron trifluoride diethyl etherate (7.5 mL, 59.7 mmol) was added slowly over the course of 1 min, causing the mixture to warm slightly. After 45 min, the mixture was quenched with NaHCO₃ (5% aq, 200 mL) and stirred vigorously for 2 h. Organics were removed and washed with Na₂SO₃ (10% aq, 2×100 mL), HCl (5% aq, 1×100 mL), and brine (2×100 mL). The organics were removed and dried with MgSO₄, filtered, and concentrated to a dark solid, which was purified by column chromatography (SiO₂ gel, CHCl₃ eluent) to afford dyad 25 as a pure red-orange solid (254 mg, 5%). ¹H NMR (CDCl₃): δ 7.51 (s, 4H, phenylene Ar—H), 2.55 (s, 12H, —CH₃), 2.32 (q, 8H, —CH₂), 1.47 (s, 12H), 1.00 (t, 12H).

### Example 6

### General Reaction Scheme for Directly Linked Dyads 26, 27, 28, and 29 of FIGS. 16B and 16C

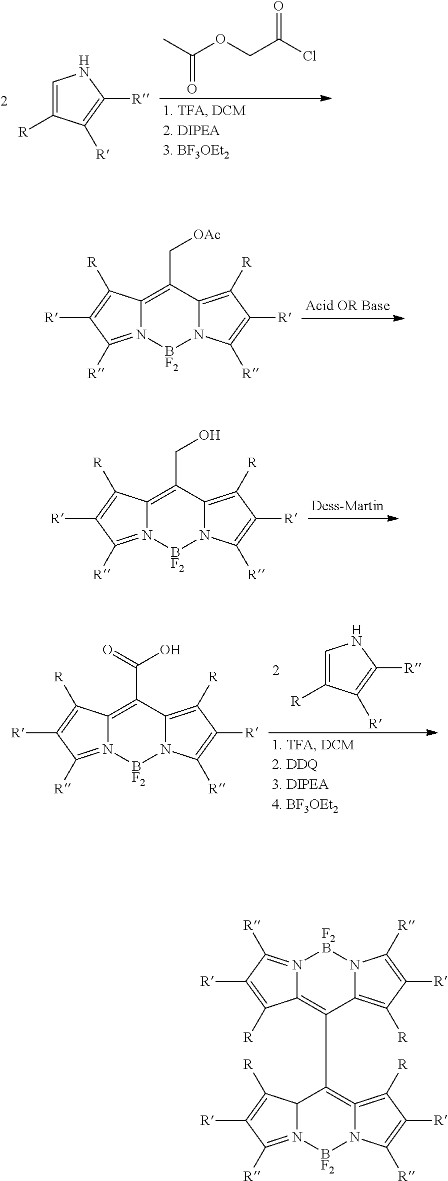

Directly Linked Dyad 26.

2-Methylpyrrole (2.01 g, 24.8 mmol) was dissolved in dry, degassed CH₂Cl₂ (20 mL) in an oven-dried three-necked flask that had been purged with N₂. The solution was cooled to 0° C. and acetoxyacetyl chloride (2.02 g, 14.8 mmol) was added in one portion in the dark and the reaction was allowed to proceed with stirring for 1 h, during which time the color turned dark red. N,N-Diisopropylethylamine (8.58 mL, 49.3 mmol) was added at room temperature, causing a color change to clear orange, and stirring was continued for 30 min followed by dropwise addition of BF₃.OEt₂ (6.18 mL, 49.3 mmol). During addition of BF₃.OEt₂ the color changed to dark red. The reaction was left stirring for 30 min and then was concentrated and purified by flash chromatography (SiO₂ gel, 25% CH₂Cl₂/hexanes, R_{f}=0.14) to yield 8-acetoxymethyl-4,4-difluoro-3,5-dimethyl-4-boro-3a,4a-diaza-s-indacene as a gold-pink solid (235 mg, 11%). ¹H NMR (CDCl₃, 600 MHz): δ 7.18 (d, ³J_{HH}=4.2 Hz, 2H, BODIPY Ar—H), 6.30 (d, ³J_{HH}=4.2 Hz, 2H, BODIPY Ar—H), 5.22 (s, 2H, —CH₂), 2.62 (s, 6H, —CH₃), 2.09 (s, 3H, —COCH₃). ¹³C NMR (CDCl₃, 600 MHz): δ 170.20, 158.96, 134.60, 133.97, 127.98, 119.84, 59.11, 20.85, 14.98. HRMS for C₁₄H₁₆BN₂O₂F₂ (MH+) calcd 293.1267. found 293.1261. 8-Acetoxymethyl-4,4-difluoro-3,5-dimethyl-4-boro-3a,4a-diaza-s-indacene (350 mg, 1.20 mmol) was dissolved in acetone (60 mL) and a solution of 4 M HCl (36 mL) was added. A condenser was fitted to the flask and the reaction was heated to 40° C. until the solution turned green and the TLC showed no starting material. The crude mixture was diluted with CH₂Cl₂, washed with water (2×75 mL), saturated NaHCO₃ (2×75 mL) and the organic layer was removed, dried over MgSO₄, filtered, concentrated and purified by flash chromatography (SiO₂ gel, CH₂Cl₂, R_{f}=0.16) to afford 8-hydroxymethyl-4,4-difluoro-3,5-dimethyl-4-boro-3a,4a-diaza-s-indacene as a red-gold solid (210 mg, 71%). ¹H NMR (CDCl₃, 600 MHz): δ 7.23 (d, ³J_{HH}=4.2 Hz, 2H, BODIPY Ar—H), 6.97 (s, 1H, —OH), 6.27 (d, ³J_{HH}=4.2 Hz, 2H, BODIPY Ar—H), 4.79 (s, 2H, —CH₂), 2.60 (s, 6H, —CH₃). ¹³C NMR (CDCl₃, 600 MHz) δ 158.41, 139.17, 133.97, 127.59, 119.53, 59.45, 14.93. HRMS for C₁₂H₁₄BN₂OF₂ (MH+) calcd 251.1162. found 251.1167. 8-hydroxymethyl-4,4-difluoro-3,5-dimethyl-4-boro-3a,4a-diaza-s-indacene (200 mg, 0.8 mmol) was dissolved in dry, degassed CH₂Cl₂ (15 mL) and was cannulated into a solution of Dess-Martin periodinane (509 mg, 1.20 mmol) in dry, degassed CH₂Cl₂ (15 mL) at 0° C. The solution was allowed to warm to room temperature and left stirring for 1 h. When the TLC showed no starting material the reaction was quenched with saturated Na₂S₂O₃ (50 mL), washed with saturated NaHCO₃ (2×50 mL) and water (2×50 mL). The organic layer was removed, dried over MgSO₄, filtered and concentrated, then purified by passing through a plug of SiO₂ gel with CH₂Cl₂ (R_{f}=0.38). 8-Formylmethyl-4,4-difluoro-3,5-dimethyl-4-boro-3a,4a-diaza-s-indacene was collected as a dark purple solid (164 mg, 83%). ¹H NMR (CDCl₃, 600 MHz): δ 10.33 (s, 1H, —CHO), 7.51 (d, ³J_{HH}=4.2 Hz, 2H, BODIPY Ar—H), 6.40 (d, ³J_{HH}=4.2 Hz, 2H, BODIPY Ar—H), 2.65 (s, 6H, —CH₃). ¹³C NMR (CDCl₃, 600 MHz) δ 188.75, 161.39, 134.87, 129.74, 125.87, 121.86, 15.33. HRMS for C₁₂H₁₂BN₂OF₂ (MH+) calcd 249.1005. found 249.1008. 8-Formyl-4,4-difluoro-3,5-dimethyl-4-boro-3a,4a-diaza-s-indacene (36 mg, 0.15 mmol) was dissolved in dry, degassed CH₂Cl₂ (10 mL) and 2-methylpyrrole (24 mg, 0.29 mmol) was added. The reaction was monitored by TLC until no starting material remained. DDQ (33 mg, 0.15 mmol) was added in one portion and the reaction was monitored by TLC until the condensation product was consumed. N,N-Diisopropylethylamine (0.10 mL, 0.58 mmol) was added in one portion, followed after 15 min by dropwise addition of BF₃.OEt₂ (0.07 mL, 0.6 mmol). The reaction was left stirring for 15 min and then was quenched with saturated Na₂S₂O₃ (25 mL), washed with saturated NaHCO₃ (2×50 mL) and the organic layer was removed. The crude mixture was dried over MgSO₄, filtered and passed through a plug of SiO₂ gel using CH₂Cl₂ (R_{f}=0.33) to recover a dark pink-green solid (25 mg, 38%). UV-vis (CH₂Cl₂) Δₘₐₓ: 334, 530. ¹H NMR (CDCl₃, 400 MHz): δ 6.84 (d, ³J_{HH}=4.4 Hz, 4H, BODIPY Ar—H), 6.23 (d, ³J_{HH}=4.4 Hz, 4H, BODIPY Ar—H), 2.65 (s, 12H, —CH₃). ¹³C NMR (CDCl₃, 600 MHz) δ 159.55, 135.04, 131.87, 130.06, 120.13, 15.06. HRMS for C₂₂H₂₁B₂N₄F₄ (MH+) calcd 439.1883. found 439.1893.

### Directly Linked Dyad 26 (Alternate Synthetic Scheme).

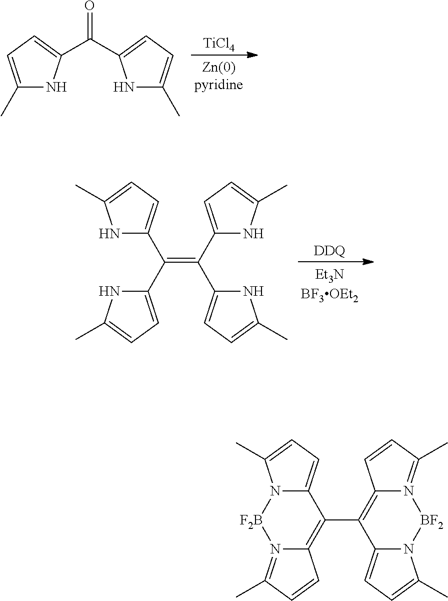

### Step 1: 1,1,2,2-tetrakis(5-methyl-1H-pyrrol-2-yl)ethene

Titanium tetrachloride (87 uL, 0.80 mmol) was added dropwise to a solution of dry THF (15 mL) at 0° C. under nitrogen. The solution was stirred for 10 min, after which a suspension of zinc powder (98 mg, 1.5 mmol) in 3 mL of dry THF was added via cannula. The resulting blue slurry was heated at reflux for 3 h and cooled to room temperature. Dry pyridine (55 uL, 0.68 mmol) was added and the solution set to reflux for 30 min. After cooling to room temperature, bis(5-methyl-1H-pyrrol-2-yl)methanone in 3 mL of dry THF was added via cannula, and the solution refluxed for 3 h. The reaction was cooled to room temperature and poured into 100 mL of K₂CO₃ solution (10% aq), which was then stirred vigorously for 10 min. Organics were removed by extraction into dichloromethane, and washed with water (2×50 mL) and brine (1×50 mL), and dried over MgSO₄. Solvent was removed, and the crude product used without further purification. MALDI, m/z for C₂₂H₂₄N₄ calcd 344.20. found 344.41.

### Step 2: Bis(4,4-ditluoro-3,5-dimethyl-4-bora-3a,4a-diaza-s-indacene-8-yl)

1,1,2,2-tetrakis(5-methyl-1H-pyrrol-2-yl)ethene (90 mg, 0.26 mmol) was dissolved in dry, degassed CH₂Cl₂ (15 mL) under N₂. The solution was degassed for an additional 5 min, and Et₃N (0.29 mL, 2.0 mmol) added by syringe. The resulting solution was stirred for 30 min at room temperature and DDQ (68 mg, 0.30 mmol) added. The solution was allowed to stir for an additional 30 min, after which boron trifluoride diethyl etherate (0.331 mL, 2.62 mmol) was added slowly. After 2 h, the mixture was quenched with saturated NaHCO₃ and stirred overnight. The organics were removed and washed with Na₂SO₃ (10% aq, 3×25 mL), water (2×25 mL), and brine (2×25 mL). The organics were dried over MgSO₄, filtered, and concentrated to a dark red oil, which was purified by column chromatography (SiO₂ gel, 1:1 CH₂Cl₂:hexanes, Rr=0.35) to afford dyad 26 as a pink solid (3 mg, 3%). A small quantity of green reflective crystals was obtained by slow evaporation from a CHCl₃ solution of 26 at room temperature. These were used for photophysical analysis, but were too thin for X-ray diffraction studies. UV-vis (CH₂Cl₂) λmax: 334,530. ¹H NMR (CDCl₃): δ 6.84 (d, ³J_{HH}=4.2 Hz, 4H, BODIPY Ar—H), 6.23 (d, ³J_{HH}=4.2 Hz, 4H, BODIPY Ar—H), 2.65 (s, 12H, —CH₃). MALDI, m/z for C₂₂H₂₀B₂F₄N₄ calcd 438.18 (100%),437.18 (49%), 439.18 (25%). found 437.94 (100%), 438.96 (61%), 437.01 (45%).

Directly Linked Dyad 27.

8-Formyl-4,4-difluoro-1,3,5,7-tetramethyl-4-boro-3a,4a-diaza-s-indacene was synthesized similarly to 8-formyl-4,4-difluoro-3,5-dimethyl-4-boro-3a,4a-diaza-s-indacene. 8-Formyl-4,4-difluoro-1,3,5,7-tetramethyl-4-boro-3a,4a-diaza-s-indacene (97 mg, 0.35 mmol) was dissolved in dry, degassed CH₂Cl₂ (30 mL) and 2,4-dimethylpyrrole (70 mg, 0.74 mmol) was added. The reaction was monitored by TLC until no starting material remained. DDQ (80 mg, 0.35 mmol) was added in one portion and the reaction was monitored by TLC until the condensation product was consumed. N,N-Diisopropylethylamine (0.25 mL, 14 mmol) was added in one portion, followed after 15 min by dropwise addition of BF₃.OEt₂ (0.18 mL, 14 mmol). The reaction was left stirring for 15 min and then was quenched with saturated Na₂S₂O₃ (25 mL), washed with saturated NaHCO₃ (2×50 mL) and the organic layer was removed. The crude mixture was dried over MgSO₄, filtered and passed through a plug of SiO₂ gel using CH₂Cl₂ to recover a dark pink-green solid (25 mg, 38%). ¹H NMR (CDCl₃): δ 6.02 (s, 4H, BODIPY Ar—H), 2.56 (s, 12H, —CH₃), 1.89 (s, 12H, —CH₃).

Directly Linked Dyad 28.

8-Formyl-4,4-difluoro-1,3,5,7-tetramethyl-2,6-diethyl-4-boro-3a,4a-diaza-s-indacene was synthesized similarly to 8-formyl-4,4-difluoro-1,3,5,7-tetramethyl-4-boro-3a,4a-diaza-s-indacene. 8-Formyl-4,4-difluoro-1,3,5,7-tetramethyl-2,6-diethyl-4-boro-3a,4a-diaza-s-indacene (208 mg, 0.63 mmol) was dissolved in dry, degassed CH₂Cl₂ (20 mL) and 2,4-dimethyl-3-ethylpyrrole (154 mg, 0.91 mmol) was added. The reaction was monitored by TLC until no starting material remained. DDQ (142 mg, 0.63 mmol) was added in one portion and the reaction was monitored by TLC until the condensation product was consumed. N,N-Diisopropylethylamine (0.44 mL, 2.5 mmol) was added in one portion, followed after 15 min by dropwise addition of BF₃.OEt₂ (0.32 mL, 2.5 mmol). The reaction was left stirring for 15 min and then was quenched with saturated Na₂S₂O₃ (25 mL), washed with saturated NaHCO₃ (2×50 mL) and the organic layer was removed. The crude mixture was dried over MgSO₄, filtered and passed through a plug of SiO₂ gel using CH₂Cl₂ to recover a dark pink-green solid (42 mg, 11%). ¹H NMR (CDCl₃): 2.55 (s, 12H, —CH₃), 2.32 (q, 8H, —CH₂), 1.81 (s, 12H, —CH₃), 0.96 (t, 12H, —CH₃). MALDI, m/z for C₂₂H₂₀B₂F₄N₄ calcd 606.37 found 605.74.

Directly Linked Dyad 29.

8-Formyl-4,4-difluoro-3,5-dimethyl-4-boro-3a,4a-diaza-1,2,6,7-ethanoisoindole was synthesized similarly to 8-formyl-4,4-difluoro-1,3,5,7-tetramethyl-4-boro-3a,4a-diaza-s-indacene. 8-Formyl-4,4-difluoro-3,5-dimethyl-4-boro-3a,4a-diaza-1,2,6,7-ethanoisoindole (37 mg, 0.10 mmol) was dissolved in dry, degassed CH₂Cl₂ (10 mL) and 1-methyl-4,7-dihydro-2H-4,7-ethanoisoindole (32 mg, 0.20 mmol) was added. The reaction was monitored by TLC until no starting material remained. DDQ (22 mg, 0.10 mmol) was added in one portion and the reaction was monitored by TLC until the condensation product was consumed. N,N-Diisopropylethylamine (0.07 mL, 0.04 mmol) was added in one portion, followed after 15 min by dropwise addition of BF₃.OEt₂ (0.05 mL, 0.04 mmol). The reaction was left stirring for 15 min and then was quenched with saturated Na₂S₂O₃ (25 mL), washed with saturated NaHCO₃ (2×50 mL) and the organic layer was removed. The crude mixture was dried over MgSO₄, filtered and passed through a plug of SiO₂ gel using CH₂Cl₂ to recover a dark pink-green solid (5 mg, 0.7%). ¹H NMR (CDCl₃): δ 6.32 (m, 4H, alkene —CH), 6.01-5.91 (m, 4H, alkene —CH), 3.80 (m, 4H, bridgehead —CH), 3.59-3.48 (m, 4H, bridgehead —CH), 2.58 (multiple s, 12H, —CH₃), 1.25 (m, 16H, bridghead —CH₂).

### Example 7

### General Reaction Scheme for Triad 30 of FIG. 16C

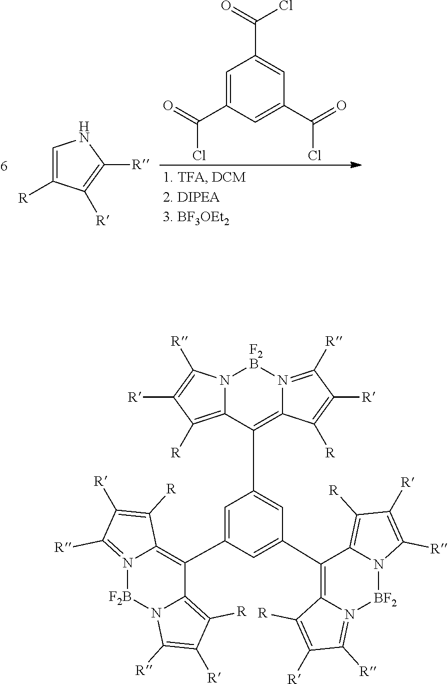

Triad 30.

1,3,5-Benzenetricarbonyl trichloride (1 g, 3.76 mmol) was dissolved in dry dichloromethane (80 ml) under N₂. 2,4-Dimethyl-3-ethylpyrrole (2.78 g, 22.6 mmol) was added and the flask was fitted with a condenser and refluxed overnight. N,N-Diisopropylethylamine (7.85 ml, 45.12 mmol) was added at reflux. After 15 minutes, the mixture was cooled to room temperature and boron trifluoride etherate (5.66 mL, 45.12 mmol) was added in one portion. After one hour, the reaction was quenched with saturated Na₂S₂O₃ (50 mL), washed with saturated NaHCO₃ (2×50 mL) and water (2×50 mL). The organic layer was removed, dried over MgSO₄, filtered and concentrated. The product was purified by flash chromatography (SiO₂ gel, CH₂Cl₂) to give the product in trace amounts. ¹H NMR (CDCl₃): δ 7.73 (s, 1H, Ar—H), 2.55 (s, 18H, BODIPY —CH₃), 2.31 (q, 12H, BODIPY —CH₂), 1.69 (s, 18H, BODIPY —CH₃), 1.01 (t, 18H, —CH₃).

### Example 8

### General Reaction Scheme for Zinc Compounds 31-34 of FIGS. 16C and 16D

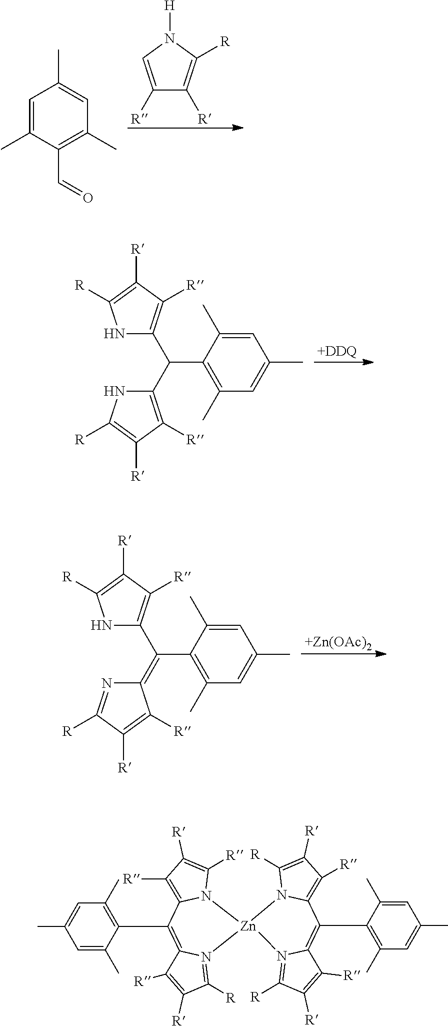

Zinc Compound 31.

5-Mesityldipyrromethane (2 g, 7.57 mmol) was dissolved in 200 ml of freshly distilled THF under Nitrogen. 2,3-Dichloro-5,6-dicyano-1,4-benzoquinone (DDQ) (1.72 g, 7.57 mmol) in 15 ml of freshly distilled THF was added slowly to the solution. Reaction mixture turned to dark red color. Reaction mixture was stirred under nitrogen for 1 hour. The reaction was quenched by adding 5 ml of Triethylamine, stirred for another 5 min. Solvent was then removed under reduced pressure. The product mixture was dissolved in 200 ml of dichloromethane, and was washed with saturated NaHCO₃ solution in water (150 ml, 3 times) and brine (150 ml, 1 time). The solution was then dried over anhydrous Na₂SO₄ and filtered. This solution of 5-mesityldipyrromethene was used without further purification. Zinc acetate dihydrate (Zn(OAc)₂.2H₂O) (10 g, 45.5 mmol) in 50 ml of methanol was added to the solution of 5-mesityldipyrromethene in dichloromethane and stirred overnight. After that, reaction mixture was filter using filter paper. Solvent was then removed under reduced pressure. The obtained solid was passed through short neutral alumina plug using hexanes/dichloromethane (50/50) mixture as eluent, the portion in orange color was collected. Solvent was then removed under reduced pressure to obtain 1 g of orange solid (14% yield). The obtained 10 was further purified by gradient sublimation under ultra high vacuum (10⁻⁵ torr) at 180° C.-140° C.-100° C. gradient temperature zones. ¹H NMR (400 MHz, CDCl₃) δ ppm 7.027.01 (m, 12H), 6.22-6.21 (m, 8H), 2.02 (s, 24H), 1.55 (s, 6H).

Zinc Compound 32.

A mixture of mesitaldehyde (4.6 g, 30.9 mmol) and 2-methylpyrrole (5 g, 61.7 mmol) was dissolved in 200 ml dichloromethane in a 500-mL single-neck round-bottomed flask was degassed with a stream of nitrogen for 10 min. Then 5 drops of trifluoroacetic acid (TFA) was added to the reaction mixture, the solution turned to dark red color. Reaction mixture was stirred under nitrogen for 6 hours until the starting materials were completely consumed. The reaction was quenched with 3 ml of triethylamine. Reaction mixture was then washed with saturated Na₂CO₃ solution in water (100 ml, 3 times) and brine (100, 1 time). Solution was dried over anhydrous Na₂SO₄. Solvent was then removed under reduced pressure to obtain the viscous pale yellow liquid (it turns to solid upon standing at room temperature). This product was dissolved in 250 ml of freshly distilled THF under Nitrogen. 2,3-Dichloro-5,6-dicyano-1,4-benzoquinone (DDQ) (7.02 g, 30.9 mmol) in 35 ml of freshly distilled THF was added slowly to the solution. Reaction mixture turned to dark red color. Reaction mixture was stirred under nitrogen for 1 hour. The reaction was quenched by adding 10 ml of triethylamine, stirred for another 5 min. Solvent was then removed under reduced pressure. The product mixture was dissolved in 500 ml of dichloromethane, and was washed with saturated NaHCO₃ solution in water (250 ml, 3 times) and brine (250 ml, 1 time). The solution was then dried over anhydrous Na₂SO₄ and filtered. Zinc acetate dihydrate (Zn(OAc)₂.2H₂O) (20 g, 91 mmol) in 100 ml of methanol was added to the solution in dichloromethane and stirred overnight. After that, reaction mixture was filter using filter paper. Solvent was then removed under reduced pressure. The obtained solid was passed through short neutral alumina plug using hexanes/dichloromethane (70/30) mixture as eluent, the portion in orange-red color was collected. Solvent was then removed under reduced pressure to obtain 2.5 g of dark green solid (12.3% total yield). The obtained 32 was further purified by gradient sublimation under ultra high vacuum (10⁻⁵ torr) at 220° C.-160° C.-120° C. gradient temperature zones. ¹H NMR (400 MHz, CDCl₃): δ ppm 6.92 (s, 4H), 6.46-6.43 (m, J=4.25 Hz, 4H), 6.13 (d, J=3.94 Hz, 4H), 2.37 (s, 6H), 2.14 (s, 12H), 2.11 (s, 12H).

Zinc Compound 33.

A mixture of mesitaldehyde (5 g, 33.5 mmol) and 2,4-dimethylpyrrole (6.4 g, 67 mmol) was dissolved in 250 ml dichloromethane in a 500-mL single-neck round-bottomed flask was degassed with a stream of nitrogen for 10 min. Then 5 drops of trifluoroaceticacid (TFA) was added to the reaction mixture, the solution turned to dark red color. Reaction mixture was stirred under Nitrogen for 7 hours until the starting materials were completely consumed. The reaction was quenched with 3 ml of triethylamine. Reaction mixture was then washed with saturated Na₂CO₃ solution in water (100 ml, 3 times) and brine (100, 1 time). Solution was dried over anhydrous Na₂SO₄. Solvent was then removed under reduced pressure to obtain the viscous pale yellow liquid (it turns to solid upon standing at room temperature). The crude product obtained was dissolved in 250 ml of freshly distilled THF under nitrogen. DDQ (7.61 g, 30.9 mmol) in 40 ml of freshly distilled THF was added slowly to the solution. Reaction mixture turned to dark red color. Reaction mixture was stirred under nitrogen for 1 hour. The reaction was quenched by adding 10 ml of Triethylamine, stirred for another 5 min. Solvent was then removed under reduced pressure. The product mixture was dissolved in 500 ml of dichloromethane, and was washed with saturated NaHCO₃ solution in water (250 ml, 3 times) and brine (250 ml, 1 time). The solution was then dried over anhydrous Na₂SO₄ and filtered. This solution of 1,3,7,9-tetramethyl-5-Mesityldipyrromethene was used without further purification. Zinc acetate dihydrate (Zn(OAc)₂.2H₂O) (20 g, 91 mmol) in 100 ml of methanol was added to the solution of 1,3,7,9-tetramethyl-5-Mesityldipyrromethene in dichloromethane and stirred overnight. After that, reaction mixture was filter using filter paper. Solvent was then removed under reduced pressure. The obtained solid was passed through short neutral alumina plug using hexanes/dichloromethane (70/30) mixture as eluent, the portion in orange-red color was collected. Solvent was then removed under reduced pressure to obtain 3.0 g of orange-red solid (13% total yield). The obtained 33 was further purified by gradient sublimation under ultra high vacuum (10⁻⁵ torr) at 230° C.-160° C.-120° C. gradient temperature zones. ¹H NMR (500 MHz, CDCl₃): δ ppm 6.93 (s, 4H), 5.91 (s 4H), 2.35 (s, 6H), 2.12 (s, 12H), 2.04 (s, 12H), 1.31 (s, 12H). ¹³C NMR (500 MHz, CDCl₃): δ ppm 155.90, 143.63, 143.15, 137.35, 136.22, 135.57, 134.54, 128.73, 119.56, 21.21, 19.26, 16.12, 14.83. HRMS: calcd for C₄₄H₅₁N₄Zn (MH⁺): 699.3400. found: 699.3407. C, H, N elemental analysis for C₄₄H₅₁N₄Zn: calcd (%) C (75.47), H (7.20), N (8.00). found (%) C (75.84), H (7.27), N (8.06).

Zinc Compound 34.

2,8diethyl1,3,7,9-tetramethyl-5-Mesityldipyrromethane. A mixture of mesitylaldehyde (2 g, 13.4 mmol) and 3-ethyl2,4-dimethylpyrrole (3.3 g, 26.8 mmol) was dissolved in 150 ml dichloromethane in a 500-mL single-neck round-bottomed flask was degassed with a stream of nitrogen for 10 min. Then 3 drops of trifluoroaceticacid (TFA) was added to the reaction mixture, the solution turned to dark red color. Reaction mixture was stirred under Nitrogen for 7 hours until the starting materials were completely consumed. The reaction was quenched with 3 ml of triethylamine. Reaction mixture was then washed with saturated Na₂CO₃ solution in water (100 ml, 3 times) and brine (100, 1 time). Solution was dried over anhydrous Na₂SO₄. Solvent was then removed under reduced pressure. This product was dissolved in 150 ml of freshly distilled THF under nitrogen. DDQ (3.3 g, 13.4 mmol) in 15 ml of freshly distilled THF was added slowly to the solution. Reaction mixture turned to dark red color. Reaction mixture was stirred under nitrogen for 1 hour. The reaction was quenched by adding 10 ml of Triethylamine, stirred for another 5 min. Solvent was then removed under reduced pressure. The product mixture was dissolved in 300 ml of dichloromethane, and was washed with saturated NaHCO₃ solution in water (150 ml, 3 times) and brine (150 ml, 1 time). The solution was then dried over anhydrous Na₂SO₄ and filtered and was used without further purification. Zinc acetate dihydrate (Zn(OAc)₂.2H₂O) (8 g, 36.4 mmol) in 50 ml of methanol was added to the solution of 2,8-diethyl-1,3,7,9-tetramethyl-5-mesityldipyrromethene in dichloromethane and stirred overnight. After that, reaction mixture was filter using filter paper. Solvent was then removed under reduced pressure. The obtained solid was passed through short neutral alumina plug using hexanes/dichloromethane (70/20) mixture as eluent, the portion in red color was collected. Solvent was then removed under reduced pressure to obtain 0.8 g of orange-red solid (7.7% total yield). The obtained 34 was further purified by gradient sublimation under ultra high vacuum (10⁻⁵ torr) at 240° C.-160° C.-120° C. gradient temperature zones. ¹H NMR (500 MHz, CDCl₃): δ ppm 6.92 (s, 4H), 2.36 (s, 6H), 2.25 (q, J=7.40 Hz, 8H), 2.11 (s, 12H), 1.97 (s, 12H), 1.19 (s, 12H), 0.91 (t, J=7.49 Hz, 12H). ¹³C NMR (500 MHz, CDCl₃): δ ppm 154.68, 142.03, 137.19, 137.10, 137.03, 136.00, 134.17, 130.66, 128.55, 21.24, 19.47, 17.92, 15.25, 14.35, 11.75. HSMS: calculated for C₅₂H₆₇N₄Zn (MH⁺) 811.4652. found 811.4658. CNH analysis for C₅₂H₆₆N₄Zn: calculated (%) C (76.87), H (8.19), N (6.90). found C (76.98), H (8.35), N (6.97).

### Example 9

### An Organic Photosensitive Optoelectronic Device Using Compound 31 of FIG. 16C

OPVs using compound 31 of FIG. 16C as a donor material and fullerene C₆₀ as an acceptor material have been fabricated using vacuum deposition technique on glass coated with Indium doped Tin Oxide (ITO) substrate. The OPV device with MoO3 as hole conducting/electron blocking layer was also fabricated. The device structures and characteristics are shown in the table below and in FIGS. 34A to 34C. Both devices have significant photocurrents (3.06 and 3.49 mA/cm2). External Quantum Efficiency measurements (FIG. 34C) confirm the contribution of compound 31 to the photocurrent (up to 30% EQE at 500 nm). The MoO3 hole conducting/electron blocking layer increases the open circuit voltage (VOC) from 0.60 to 0.82 V, while the short circuit current (JSC) and the fill factor (FF) decreases slightly compared to the device without MoO3. Thus, both devices (D1 and D2) have comparable power conversion efficiency (0.9%). One of ordinary skill in the art would understand that the OPVs of Example 9 represent only one illustration of the present disclosure and that OPV device performance can be improved by methods known in the art.

| Device | J_{SC} (mA/cm²) | V_{OC} (V) | FF | η (%) |
|---|---|---|---|---|
| 1 | 3.06 | 0.82 | 0.35 | 0.88 |
| 2 | 3.49 | 0.60 | 0.41 | 0.86 |

Device performance characteristics under AM1.5G illumination. D1: ITO/MoO3 (8 nm)/31 (10 nm)/C60 (40 nm)/BCP (10 nm)/Al, and D2: ITO/31 (10 nm)/C60 (40 nm)/BCP (10 nm)/Al.

Specific examples of the disclosure are illustrated and/or described herein. However, it will be appreciated that modifications and variations of the disclosure are covered by the above teachings and within the purview of the appended claims without departing from the spirit and scope of the disclosure.

What is claimed is:

1. An organic photosensitive optoelectronic device comprising at least one compound of formula (I): 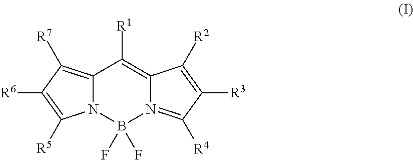
wherein:
R¹ is chosen from an optionally substituted monocyclic group, an optionally substituted C₆₋₂₄ multicyclic group, and an optionally substituted meso-linked BODIPY, or R¹ and R² and R⁷ taken together with any intervening atoms comprise a substituted BODIPY, wherein R¹ is meso-linked and R² and R⁷ are beta-linked;
R² is chosen from hydrogen, an alkyl group, and a cyano group, or R² and R³ taken together with any intervening atoms comprise a group chosen from an optionally substituted monocyclic group and an optionally substituted C₆₋₂₄ multicyclic group, or R² and R¹ and R⁷ taken together with any intervening atoms comprise a substituted BODIPY, wherein R¹ is meso-linked and R² and R⁷ are beta-linked;
R³ is chosen from hydrogen, an alkyl group, and a cyano group, or R³ and R² taken together with any intervening atoms comprise a group chosen from an optionally substituted monocyclic group and an optionally substituted C₆₋₂₄ multicyclic group, or R³ and R⁴ taken together with any intervening atoms comprise a group chosen from an optionally substituted monocyclic group and an optionally substituted C₆₋₂₄ multicyclic group;
R⁴ is chosen from hydrogen, an alkyl group, and a cyano group, or R⁴ and R³ taken together with any intervening atoms comprise a group chosen from an optionally substituted monocyclic group and an optionally substituted C₆₋₂₄ multicyclic group;
R⁵ is chosen from hydrogen, an alkyl group, and a cyano group, or R⁵ and R⁶ taken together with any intervening atoms comprise a group chosen from an optionally substituted monocyclic group and an optionally substituted C₆₋₂₄ multicyclic group;
R⁶ is chosen from hydrogen, an alkyl group, and a cyano group, or R⁶ and R⁵ taken together with any intervening atoms comprise a group chosen from an optionally substituted monocyclic group and an optionally substituted C₆₋₂₄ multicyclic group, or R⁶ and R⁷ taken together with any intervening atoms comprise a group chosen from an optionally substituted monocyclic group and an optionally substituted C₆₋₂₄ multicyclic group; and
R⁷ is chosen from hydrogen, an alkyl group, and a cyano group, or R⁷ and R⁶ taken together with any intervening atoms comprise a group chosen from an optionally substituted monocyclic group and an optionally substituted C₆₋₂₄ multicyclic group, or R⁷ and R¹ and R² taken together with any intervening atoms comprise a substituted BODIPY, wherein R¹ is meso-linked and R² and R⁷ are beta-linked;
and wherein the optionally substituted monocyclic and multicyclic groups are chosen from aryl and heteroaryl groups.

2. The device of claim 1, wherein R¹ is chosen from optionally substituted benzene and optionally substituted fused benzene.

3. The device of claim 1, wherein R² and R³ taken together with any intervening atoms, and R⁶ and R⁷ taken together with any intervening atoms, both comprise a group chosen from an optionally substituted monocyclic group and an optionally substituted C₆₋₂₄ multicyclic group.

4. The device of claim 1, wherein R³ and R⁴ taken together with any intervening atoms, and R⁵ and R⁶ taken together with any intervening atoms, both comprise a group chosen from an optionally substituted monocyclic group and an optionally substituted C₆₋₂₄ multicyclic group.

5. The device of claim 1, wherein R² and R⁷ are both chosen from hydrogen, an alkyl group, and a cyano group.

6. The device of claim 1, wherein R⁵ and R⁴ are both chosen from hydrogen, an alkyl group, and a cyano group.

7. The device of claim 1, wherein R³ and R⁶ are both chosen from hydrogen, an alkyl group, and a cyano group.

8. The device of claim 1, wherein R², R³, R⁴, R⁵, R⁶, and R⁷ are all chosen from hydrogen, an alkyl group, and a cyano group.

9. The device of claim 1, wherein the at least one compound of formula (I) is chosen from 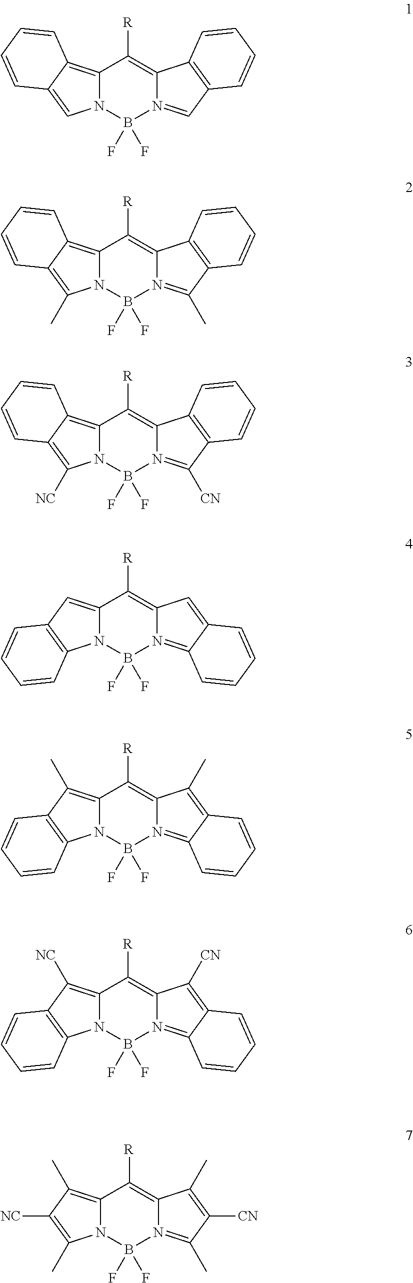 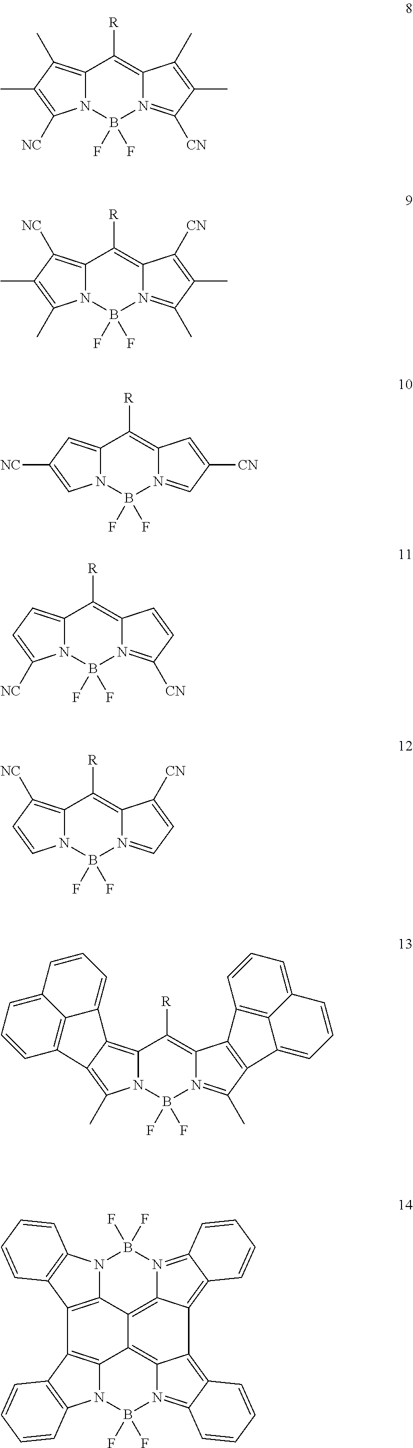 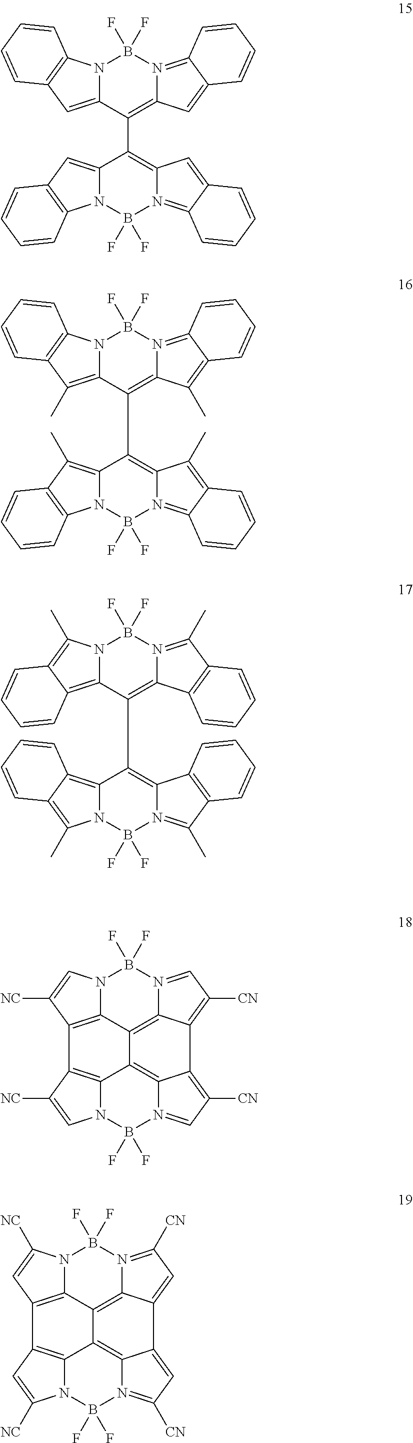 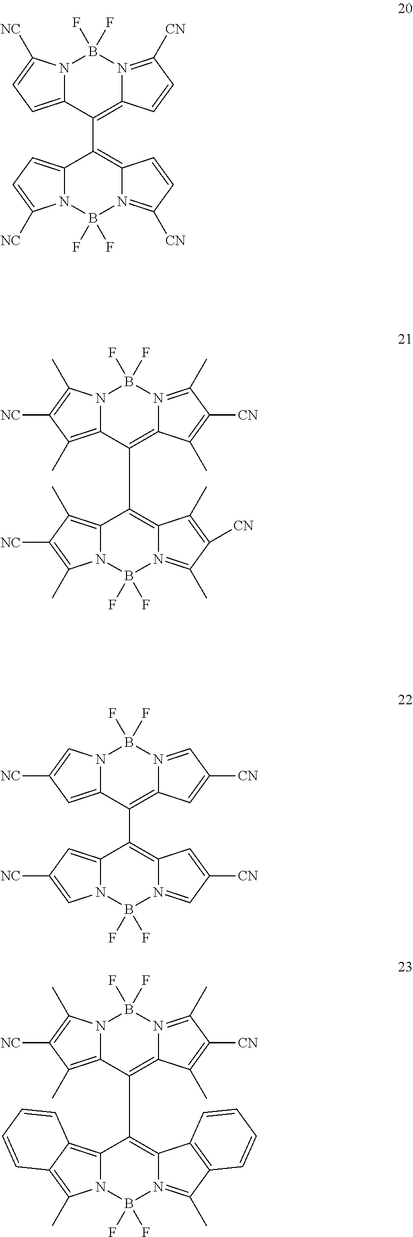
wherein R is chosen from an optionally substituted monocyclic aryl or heteroaryl group and an optionally substituted C₆₋₂₄ multicyclic aryl or heteroaryl group.

10. The device of claim 9, wherein R is chosen from 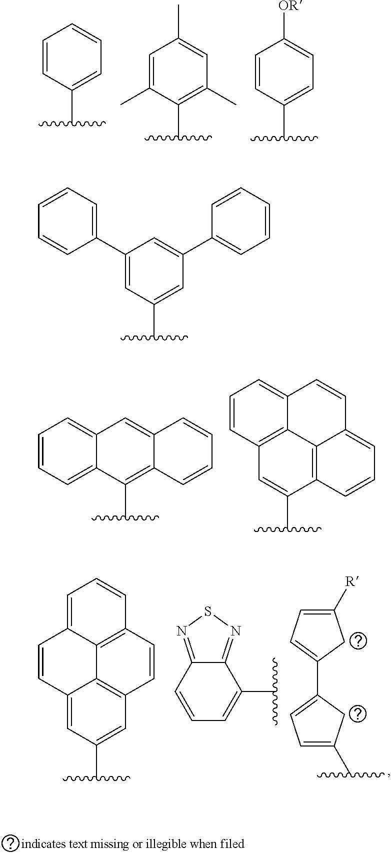
wherein R′ is chosen from H, alkyl, and aryl or heteroaryl groups.

11. The device of claim 9, further comprising at least one donor material and at least one acceptor material, wherein one of the donor and acceptor materials comprises the at least one compound of formula (I).

12. The device of claim 1, further comprising at least one donor material and at least one acceptor material, wherein one of the donor and acceptor materials comprises the at least one compound of formula (I).

13. The device of claim 12, wherein the at least one donor material comprises the at least one compound of formula (I).

14. The device of claim 13, wherein the at least one acceptor material comprises C₆₀.

15. The device of claim 12, wherein the at least one acceptor material comprises the at least one compound of formula (I).

16. The device of claim 15, wherein the at least one donor material comprises CuPc.

17. The device of claim 12, wherein the at least one donor material comprises the at least one compound of formula (I), and the at least one acceptor material comprises another compound of formula (I).

18. The device of claim 12, wherein the at least one donor material and the at least one acceptor material form a donor-acceptor heterojunction.

19. The device of claim 13, wherein the at least one donor material and the at least one acceptor material form a lamellar structure, and wherein the at least one donor layer has a thickness ranging from about 1 nm to about 150 nm.

20. The device of claim 19, wherein the thickness of the at least one donor layer ranges from about 20 nm to about 80 nm.

21. The device of claim 1, wherein the device is an organic solar cell.

22. A method of making an organic photosensitive optoelectronic device of claim 1, comprising depositing a photoactive region over a substrate, wherein the photoactive region comprises at least one compound of formula (I).

23. The method of claim 22, wherein the photoactive region comprises at least one donor material and at least one acceptor material, wherein one of the donor and acceptor materials comprises the at least one compound of formula (I).

24. The method of claim 22, wherein the deposition of the photoactive region comprises depositing the at least one compound of formula (I) over a substrate using a technique chosen from spin casting and vapor deposition.
